(19) United States
(12) Patent Application Publication
(10) Pub. No.: US 2026/0107686 A1
(43) Pub. Date: Apr. 16, 2026

(54) LIGHT EMITTING ELEMENT AND ELECTRONIC DEVICE INCLUDING THE SAME

(71) Applicant: Samsung Display Co., Ltd., Yongin-si (KR)

(72) Inventors: MINJE KIM, Yongin-si (KR); EUNG DO KIM, Yongin-si (KR); HYUN SHIN, Yongin-si (KR); BYEONGWOOK YOO, Yongin-si (KR); JINYOUNG YUN, Yongin-si (KR); CHANGWOONG CHU, Yongin-si (KR)

(73) Assignee: Samsung Display Co., Ltd., Yongin-si (KR)

(21) Appl. No.: 19/245,553

(22) Filed: Jun. 23, 2025

(30) Foreign Application Priority Data
Jun. 26, 2024 (KR) 10-2024-0083331
Jul. 8, 2024 (KR) 10-2024-0089470

(51) Int. Cl. H10K 85/60; C09K 11/02; C09K 11/06; H10K 50/12; H10K 85/30; H10K 85/40

(52) U.S. Cl. CPC H10K 85/6572; C09K 11/02; C09K 11/06; H10K 85/346; H10K 85/40; H10K 85/654; H10K 85/658; C09K 2211/1007; C09K 2211/1018; H10K 50/121

(57) ABSTRACT

Embodiments provide a light emitting element and an electronic device that includes the light emitting element. The light emitting element includes a first electrode, a second electrode disposed on the first electrode, an emission layer disposed between the first and second electrodes, a first buffer layer disposed between the emission layer and the first electrode, and a second buffer layer disposed between the emission layer and the second electrode. The emission layer includes a hole transporting host, an electron transporting host, a phosphorescent sensitizer, and a light emitting dopant; the first buffer layer includes the hole transporting host, the phosphorescent sensitizer, and the light emitting dopant; and the second buffer layer includes the electron transporting host, the phosphorescent sensitizer, and the light emitting dopant. The first buffer layer and the second buffer layer each independently have a thickness in a range of about 20 Å to about 50 Å.

### CROSS-REFERENCE TO RELATED APPLICATION(S)

This application claims priority to and benefits of Korean Patent Application Nos. 10-2024-0083331 and 10-2024-0089470 under 35 U.S.C. § 119, respectively filed on Jun. 26, 2024 and Jul. 8, 2024 in the Korean Intellectual Property Office, the entire contents of which are incorporated herein by reference.

### BACKGROUND

### 1. Technical Field

The disclosure relates to a light emitting element including a buffer layer disposed adjacent to each of an upper portion and a lower portion of an emission layer, and an electronic device including the light emitting element.

### 2. Description of the Related Art

Ongoing development continues for organic electroluminescence display devices and the like as image display devices. An organic electroluminescence display device is a so-called self-emissive display device that includes light emitting elements, in which holes and electrons respectively injected from a first electrode and a second electrode recombine in an emission layer, so that in the emission layer, a luminescent material emits light to achieve display.

In the application of light emitting elements to display devices, there is a persistent demand for greater light efficiency and service life. Thus, continuous development is required on materials for light emitting elements that are capable of achieving such characteristics.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a light emitting element having increased lifetime and luminous efficiency.

The disclosure also provides a display device exhibiting excellent display quality and reliability, including a light emitting element having increased lifetime and luminous efficiency.

According to embodiments, a light emitting element may include a first electrode, a hole transport region disposed on the first electrode, an emission layer disposed on the hole transport region, an electron transport region disposed on the emission layer, a second electrode disposed on the electron transport region, a first buffer layer disposed between the hole transport region and the emission layer, and a second buffer layer disposed between the emission layer and the electron transport region. The emission layer may include a hole transporting host, an electron transporting host, a phosphorescent sensitizer, and a light emitting dopant; the first buffer layer may include the hole transporting host, the phosphorescent sensitizer, and the light emitting dopant; the second buffer layer may include the electron transporting host, the phosphorescent sensitizer, and the light emitting dopant; and the first buffer layer and the second buffer layer may each independently have a thickness in a range of about 20 Å to about 50 Å.

In an embodiment, an amount of the phosphorescent sensitizer in the first buffer layer and the second buffer layer may each independently be in a range of about 5 wt % to about 20 wt %; and an amount of the light emitting dopant in the first buffer layer and the second buffer layer may each independently be in a range of about 1 wt % to about 3 wt %.

In an embodiment, the first buffer layer and the second buffer layer may each be directly disposed on the emission layer.

In an embodiment, the hole transport region may include a hole transport layer, and a hole injection layer disposed between the first electrode and the hole transport layer; the electron transport region may include an electron transport layer, and an electron injection layer disposed between the electron transport layer and the second electrode; the first buffer layer may be directly disposed between the hole transport layer and the emission layer; and the second buffer layer may be directly disposed between the emission layer and the electron transport layer.

In an embodiment, in the emission layer, a weight ratio of the hole transporting host to the electron transporting host may be in a range of about 3:7 to about 7:3.

In an embodiment, in the emission layer, an amount of the phosphorescent sensitizer may be in a range of about 10 wt % to about 20 wt %; and an amount of the light emitting dopant may be in a range of about 2 wt % to about 5 wt %.

In an embodiment, the hole transporting host may include at least one compound selected from Compound Group 1, which is explained below; and the electron transporting host may include at least one compound selected from Compound Group 2, which is explained below.

In an embodiment, the phosphorescent sensitizer may be an organometallic complex that includes platinum (Pt) as a central metal atom.

In an embodiment, the light emitting dopant may be a thermally activated delayed fluorescence dopant.

In an embodiment, the phosphorescent sensitizer may include at least one compound selected from Compound Group 3, which is explained below.

In an embodiment, the light emitting dopant may include at least one compound selected from Compound Group 4, which is explained below.

In an embodiment, the emission layer may emit blue light.

According to embodiments, a light emitting element may include a first electrode, a second electrode facing the first electrode, and at least one light emitting structure disposed between the first electrode and the second electrode. The at least one light emitting structure may include a hole transport region, a first buffer layer disposed on the hole transport region, an emission layer disposed on the first buffer layer, a second buffer layer disposed on the emission layer, and an electron transport region disposed on the second buffer layer. The emission layer may include a hole transporting host, an electron transporting host, a phosphorescent sensitizer, and a light emitting dopant; the first buffer layer may include the hole transporting host, the phosphorescent sensitizer, and the light emitting dopant; the second buffer layer may include the electron transporting host, the phosphorescent sensitizer, and the light emitting dopant; and the first buffer layer and the second buffer layer may each independently have a thickness in a range of about 20 Å to about 50 Å.

In an embodiment, an amount of the phosphorescent sensitizer in the first buffer layer and the second buffer layer may each independently be in a range of about 5 wt % to about 20 wt %; and an amount of the light emitting dopant in the first buffer layer and the second buffer layer may each independently be in a range of about 1 wt % to about 3 wt %.

In an embodiment, the light emitting element may include multiple light emitting structures; and the light emitting element may further include a charge generation layer disposed between adjacent structures among the light emitting structures.

According to embodiments, an electronic device may include a circuit layer disposed on a base layer, and a light emitting element disposed on the circuit layer. The light emitting element may include a first electrode, a second electrode facing the first electrode, and at least one light emitting structure disposed between the first electrode and the second electrode. The at least one light emitting structure may include a hole transport region, a first buffer layer disposed on the hole transport region, an emission layer disposed on the first buffer layer, a second buffer layer disposed on the emission layer, and an electron transport region disposed on the second buffer layer. The emission layer may include a hole transporting host, an electron transporting host, a phosphorescent sensitizer, and a light emitting dopant; the first buffer layer may include the hole transporting host, the phosphorescent sensitizer, and the light emitting dopant; the second buffer layer may include the electron transporting host, the phosphorescent sensitizer, and the light emitting dopant; and the first buffer layer and the second buffer layer may each independently have a thickness in a range of about 20 Å to about 50 Å.

In an embodiment, the electronic device may further include a light control layer disposed on the light emitting element, wherein the light emitting element may emit a source light, and light control layer may transmit the source light or may convert the wavelength of the source light.

In an embodiment, the electronic device may include a first pixel region emitting red light, a second pixel region emitting green light, and a third pixel region emitting blue light, wherein the first pixel region, the second pixel region, and the third pixel region do not overlap each other in a plan view. The light control layer may include: a first light control part that is disposed to correspond to the first pixel region, and includes a first quantum dot that converts the wavelength of the source light; a second light control part that is disposed to correspond to the second pixel region, and includes a second quantum dot that converts the wavelength of the source light; and a third light control part that is disposed to correspond to the third pixel region.

In an embodiment, an amount of the phosphorescent sensitizer in the first buffer layer and the second buffer layer may each independently be in a range of about 5 wt % to about 20 wt %; and an amount of the light emitting dopant in the first buffer layer and the second buffer layer may each independently be in a range of about 1 wt % to about 3 wt %.

In an embodiment, the phosphorescent sensitizer may be an organometallic complex that includes platinum (Pt) as a central metal atom; and the light emitting dopant may be a thermally activated delayed fluorescence dopant.

It is to be understood that the embodiments above are described in a generic and explanatory sense only and not for the purposes of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a schematic plan view of a display device according to an embodiment;

FIG. 2 is a schematic cross-sectional view of a display device according to an embodiment;

FIG. 3 is a schematic cross-sectional view of a light emitting element according to an embodiment;

FIG. 4 is a schematic cross-sectional view of a display device according to an embodiment;

FIG. 5 is a schematic cross-sectional view of a display device according to an embodiment;

FIG. 6 is a schematic cross-sectional view of a light emitting element according to an embodiment;

FIG. 7 is a schematic diagram of a configuration of a light emitting structure of a light emitting element according to the related art;

FIG. 8 is a schematic diagram of a configuration of a light emitting structure of a light emitting element according to an embodiment; and

FIGS. 9A and 9B are each a graph showing changes in luminance over time in each of the light emitting elements according to the Comparative Examples and the Examples.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and reference characters refer to like elements throughout.

In the specification, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the specification, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within +20%, +10%, or +5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the term, “substituted or unsubstituted” may describe a group that is substituted or unsubstituted with at least one substituent selected from the group consisting of a deuterium atom, a halogen atom, a cyano group, a nitro group, an amine group, a silyl group, oxy group, thio group, sulfinyl group, sulfonyl group, carbonyl group, a boron group, a phosphine oxide group, a phosphine sulfide group, an alkyl group, an alkenyl group, an alkynyl group, a hydrocarbon ring group, an aryl group, and a heterocyclic group. Each of the substituents listed above may itself be substituted or unsubstituted. For example, a biphenyl group may be interpreted as an aryl group, or it may be interpreted as a phenyl group substituted with a phenyl group.

In the specification, the term, “bonded to an adjacent group to form a ring” may refer to a group that is bonded to an adjacent group to form a substituted or unsubstituted hydrocarbon ring or a substituted or unsubstituted heterocycle. A hydrocarbon ring may be aliphatic or aromatic. A heterocycle may be aliphatic or aromatic. A hydrocarbon ring and a heterocycle may each independently be monocyclic or polycyclic. A ring that is formed by adjacent groups being bonded to each other may itself be linked to another ring to form a spiro structure.

In the specification, the term, “adjacent group” may be interpreted as a substituent that is substituted for an atom that is directly linked to an atom substituted with a corresponding substituent, as another substituent that is substituted for an atom that is substituted with a corresponding substituent, or as a substituent that is sterically positioned at the nearest position to a corresponding substituent. For example, two methyl groups in 1,2-dimethylbenzene may be interpreted as “adjacent groups” to each other, and two ethyl groups in 1,1-diethylcyclopentane may be interpreted as “adjacent groups” to each other. For example, two methyl groups in 4,5-dimethylphenanthrene may be interpreted as “adjacent groups” to each other.

In the specification, examples of a halogen atom may include a fluorine atom, a chlorine atom, a bromine atom, and an iodine atom.

In the specification, an alkyl group may be linear or branched. The number of carbon atoms in the alkyl group may be 1 to 60, 1 to 30, 1 to 20, 1 to 15, 1 to 10, or 1 to 6. Examples of an alkyl group may include a methyl group, an ethyl group, an n-propyl group, an isopropyl group, an n-butyl group, a s-butyl group, at-butyl group, an i-butyl group, a 2-ethylbutyl group, a 3,3-a dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, and the like, but embodiments are not limited thereto.

In the specification, a cycloalkyl group may be a cyclic alkyl group. The number of carbon atoms in a cycloalkyl group may be 3 to 60, 3 to 30, 3 to 20, or 3 to 10. Examples of a cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, and the like, but embodiments are not limited thereto.

In the specification, an alkenyl group may be a hydrocarbon group that includes at least one carbon-carbon double bond in the middle or at a terminus of an alkyl group having 2 or more carbon atoms. An alkenyl group may be linear or branched. The number of carbon atoms in an alkenyl group is not particularly limited, and may be 2 to 60, 2 to 30, 2 to 20, or 2 to 10. Examples of an alkenyl group may include a vinyl group, a 1-butenyl group, a 1-pentenyl group, a 1,3-butadienyl aryl group, a styrenyl group, a styryl vinyl group, and the like, but embodiments are not limited thereto.

In the specification, an alkynyl group may be a hydrocarbon group that includes at least one carbon-carbon triple bond in the middle or at a terminus of an alkyl group having 2 or more carbon atoms. An alkynyl group may be linear or branched. The number of carbon atoms in an alkynyl group is not particularly limited, and may be 2 to 30, 2 to 20, or 2 to 10. Examples of an alkynyl group may include an ethynyl group, a propynyl group, and the like, but embodiments are not limited thereto.

In the specification, a hydrocarbon ring group may be any functional group or substituent derived from an aliphatic hydrocarbon ring. For example, a hydrocarbon ring group may be a saturated hydrocarbon ring group having 5 to 20 ring-forming carbon atoms.

In the specification, an aryl group may be any functional group or substituent derived from an aromatic hydrocarbon ring. An aryl group may be monocyclic or polycyclic. The number of ring-forming carbon atoms in an aryl group may be 6 to 60, 6 to 30, 6 to 20, or 6 to 15. Examples of an aryl group may include a phenyl group, a naphthyl group, a fluorenyl group, an anthracenyl group, a phenanthryl group, a biphenyl group, a terphenyl group, a quarterphenyl group, a quinquephenyl group, a sexiphenyl group, a triphenylenyl group, a pyrenyl group, a benzofluoranthenyl group, a chrysenyl group, and the like, but embodiments are not limited thereto.

In the specification, a fluorenyl group may be substituted, and two substituents may be bonded to each other to form a spiro structure. Examples of a substituted fluorenyl group may include the groups shown below. However, embodiments are not limited thereto.

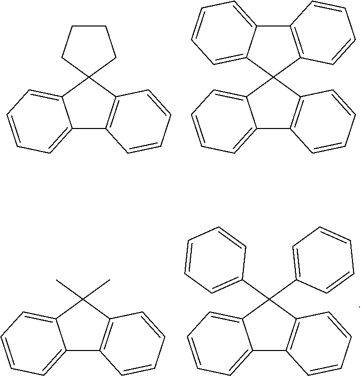

In the specification, a heterocyclic group may be any functional group or substituent derived from a ring containing at least one of B, O, N, P, S, Si, and Se as a heteroatom. A heterocyclic group may be aliphatic or aromatic. An aromatic heterocyclic group may be a heteroaryl group. An aliphatic heterocycle and an aromatic heterocycle may each independently be monocyclic or polycyclic.

When a heterocyclic group contains two or more heteroatoms, the two or more heteroatoms may be the same as or different from each other. The number of ring-forming carbon atoms in a heterocyclic group may be 2 to 60, 2 to 30, 2 to 20, or 2 to 10.

Examples of an aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, and the like, but embodiments are not limited thereto.

Examples of a heteroaryl group may include a thienyl group, a furyl group, a pyrrolyl group, an imidazolyl group, a pyridyl group, a bipyridinyl group, a pyrimidinyl group, a triazinyl group, a triazolyl group, an acridinyl group, a pyridazinyl group, a pyrazinyl group, a quinolyl group, a quinazolinyl group, a quinoxalinyl group, a phenoxazinyl group, a phthalazinyl group, a pyridopyrimidinyl group, a pyridopyrazinyl group, a pyrazinopyrazinyl group, an isoquinolinyl group, an indolyl group, a carbazolyl group, an N-arylcarbazolyl group, an N-heteroarylcarbazolyl group, an N-alkylcarbazolyl group, a benzoxazolyl group, a benzoimidazolyl group, a benzothiazolyl group, a benzocarbazolyl group, a benzothiophenyl group, a dibenzothiophenyl group, a thienothiophenyl group, a benzofuranyl group, a phenanthrolinyl group, a thiazolyl group, an isoxazolyl group, an oxazolyl group, an oxadiazolyl group, a thiadiazolyl group, a phenothiazinyl group, a dibenzosilolyl group, and a dibenzofuranyl group, but embodiments are not limited thereto.

In the specification, the above description of an aryl group may be applied to an arylene group, except that an arylene group is a divalent group. In the specification, the above description of a heteroaryl group may be applied to a heteroarylene group, except that a heteroarylene group is a divalent group.

In the specification, a silyl group may be an alkyl silyl group or an aryl silyl group. Examples of a silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, and the like, but embodiments are not limited thereto.

In the specification, the number of carbon atoms in a carbonyl group is not particularly limited, and may be 1 to 40, 1 to 30, or 1 to 20. For example, a carbonyl group may include one of the following structures, but embodiments are not limited thereto.

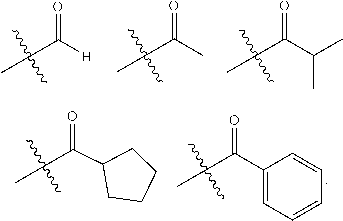

In the specification, the number of carbon atoms in a sulfinyl group or a sulfonyl group is not particularly limited, and may be 1 to 30. A sulfinyl group may be an alkyl sulfinyl group or an aryl sulfinyl group. A sulfonyl group may be an alkyl sulfonyl group or an aryl sulfonyl group.

In the specification, a thio group may be an alkyl thio group or an aryl thio group. A thio group may be a sulfur atom that is bonded to an alkyl group or to an aryl group as defined above. Examples of a thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, and the like, but embodiments are not limited to thereto.

In the specification, an oxy group may be an oxygen atom that is bonded to an alkyl group or to an aryl group as defined above. An oxy group may be an alkoxy group or an aryl oxy group. An alkoxy group may be linear, branched, or cyclic. The number of carbon atoms in an alkoxy group is not particularly limited, and may be, for example, 1 to 20 or 1 to 10. Examples of an oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy group, and the like, but embodiments are not limited thereto.

In the specification, a boron group may be a boron atom that is bonded to an alkyl group or to an aryl group as defined above. A boron group may be an alkyl boron group or an aryl boron group. Examples of a boron group may include a dimethyl boron group, a diethyl boron group, a t-butylmethyl boron group, a diphenyl boron group, a phenyl boron group, and the like, but embodiments are not limited thereto.

In the specification, the number of carbon atoms in an amine group is not particularly limited, and may be 1 to 30. An amine group may be an alkyl amine group or an aryl amine group. Examples of an amine group may include a methylamine group, a dimethylamine group, a phenylamine group, a diphenylamine group, a naphthylamine group, a 9-methyl-anthracenylamine group, and the like, but embodiments are not limited thereto.

In the specification, an alkyl group within an alkylthio group, an alkyl sulfoxy group, an alkylaryl group, an alkylamino group, an alkyl boron group, an alkyl silyl group, or an alkyl amine group may be the same as an example of an alkyl group as described above.

In the specification, an aryl group within an aryloxy group, an arylthio group, an aryl sulfoxy group, an arylamino group, an aryl boron group, an aryl silyl group, or an aryl amine group may be the same as an example of an aryl group as described above.

In the specification, a direct linkage may be a single bond.

In the specification, the symbols

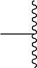

and -* each represent a bond to a neighboring atom in a corresponding formula or moiety.

Hereinafter, a light emitting element according to an embodiment and a display device according to an embodiment will be described with reference to the accompanying drawings.

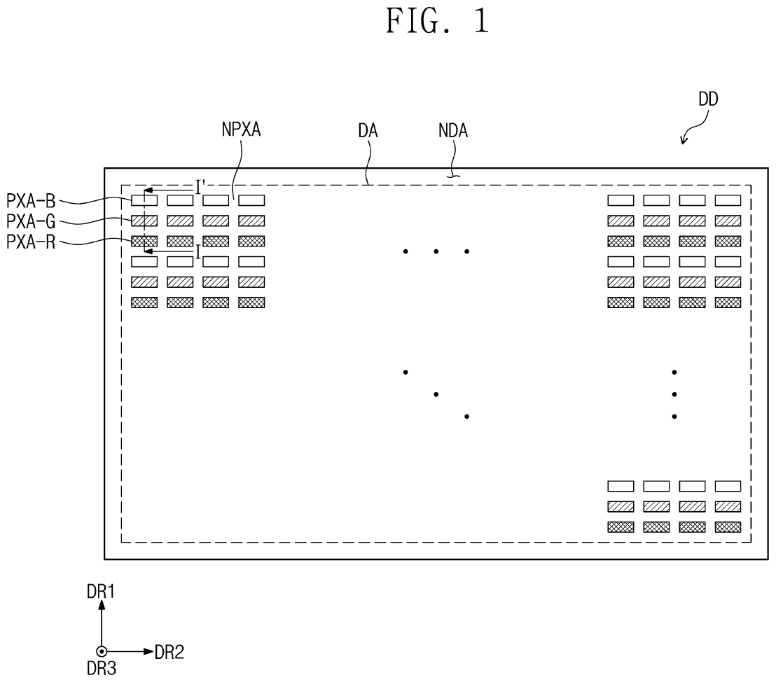

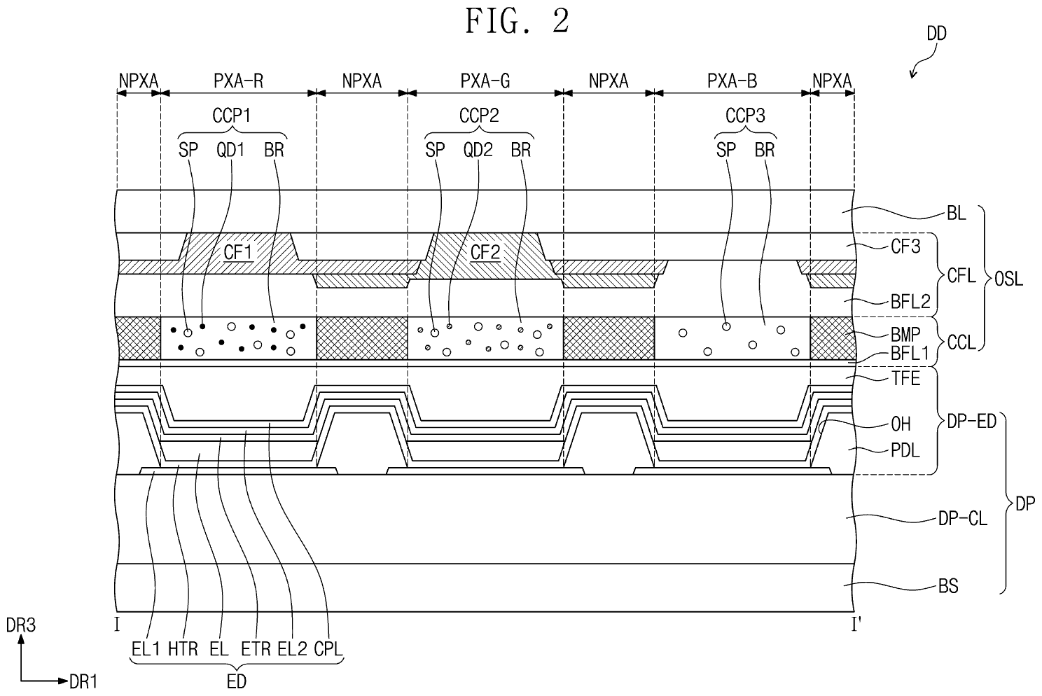

FIG. 1 is a schematic plan view of a display device DD according to an embodiment. FIG. 2 is a schematic cross-sectional view of a display device DD according to an embodiment. FIG. 2 is a schematic cross-sectional view of a portion corresponding to virtual line I-I′ in FIG. 1.

The display device DD may be a device that is activated according to electrical signals to display images. Examples of a display device DD may include large, medium-sized, and small devices, such as a television, a billboard, a monitor, a mobile phone, a tablet computer, a navigation system, and a game console. However, the aforementioned embodiments of the display device DD are presented only as examples, and embodiments are not limited to the particular examples listed above.

The display device DD may be rigid or flexible. In the specification, the term “flexible” indicates a property of being able to bend. Examples of a flexible display device DD may include a curved device, a rollable device, and a foldable device.

The drawings show first, second, and third directional axes DR1, DR2, and DR3, and the directions that are indicated by the first to third directional axes DR1, DR2, and DR3 are relative concepts, and thus may be changed to other directions. The directions that are indicated by the first, second, and third directional axes DR1, DR2, and DR3 may be respectively described as first, second, and third directions DR1, DR2, and DR3, and the same reference numerals may be used. In the specification, the first directional axis DR1 and the second directional axis DR2 may be perpendicular to each other, and the third directional axis DR3 may be a normal direction with respect to a plane defined by the first directional axis DR1 and the second directional axis DR2.

A thickness direction of the display device DD may be parallel to the third directional axis DR3, which is a normal direction with respect to the plane defined by the first directional axis DR1 and the second directional axis DR2. In the specification, a front surface (or an upper surface) and a rear surface (or a lower surface) of the members constituting the display device DD may be defined with respect to the third directional axis DR3. The front surface (or upper surface) and the rear surface (or lower surface) of each member constituting the display device DD may face each other in the third direction DR3, and a normal direction of each of the front and rear surfaces may substantially be parallel to the third direction DR3. A distance between the front surface and the rear surface defined along the third direction DR3 may correspond to a thickness of a member.

In the specification, the term “in a plan view” may refer to a viewing perspective in the third direction DR3. In the specification, the term “cross-sectional view” may refer to a viewing perspective in the first direction DR1 and/or the second direction DR2. As explained above, the directions that are indicated by the first to third directions DR1, DR2, and DR3 are relative concepts, and thus may be changed to other directions.

An electronic device according to an embodiment includes the display device DD according to an embodiment, so that the electronic device may provide images. The display device DD according to an embodiment includes an optical control panel and a display panel, which will be explained below, that includes the light-emitting element. The electronic device may further include at least one of a power module, a processor, and memory, in addition to the display panel. The electronic device may be a video display device, a wearable device, or a vehicle device.

The display device DD may include a display region DA and a non-display region NDA. Pixel regions PXA-R, PXA-G, and PXA-B are disposed on the display region DA. A non-display region NDA may surround the display region DA. However, embodiments are not limited thereto, and the non-display region NDA may not be provided, or the non-display region NDA may be disposed only on a side of the display region DA.

Referring to FIGS. 1 and 2, in an embodiment, the display device DD may include a first pixel region PXA-R, a second pixel region PXA-G, and a third pixel region PXA-B, which emit light in different wavelength ranges. The first to third pixel regions PXA-R, PXA-G, and PXA-B may not overlap and may be spaced apart from each other in a plan view.

In an embodiment, the first pixel region PXA-R may be a red light emitting region that emits red light, the second pixel region PXA-G may be a green light emitting region that emits green light, and the third pixel region PXA-B may be a blue light emitting region that emits blue light. However, embodiments are not limited thereto. In an embodiment, the display region DA may further include a pixel region that emits white light, in addition to the first to third pixel regions PXA-R, PXA-G, and PXA-B.

The pixel regions PXA-R, PXA-G, and PXA-B in the display device DD according to an embodiment may be arranged in a stripe configuration. Referring to FIG. 1, the first pixel regions PXA-R, the second pixel regions PXA-G, and the third pixel regions PXA-B may be respectively arranged along the second directional axis DR2. In another embodiment, the first pixel region PXA-R, the second pixel region PXA-G, and the third pixel region PXA-B may be alternately arranged in this repeating order along the first directional axis DR1.

FIGS. 1 and 2 show that the pixel regions PXA-R, PXA-G, and PXA-B all have a similar area, but embodiments are not limited thereto. In an embodiment, the pixel regions PXA-R, PXA-G and PXA-B may be different in size and/or shape from each other, according to a wavelength range of emitted light. The areas of the pixel regions PXA-R, PXA-G, and PXA-B may be areas in a plan view that are defined by the first directional axis DR1 and the second directional axis DR2.

An arrangement of the pixel regions PXA-R, PXA-G, and PXA-B is not limited to what is shown in FIG. 1, and the order in which the first pixel region PXA-R, the second pixel region PXA-G, and the third pixel region PXA-B are arranged may be provided in varied combinations, according to the display quality characteristics that are required for the display device DD. For example, the pixel regions PXA-R, PXA-G, and PXA-B may be arranged in a pentile configuration (such as PenTile®) or in a diamond configuration (such as Diamond Pixel®).

The areas of each of the pixel regions PXA-R, PXA-G, and PXA-B may be different in size from one another. For example, in an embodiment, an area of a second pixel region PXA-G that corresponds to a green light emitting region may be smaller than an area of a third pixel region PXA-B that corresponds to a blue light emitting region, but embodiments are not limited thereto.

Referring to FIG. 2, the display device DD may include a display panel DP and an optical control panel OSL disposed on the display panel DP. The display panel DP may include a base layer BS, a circuit layer DP-CL, and a display element layer DP-ED, which are sequentially stacked in the third directional axis DR3. The optical control panel OSL may be disposed on the display element layer DP-ED. In the display device DD, the optical control panel OSL may include a color filter layer CFL and a base substrate BL.

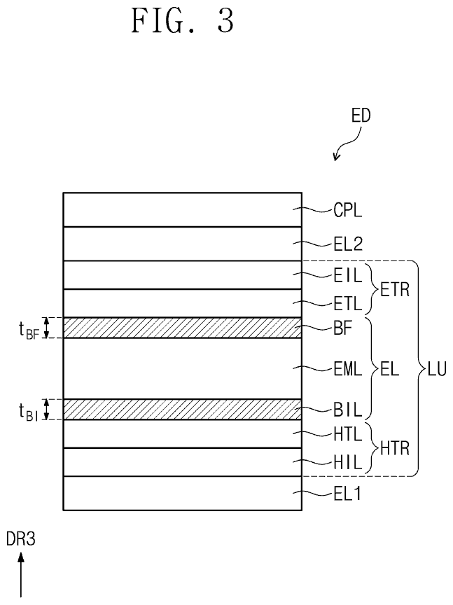

The display panel DP may include a base layer BS, a circuit layer DP-CL disposed on the base layer BS, and a display element layer DP-ED. The display element layer DP-ED may include the light emitting element ED. In an embodiment, the light emitting element ED may have a structure according to an embodiment, which will be described later with reference to FIG. 3. However, embodiments are not limited thereto.

In the display panel DP, the base layer BS may provide a base surface on which the circuit layer DP-CL is disposed. In an embodiment, the base layer BS may be a glass substrate, a metal substrate, a polymer substrate, or the like. However, embodiments are not limited thereto, and the base layer BS may include an inorganic layer, a functional layer, or a composite material layer.

The base layer BS may have a multilayered structure. For example, the base layer BS may have a three-layered structure that includes a polymer resin layer, an adhesive layer, and another polymer resin layer. For example, the polymer resin layer may include a polyimide-based resin. In embodiments, the polymer resin layer may include at least one of an acrylic resin, a methacrylic resin, a polyisoprene-based resin, a vinyl-based resin, an epoxy-based resin, a urethane-based resin, a cellulose-based resin, a siloxane-based resin, a polyamide-based resin, and a perylene-based resin. In the specification, a resin that is described as “a-based” may refer to a resin that is derived from a monomer that includes “a” as a functional group.

In an embodiment, the circuit layer DP-CL may be disposed on the base layer BS, and the circuit layer DP-CL may include transistors (not shown). The transistors (not shown) may each include a control electrode, an input electrode, and an output electrode. For example, the circuit layer DP-CL may include a switching transistor and a driving transistor for driving the light emitting element ED of the display element layer DP-ED.

The display element layer DP-ED may include the light emitting element ED. In an embodiment, the light emitting element ED may generate a source light. In an embodiment, the source light provided by the light emitting element ED may be light in a blue wavelength range. However, embodiments are not limited thereto. In an embodiment, the light emitting element ED may provide light in a blue wavelength range and light in a green wavelength range as a source light, or the light emitting element ED may provide white light as a source light.

The light emitting element ED may include a first electrode EL1, a hole transport region HTR, a light emitting portion EL, an electron transport region ETR, and a second electrode EL2, which may be stacked in a thickness direction that is parallel to the third direction DR3. In an embodiment, the light emitting element ED may further include a capping layer CPL disposed on the second electrode EL2.

The light emitting element ED included in the display device DD shown in FIG. 2 may provide a source light to the optical control panel OSL disposed on the display panel DP. For example, in the display device DD, the light emitting element ED may provide a first light as a source light to the optical control panel OSL, and the optical control panel OSL may transmit the source light or convert the wavelength of the source light. The light emitting element ED will be described in further detail below.

The display element layer DP-ED may include a pixel defining film PDL. An opening OH is defined between portions of the pixel defining film PDL. The opening OH may expose at least a portion of the first electrode EL1. In an embodiment, the pixel regions PXA-R, PXA-G, and PXA-B may each be defined by the openings OH.

In an embodiment, the pixel defining film PDL may be an organic layer. The pixel defining film PDL may be formed of a polymer resin. For example, the pixel defining film PDL may include a polyacrylate-based resin or a polyimide-based resin. In an embodiment, the pixel defining film PDL may be formed by further including an inorganic material, in addition to the polymer resin. In embodiments, the pixel defining film PDL may include a light absorbing material, or may include a black pigment or a black dye. A pixel defining film PDL that include a black pigment or a black dye may be implemented as a black pixel defining film PDL. When forming the pixel defining film PDL, carbon black may be used as the black pigment or black dye, but embodiments are not limited thereto.

In embodiments, the pixel defining film PDL may include an inorganic material. For example, the pixel defining film PDL may be formed of silicon nitride (SiNₓ), silicon oxide (SiOₓ), silicon oxynitride (SiOₓN_{y}), or the like.

The display element layer DP-ED may include an encapsulation layer TFE that protects the light emitting element ED. The encapsulation layer TFE may cover the display element layer DP-ED. The encapsulation layer TFE may be disposed on the light emitting element ED, and may be disposed to fill the openings OH. The encapsulation layer TFE be directly disposed on the light emitting element ED through a roll-to-roll process.

The encapsulation layer TFE may include an organic material or an inorganic material. The encapsulation layer TFE may have a single-layered structure or a multilayered structure. The encapsulation layer TFE may include at least one inorganic film (hereinafter, an encapsulation inorganic film). In an embodiment, the encapsulation layer TFE may include at least one organic film (hereinafter, an encapsulation organic film) and at least one encapsulation inorganic film. The encapsulation layer TFE may have a multilayered structure in which inorganic films and organic films are disposed in an alternating sequence.

The encapsulation inorganic film protects the display element layer DP-ED from moisture and/or oxygen, and the encapsulation organic film protects the display element layer DP-ED from foreign substances such as dust particles. The encapsulation inorganic film may include silicon nitride, silicon oxynitride, silicon oxide, titanium oxide, aluminum oxide, or the like, but embodiments are not limited thereto. The encapsulation organic film may include an acrylic compound, an epoxy-based compound, or the like. The encapsulation organic film may include a photopolymerizable organic material, but embodiments are not limited thereto.

The display device DD may include the optical control panel OSL disposed on the display panel DP, and the optical control panel OSL may include an optical control layer CCL that includes a light converter. The light converter may be a quantum dot or a phosphor. The light converter may convert the wavelength of a provided light and emit the resulting light. For example, the light control layer CCL may be a layer that includes quantum dots or a layer that includes phosphors.

The light control layer CCL may include light control parts CCP1, CCP2, and CCP3. The light control parts CCP1, CCP2, and CCP3 may be spaced apart from one another. In an embodiment, the light control parts CCP1, CCP2, and CCP3 may not overlap each other in a plan view.

Referring to FIG. 2, a division pattern BMP may be disposed between the light control parts CCP1, CCP2, and CCP3 that are spaced apart from one another, but embodiments are not limited thereto. In FIG. 2, it is shown that the division pattern BMP does not overlap the light control parts CCP1, CCP2, and CCP3, but the edges of the light control parts CCP1, CCP2, and CCP3 may overlap at least a portion of the division pattern BMP.

The light control layer CCL may include a first light control part CCP1 including a first quantum dot QD1 that converts first color light, which is a source light provided from the light emitting element ED, into second color light, a second light control part CCP2 including a second quantum dot QD2 that converts the first color light into third color light, and a third light control part CCP3 that transmits the first color light.

In an embodiment, the first light control part CCP1 may provide red light, which is the second color light, and the second light control part CCP2 may provide green light, which is the third color light. The third light control part CCP3 may provide blue light by transmitting the blue light that is the first color light provided from the light emitting element ED. In an embodiment, the first quantum dot QD1 may be a red quantum dot, and the second quantum dot QD2 may be a green quantum dot.

In the specification, a quantum dot may be a crystal of a semiconductor compound. In an embodiment, quantum dots, such as the first quantum dot QD1 and the second quantum dot QD2, may emit light of various emission wavelengths depending on the size of the crystals. In another embodiment, quantum dots, such as the first quantum dot QD1 and the second quantum dot QD2, may emit light of various emission wavelengths by adjusting an elemental ratio of a quantum dot compound.

The quantum dots may have a diameter, for example, in a range of about 1 nm to about 10 nm. The quantum dots may be synthesized through a wet chemical process, a metal organic chemical vapor deposition process, a molecular beam epitaxy process, or a process similar thereto.

Among the quantum dot manufacturing processes, the wet chemical process is a method of mixing an organic solvent and a precursor material and growing a quantum dot particle crystal. When the quantum dot particle crystal grows, the organic solvent naturally serves as a dispersant that is coordinated onto a surface of the quantum dot crystal and may control the growth of the particle crystal. Therefore, the wet chemical process may be more readily performed than vapor deposition methods such as metal organic chemical vapor deposition (MOCVD) or molecular beam epitaxy (MBE), and may control the growth of quantum dot particles through a low-cost process.

A quantum dot may include a Group II-VI compound, a Group III-V compound, a Group III-VI compound, a Group I-III-VI compound, a Group IV-VI compound, a Group IV element, a Group IV compound, or a combination thereof.

Examples of a Group II-VI compound may include: a binary compound such as CdSe, CdTe, CdS, ZnS, ZnSe, ZnTe, ZnO, HgS, HgSe, HgTe, MgSe, MgS, and a mixture thereof; a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; a quaternary compound such as HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof; and any combination thereof. In an embodiment, a Group II-VI compound may further include a Group I metal and/or a Group IV element. Examples of a Group I-II-VI compound may include CuSnS and CuZnS, and examples of a Group II-IV-VI compound may include ZnSnS and the like. Examples of a Group I-II-IV-VI compound may include a quaternary compound such as Cu₂ZnSnS₂, Cu₂ZnSnS₄, Cu₂ZnSnSe₄, Ag₂ZnSnS₂, and a mixture thereof.

Examples of a Group III-VI compound may include: a binary compound such as In₂S₃ and In₂Se₃; a ternary compound such as InGaS₃ and InGaSe₃; and any combination thereof.

Examples of a Group I-III-VI compound may include: a ternary compound such as AgInS, AgInS₂, CuInS, CuInS₂, AgGaS₂, CuGaS₂ CuGaO₂, AgGaO₂, AgAlO₂, and a mixture thereof; a quaternary compound such as AgInGaS₂ and CuInGaS₂; and any combination thereof.

Examples of a Group III-V compound may include: a binary compound such as GaN, GaP, GaAs, GaSb, AlN, AIP, AlAs, AlSb, InN, InP, InAs, InSb, and a mixture thereof; a ternary compound such as GaNP, GaNAs, GaNSb, GaPAs, GaPSb, AlNP, AlNAs, AlNSb, AlPAS, AlPSb, InGaP, InAlP, InNP, InNAs, InNSb, InPAs, InPSb, and a mixture thereof; a quaternary compound such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof; and any combination thereof. In an embodiment, a Group III-V compound may further include a Group II metal. Examples of a Group III-II-V compound may include InZnP and the like.

Examples of a Group IV-VI compound may include: a binary compound such as SnS, SnSe, SnTe, PbS, PbSe, PbTe, and a mixture thereof; a ternary compound such as SnSeS, SnSeTe, SnSTe, PbSeS, PbSeTe, PbSTe, SnPbS, SnPbSe, SnPbTe, and a mixture thereof; a quaternary compound such as SnPbSSe, SnPbSeTe, SnPbSTe, and a mixture thereof; and any combination thereof.

Examples of a Group II-IV-V compound may include a ternary compound such as ZnSnP, ZnSnP₂, ZnSnAs₂, ZnGeP₂, ZnGeAs₂, CdSnP₂, and CdGeP₂, and a mixture thereof.

Examples of a Group IV element may include Si, Ge, and a mixture thereof. Examples of a Group IV compound may include a binary compound such as SiC, SiGe, and a mixture thereof.

Each element included in a compound, such as a binary compound, a ternary compound, or a quaternary compound, may be present in a particle at a uniform concentration distribution or at a non-uniform concentration distribution. For example, a quantum dot formula may indicate the elements that are included in a quantum dot compound, but an elemental ratios of a quantum dot compound may vary.

In an embodiment, a quantum dot may have a single structure, in which the concentration distribution of each element included in the quantum dot is uniform. In another embodiment, a quantum dot may have a core/shell structure in which one quantum dot surrounds another quantum dot. In an embodiment, a material included in the core may be different from a material included in the shell. A quantum dot having a core/shell structure may have a concentration gradient in which the concentration of an element that is present in the shell decreases towards the core.

In embodiments, a quantum dot that has a core/shell structure as described above may include a core having nano-crystals and a shell surrounding the core. The shell of a quantum dot may serve as a protection layer that prevents chemical deformation of the core so as to maintain semiconductor properties, and/or may serve as a charging layer that imparts electrophoretic properties to a quantum dot. The shell may have a single-layered structure or a multilayered structure. Examples of a shell of a quantum dot may include a metal oxide, a non-metal oxide, a semiconductor compound, and any combination thereof.

Examples of a metal oxide or a non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, and a ternary compound such as MgAl₂O₄, CoFe₂O₄, NiFe₂O₄, and CoMn₂O₄, but embodiments are not limited thereto.

Examples of a semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, and AlSb, but embodiments are not limited thereto.

A quantum dot may have a full width at half maximum (FWHM) of an emission wavelength spectrum equal to or less than about 45 nm. For example, the quantum dot may have a FWHM of an emission wavelength spectrum equal to or less than about 40 nm. For example, the quantum dot may have a FWHM of an emission wavelength spectrum equal to or less than about 30 nm. Within any of the above ranges, color purity or color reproducibility may be improved. Light emitted through a quantum dot may be emitted in all directions, so that a wide viewing angle may be improved.

The form of a quantum dot is not particularly limited, and may be any shape that is used in the related art. For example, a quantum dot may have a spherical shape, a pyramidal shape, a multi-arm shape, or a cubic shape, a quantum dot may be in the form of nanoparticles, nanotubes, nanowires, nanofibers, nanoplatelets, or the like.

As a size of a quantum dot or an elemental ratio of a quantum dot compound is adjusted, an energy band gap may be accordingly controlled, so that light of various wavelengths may be obtained from a quantum dot emission layer. Therefore, by using the quantum dots as described above (using quantum dots of different sizes or having different element ratios in the quantum dot compound), a light emitting element that emits of light of various wavelengths may be implemented. For example, the size of a quantum dot or the elemental ratio of a quantum dot compound may be adjusted to emit red light, green light, and/or blue light. In an embodiment, quantum dots may be configured to emit white light by combining light of various colors.

In an embodiment, as a particle size of a quantum dot decreases, the quantum dot may emit light in a shorter wavelength range. For example, among quantum dots having a same core, a particle size of a quantum dot that emits green light may be smaller than a particle size of a quantum dot that emits red light. As another example, among quantum dots having a same core, a particle size of a quantum dot that emits blue light may be smaller than a particle size of a quantum dot that emits green light. However, embodiments are not limited thereto, and even among quantum dots having a same core, particle size may be controlled by adjusting a material of the shell and a thickness of the shell.

When quantum dots emit light of various colors, such as blue light, red light, or green light, quantum dots that have different light emission colors may each include different core materials.

In the light control layer CCL, the first light control part CCP1 may correspond to the first pixel region PXA-R, the second light control part CCP2 may correspond to the second pixel region PXA-G, and the third light control part CCP3 may correspond to the third pixel region PXA-B.

In an embodiment, the first light control part CCP1 may be referred to as a red light control part, the second light control part CCP2 may be referred to as a green light control part, and the third light control part CCP3 may be referred to as a blue light control part.

The first light control part CCP1, the second light control part CCP2, and the third light control part CCP3 may each include a base resin portion BR. In an embodiment, the first light control part CCP1, the second light control part CCP2, and the third light control part CCP3 may each further include a scatterer SP. In the first light control part CCP1, the first quantum dots QD1 and the scatterer SP may be dispersed in the base resin portion BR; in the second light control part CCP2, the second quantum dots QD2 and the scatterer SP may be dispersed in the base resin portion BR; and in the third light control part CCP3, the scatterer SP may be dispersed in the base resin portion BR.

In an embodiment, the third light control part CCP3 may not include quantum dots. However, embodiments are not limited thereto, and the third light control part CCP3 may include quantum dots that convert the wavelength of a source light into a wavelength range that is different from the first and second light control parts.

In an embodiment, the scatterer SP may uniformly scatter and emit light that is incidental to the light control parts CCP1, CCP2, and CCP3. The scatterer SP may scatter and emit a source light, or the scatterer SP may scatter and emit light in which the wavelength thereof has been converted from a source light.

The scatterer SP may have a spherical shape with a diameter in a range of several tens to several hundreds of nanometers (nm). In an embodiment, the scatterer SP may have a diameter in a range of about 50 nm to 300 nm. For example, the scatterer SP may have a diameter of about 200 nm.

The scatterer SP may include inorganic particles. For example, the scatterer SP may include TiO₂, BaTiO₃, ZnO, ZnS, Al₂O₃, SiO₂, hollow silica, or a combination thereof.

The base resin portion BR is a medium in which the quantum dots QD1 and QD2 and the scatterer SP are dispersed, and may include various compositions, which may be referred to as a binder. For example, the base resin portion BR may be an acrylate-based resin, a urethane-based resin, a silicone-based resin, or an epoxy-based resin. The base resin portion BR included in the first to third light control parts CCP1, CCP2, and CCP3 may be the same as each other, or at least one light control part may include a base resin portion that is different from the other light control parts.

The light control layer CCL may include a barrier layer BFL1. The barrier layer BFL1 may prevent the penetration of moisture and/or oxygen (hereinafter referred to as “moisture/oxygen”) into the display device DD. The barrier layer BFL1 may be disposed on the light control parts CCP1, CCP2, and CCP3 to prevent the light control parts CCP1, CCP2, and CCP3 from exposure to moisture/oxygen. The barrier layer BFL1 may cover the light control parts CCP1, CCP2, and CCP3.

The optical control panel OSL may further include a color filter layer CFL. The color filter layer CFL may be disposed on the light control layer CCL. The color filter layer CFL may include filters CF1, CF2, and CF3. For example, the color filter layer CFL may include a first filter CF1 that transmits second color light, a second filter CF2 that transmits third color light, and a third filter CF3 that transmits first color light. For example, the first filter CF1 may be a red filter, the second filter CF2 may be a green filter, and the third filter CF3 may be a blue filter. The filters CF1, CF2, and CF3 may each include a polymer photosensitive resin and a pigment or a dye. The first filter CF1 may include a red pigment or a red dye, the second filter CF2 may include a green pigment or a green dye, and the third filter CF3 may include a blue pigment or a blue dye.

However, embodiments are not limited thereto, and the third filter CF3 may not include a pigment or a dye. The third filter CF3 may include a polymer photosensitive resin, and may not include a pigment or a dye. The third filter CF3 may be transparent. The third filter CF3 may be formed of a transparent photosensitive resin.

In an embodiment, the first filter CF1 and the second filter CF2 may each be a yellow filter. The first filter CF1 and the second filter CF2 may not be provided as separate filters and may be provided as a unitary filter.

Although not shown in the drawings, in an embodiment, the color filter layer CFL may further include a light blocking unit (not shown). The light blocking unit (not shown) may be a black matrix. The light blocking unit (not shown) may include an organic light blocking material or an inorganic light blocking material, each including a black pigment or a black dye. The light blocking unit (not shown) may prevent light leakage and may separate the boundaries between adjacent filters CF1, CF2, and CF₃. In an embodiment, the light blocking unit (not shown) may be formed of a blue filter.

The first to third filters CF1, CF2, and CF3 may respectively correspond to the first pixel region PXA-R, the second pixel region PXA-G, and the third pixel region PXA-B.

The color filter layer CFL may further include a barrier layer BFL2. The barrier layer BFL2 may be disposed between the light control layer CCL and the filters CF1, CF2, and CF3.

The barrier layers BFL1 and BFL2 may each independently include at least one inorganic layer. For example, the barrier layers BFL1 and BFL2 may each be formed of an inorganic material. For example, the barrier layers BFL1 and BFL2 may each independently include silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, a metal thin film that secures light transmittance, or the like. The barrier layers BFL1 and BFL2 may each further include an organic film. The barrier layers BFL1 and BFL2 may each have a single-layered structure or a multilayered structure.

The base substrate BL may be disposed on the color filter layer CFL. The base substrate BL may provide a base surface on which the color filter layer CFL and the light control layer CCL are disposed. The base substrate BL may be a glass substrate, a metal substrate, a plastic substrate, or the like. However, embodiments are not limited thereto, and the base substrate BL may include an inorganic layer, an organic layer, or a composite material layer. Although not shown in the drawings, in an embodiment, the base substrate BL may be omitted.

FIG. 3 is a schematic cross-sectional view of a light emitting element according to an embodiment. The light emitting element ED may include a first electrode EL1, a second electrode EL2 facing the first electrode EL1, and at least one light emitting structure LU disposed between the first electrode EL1 and the second electrode EL2. The light emitting structure LU may include a hole transport region HTR, a light emitting portion EL, and an electron transport region ETR. In an embodiment, the light emitting portion EL may include an emission layer EML, and buffer layers BIL and BF, which are each disposed adjacent to the emission layer EML. In an embodiment, the light emitting element ED may include a capping layer CPL disposed on the second electrode EL2.

Referring to FIG. 3, in the light emitting element ED, the light emitting portion EL may include the emission layer EML, the first buffer layer BIL disposed between the emission layer EML and the hole transport region HTR, and the second buffer layer BF disposed between the emission layer EML and the electron transport region ETR. In an embodiment, the first buffer layer BIL may be disposed directly below the emission layer EML, and the second buffer layer BF may be disposed directly above the emission layer EML.

In the light emitting element ED, the first electrode EL1 has conductivity. The first electrode EL1 may be formed of a metal material, a metal alloy, or a conductive compound. The first electrode EL1 may be an anode or a cathode. However, embodiments are not limited thereto. In an embodiment, the first electrode EL1 may be a pixel electrode. The first electrode EL1 may be a transmissive electrode, a transflective electrode, or a reflective electrode. The first electrode may include at least one of Ag, Mg, Cu, Al, Pt, Pd, Au, Ni, Nd, Ir, Cr, Li, Ca, LiF, Mo, Ti, W, In, Sn, Zn, an oxide thereof, a compound thereof, and a mixture thereof.

When the first electrode EL1 is a transmissive electrode, the first electrode EL1 may include a transparent metal oxide such as indium tin oxide (ITO), indium zinc oxide (IZO), zinc oxide (ZnO), and indium tin zinc oxide (ITZO). When the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stack structure of LiF and Ca), LiF/Al (a stack structure of LiF and Al), Mo, Ti, W, a compound thereof, or a mixture thereof (e.g., a mixture of Ag and Mg). In another embodiment, the first electrode EL1 may have a multilayered structure that includes a reflective film or a transflective film formed of the above-described materials, and a transparent conductive film formed of indium tin oxide (ITO), indium zinc oxide (IZO), zinc oxide (ZnO), indium tin zinc oxide (ITZO), or the like. For example, the first electrode EL1 may have a three-layered structure of ITO/Ag/ITO, but embodiments are not limited thereto. In an embodiment, the first electrode EL1 may include the above-described metal materials, a combination of two or more of the above-described metal materials, or oxides of the above-described metal materials. The first electrode EL1 may have a thickness in a range of about 700 Å to about 10,000 Å. For example, the first electrode EL1 may have a thickness in a range of 1,000 Å to about 3,000 Å.

The hole transport region HTR may be provided on the first electrode EL1. The hole transport region HTR may have a structure consisting of a layer consisting of a single material, a structure consisting of a layer including different materials, or a structure including multiple layers including different materials.

For example, the hole transport region HTR may have a single-layered structure consisting of a hole injection layer HIL or a hole transport layer HTL, or may have a single-layered structure formed of a hole injection material and a hole transport material. The hole transport region HTR may have a single-layered structure including different materials or may have a multilayered structure including multiple layers stacked from the first electrode EL1.

Referring to FIG. 3, in an embodiment, the hole transport region HTR may include a hole injection layer HIL and a hole transport layer HTL. However, embodiments are not limited thereto. In an embodiment, the hole transport region HTR may include a hole transport layer HTL having a single-layered structure, or may include a hole transport layer HTL having a multilayered structure. In embodiments, the hole transport region HTR may further include an auxiliary emission layer that compensates for a resonance distance according to a wavelength of light emitted from the light emitting portion EL or that regulates a hole charge balance, or the hole transport region HTR may further include an electron blocking layer that prevents electron injection.

The hole transport region HTR may have a thickness in a range of about 50 Å to about 15,000 Å. The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

The hole transport region HTR may include a phthalocyanine compound such as copper phthalocyanine, N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino] triphenylamine (m-MTDATA), 4,4′4″-tris(N,N-diphenylamino)triphenylamine (TDATA), 4,4′,4″-tris [N (2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonicacid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium tetrakis(pentafluorophenyl) borate, dipyrazino[2,3-f: 2′,3′-h]quinoxaline-2,3,6,7,10,11-hexacarbonitrile (HATCN), or the like.

The hole transport region HTR may include a carbazole-based derivative such as N-phenyl carbazole and polyvinyl carbazole, a fluorene-based derivative, N,N′-bis(3-methylphenyl)-N,N′-diphenyl-[1,1-biphenyl]-4,4′-diamine (TPD), a triphenylamine-based derivative such as 4,4,4-tris (N-carbazolyl)triphenylamine (TCTA), N,N-di (1-naphtalene-1-yl)-N,N′-diphenyl-benzidine (NPB), 4,4′-cyclohexylidene bis[N,N-bis(4-methylphenyl]benzenamine] (TAPC), 4,4-bis [N,N′-(3-tolyl)amino]-3,3-dimethylbiphenyl (HMTPD), and 1,3-bis(N-carbazolyl)benzene (mCP), or the like.

In an embodiment, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), or the like.

In the light emitting element ED according to an embodiment, the light emitting portion EL is provided between the hole transport region HTR and the electron transport region ETR. The light emitting portion EL may include the first buffer layer BIL, the emission layer EML, and the second buffer layer BF. The light emitting element ED included in the display device DD shown in FIG. 2 may emit blue light. For example, in the light emitting element ED, the light emitting portion EL may emit blue fluorescence. However, embodiments are not limited thereto, and the light emitting element ED may emit light in a wavelength range other than blue light.

The emission layer EML included in the light emitting portion EL may have a structure consisting of a layer consisting of a single material, a structure consisting of a layer including different materials, or a structure including multiple layers including different materials. The emission layer EML may have a thickness in a range of about 50 Å to about 1,000 Å. For example, the emission layer EML may have a thickness in a range of about 50 Å to about 200 Å. For example, the emission layer EML may have a thickness in a range of about 100 Å to about 200 Å.

In an embodiment, the emission layer EML may include two different host materials, a phosphorescent sensitizer, and a light emitting dopant. For example, the emission layer EML may include a hole transporting host, an electron transporting host, a phosphorescent sensitizer, and a light emitting dopant.

In an embodiment, the first buffer layer BIL may be disposed between the emission layer EML and the hole transport region HTR. For example, the first buffer layer BIL may be directly disposed between the emission layer EML and the hole transport region HTR. When the hole transport region HTR includes a hole injection layer HIL and a hole transport layer HTL that are stacked in a thickness direction, the first buffer layer BIL may be directly disposed between the hole transport layer HTL and the emission layer EML.

The first buffer layer BIL may include a hole transporting host, a phosphorescent sensitizer, and a light emitting dopant. In contrast to the emission layer EML, the first buffer layer BIL may not include an electron transporting host. In an embodiment, the hole transporting host, the phosphorescent sensitizer, and the light emitting dopant included in the first buffer layer BIL may be respectively the same as the hole transporting host, the phosphorescent sensitizer, and the light emitting dopant included in the emission layer EML. However, embodiments are not limited thereto.

The hole transport region HTR, which is disposed adjacent to the first buffer layer BIL, includes a hole transport material as described above, and may not include the phosphorescent sensitizer and the light emitting dopant that are included in the first buffer layer BIL.

In an embodiment, the second buffer layer BF may be disposed between the emission layer EML and the electron transport region ETR. For example, the second buffer layer BF may be directly disposed between the emission layer EML and the electron transport region ETR. When the electron transport region ETR includes an electron transport layer ETL and an electron injection layer EIL that are stacked in a thickness direction, the second buffer layer BF may be directly disposed between the electron transport layer ETL and the emission layer EML.

The second buffer layer BF may include an electron transporting host, a phosphorescent sensitizer, and a light emitting dopant. In contrast to the emission layer EML, the second buffer layer BF may not include a hole transporting host. In an embodiment, the electron transporting host, the phosphorescent sensitizer, and the light emitting dopant included in the second buffer layer BF may be respectively the same as the electron transporting host, the phosphorescent sensitizer, and the light emitting dopant included in the emission layer EML. However, embodiments are not limited thereto.

The electron transport region ETR, which is disposed adjacent to the second buffer layer BF, includes an electron transport material as described above, and may not include the phosphorescent sensitizer and the light emitting dopant that are included in the second buffer layer BF.

In an embodiment, in the light emitting portion EL of the light emitting element ED, the emission layer EML may consist of the hole transporting host, the electron transporting host, the phosphorescent sensitizer, and the light emitting dopant, the first buffer layer BIL may consist of the hole transporting host, the phosphorescent sensitizer, and the light emitting dopant, the second buffer layer BF may consist of the electron transporting host, the phosphorescent sensitizer, and the light emitting dopant, and the hole transport region HTR and the electron transport region ETR, which are each adjacent to the light emitting portion EL, may each not include the phosphorescent sensitizer and the light emitting dopant.

In an embodiment, the hole transporting host may include a compound represented by Formula HT-1:

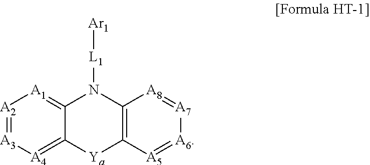

In Formula HT-1, A₁ to A₈ may each independently be N or C(R₅₁). For example, A₁ to A₈ may each independently be C(R₅₁). As another example, one of A₁ to A₈ may be N, and the remainder of A₁ to A₈ may each independently be C(R₅₁).

In Formula HT-1, L₁ may be a direct linkage, a substituted or unsubstituted arylene group having 6 to 30 ring-forming carbon atoms, or a substituted or unsubstituted heteroarylene group having 2 to 30 ring-forming carbon atoms. For example, L₁ may be a direct linkage, a substituted or unsubstituted phenylene group, a substituted or unsubstituted divalent biphenyl group, a substituted or unsubstituted divalent carbazole group, or the like, but embodiments are not limited thereto.

In Formula HT-1, Yₐ may be a direct linkage, C(R₅₂)(R₅₃), or Si(R₅₄)(R₅₅). For example, the two benzene rings that are connected to the nitrogen atom in Formula HT-1 may be connected to each other through a direct linkage,

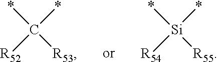

In Formula HT-1, when Yₐ is a direct linkage, a hole transporting host represented by Formula HT-1 may include a carbazole moiety.

In Formula HT-1, Ar₁ may be a substituted or unsubstituted aryl group having 6 to 30 ring-forming carbon atoms or a substituted or unsubstituted heteroaryl group having 2 to 30 ring-forming carbon atoms. For example, Ar₁ may be a substituted or unsubstituted carbazole group, a substituted or unsubstituted dibenzofuran group, a substituted or unsubstituted dibenzothiophene group, or a substituted or unsubstituted biphenyl group, but embodiments are not limited thereto.

In Formula HT-1, R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 ring-forming carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring. For example, R₅₁ to R₅₅ may each independently be a hydrogen atom or a deuterium atom. For example, R₅₁ to R₅₅ may each independently be an unsubstituted methyl group or an unsubstituted phenyl group.

In an embodiment, in the light emitting element ED, the hole transporting host may include at least one compound selected from Compound Group 1:

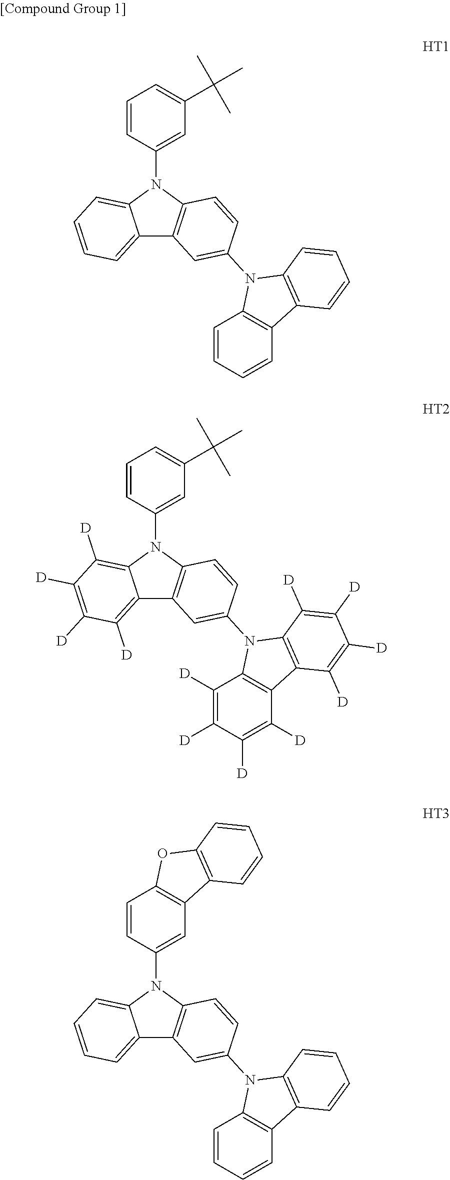 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

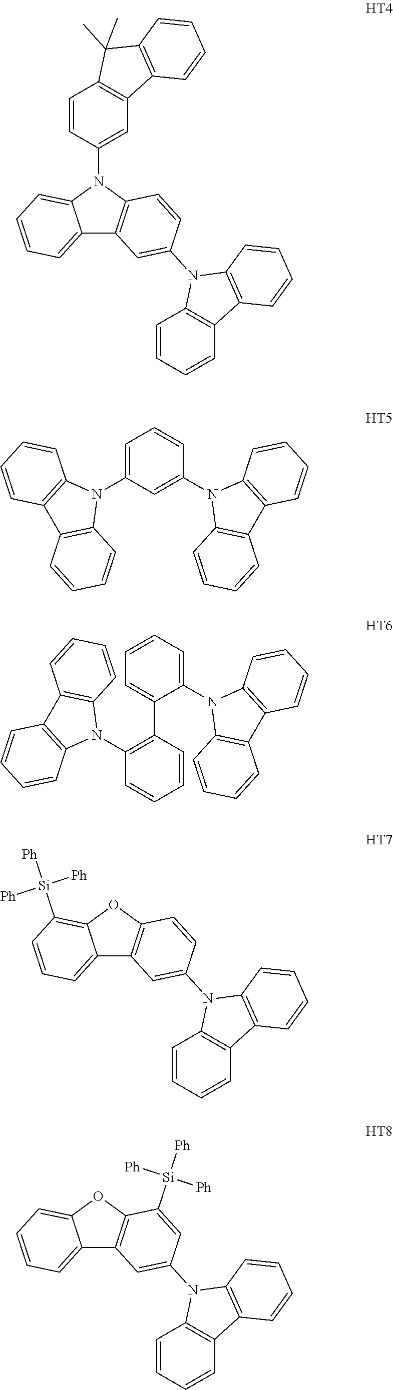 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1 ; c1ccc([Si](c2ccccc2)(c2ccccc2)c2cc(-n3c4ccccc4c4ccccc43)cc3c2oc2ccccc23)cc1]

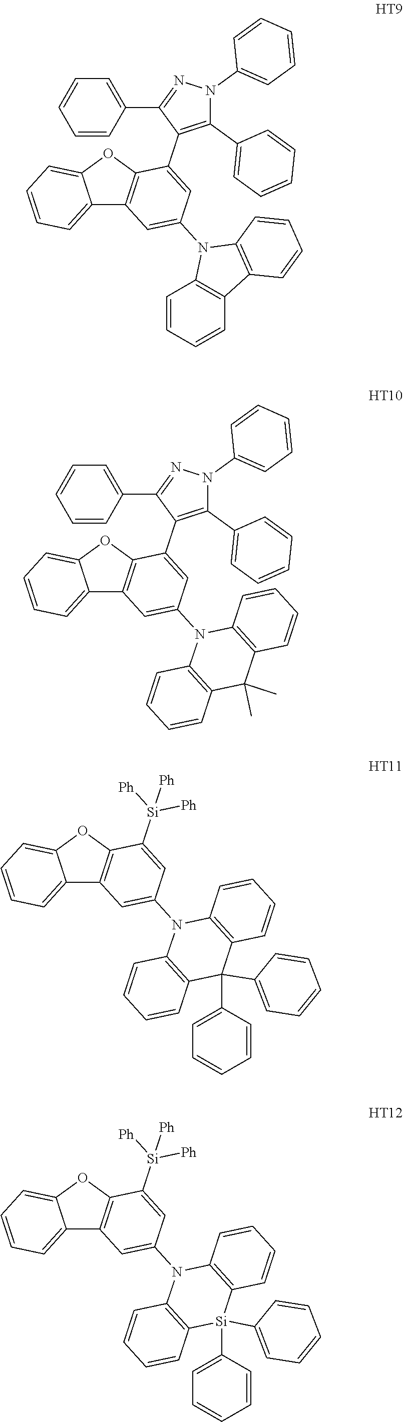 [SMILES: c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1 ; c1ccc([Si]2(c3ccccc3)c3ccccc3N(c3cc([Si](c4ccccc4)(c4ccccc4)c4ccccc4)c4oc5ccccc5c4c3)c3ccccc32)cc1]

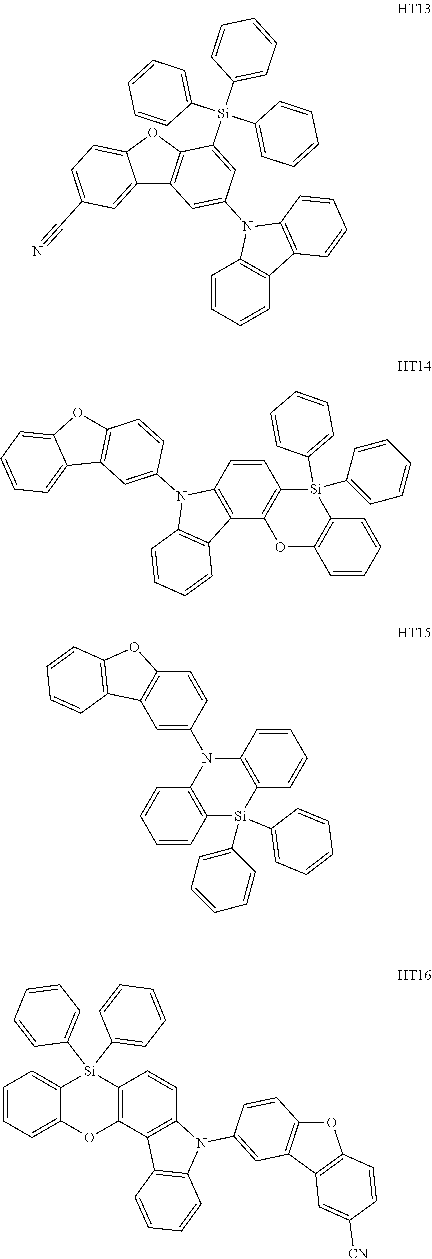 [SMILES: N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1]

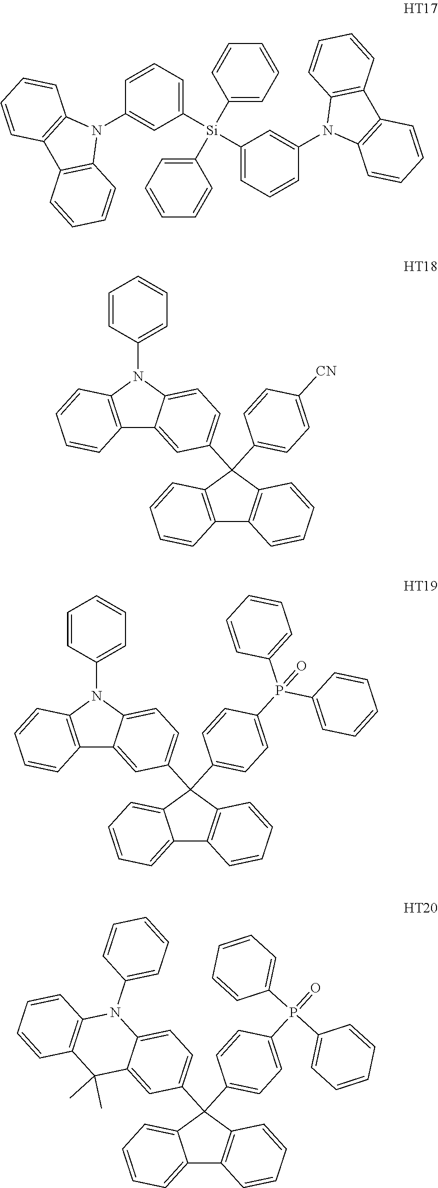 [SMILES: c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21]

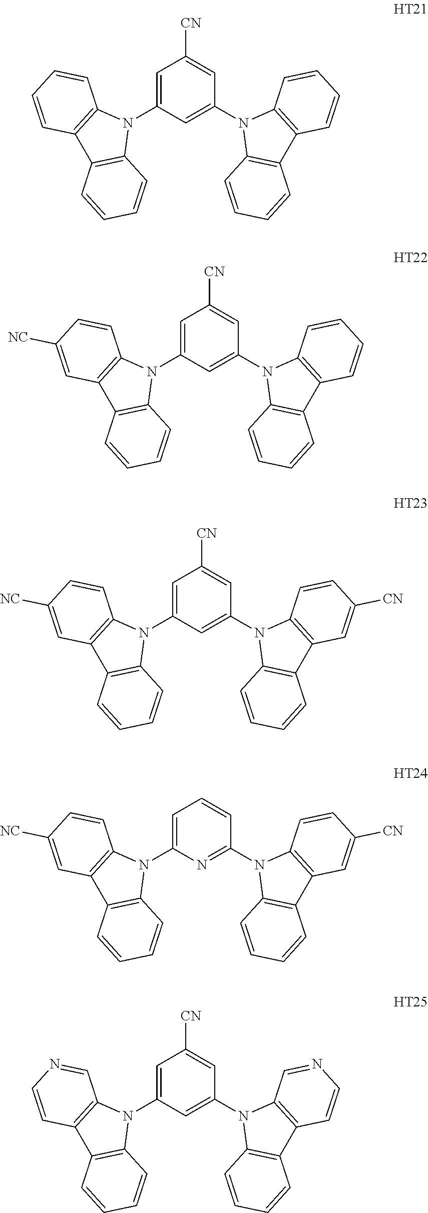 [SMILES: N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1]

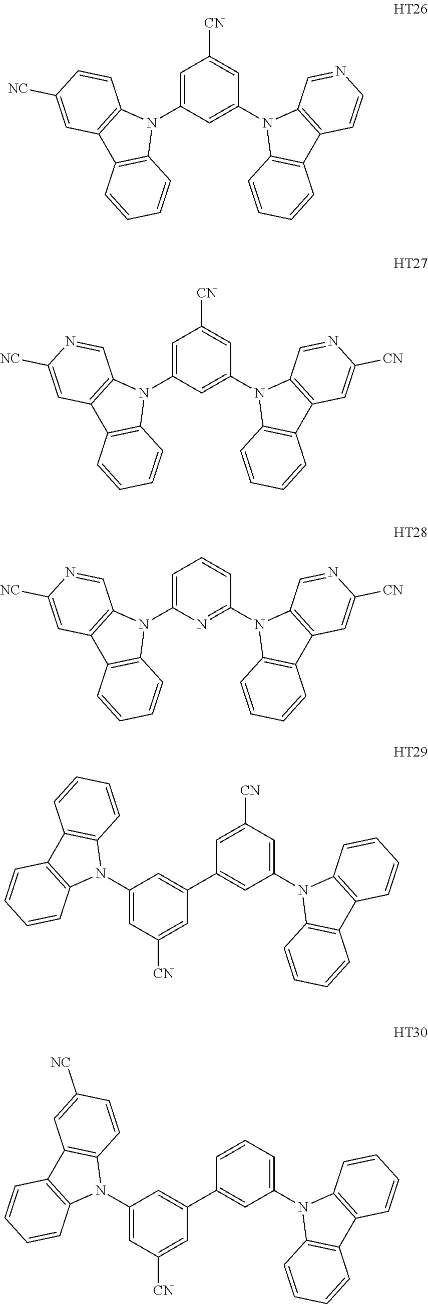 [SMILES: N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1]

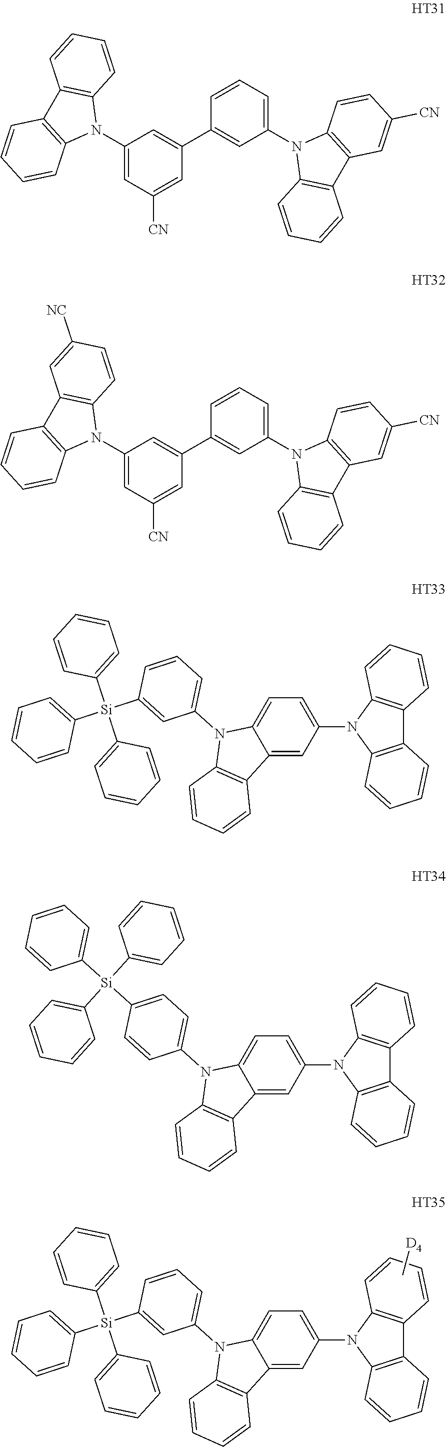

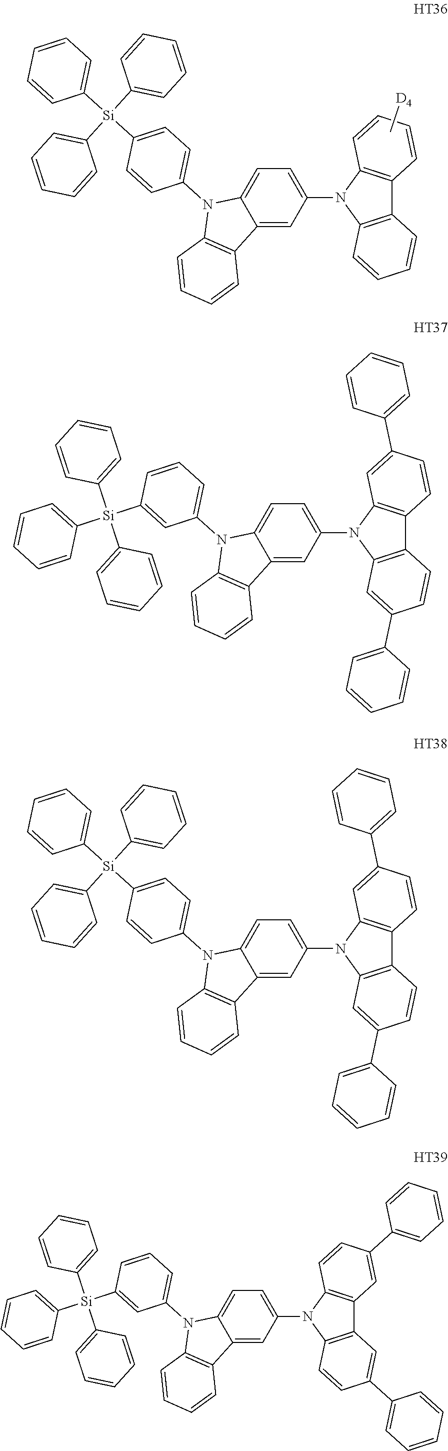

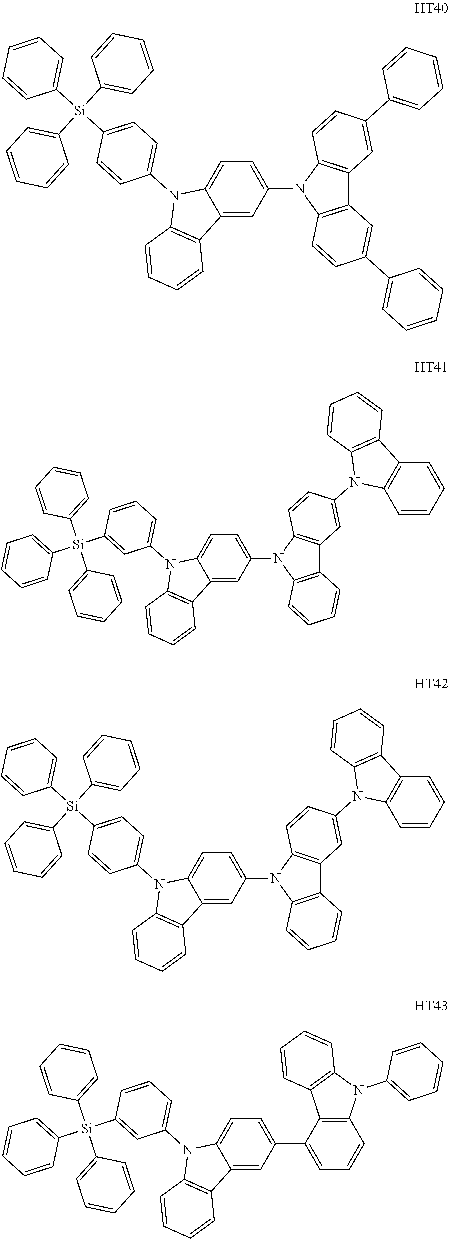 [SMILES: c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1 ; c1ccc(-n2c3ccccc3c3c(-c4ccc5c(c4)c4ccccc4n5-c4cccc([Si](c5ccccc5)(c5ccccc5)c5ccccc5)c4)cccc32)cc1]

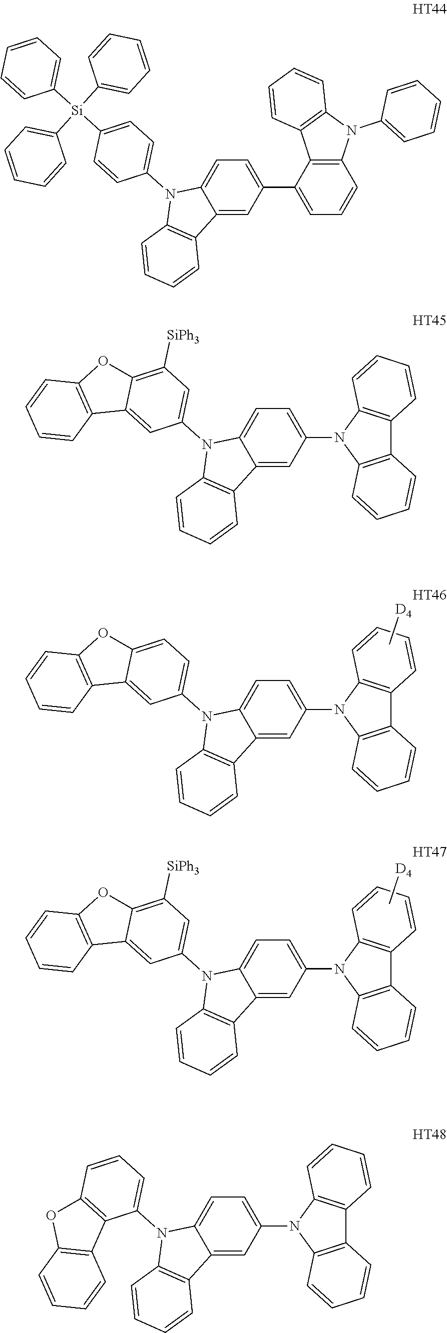

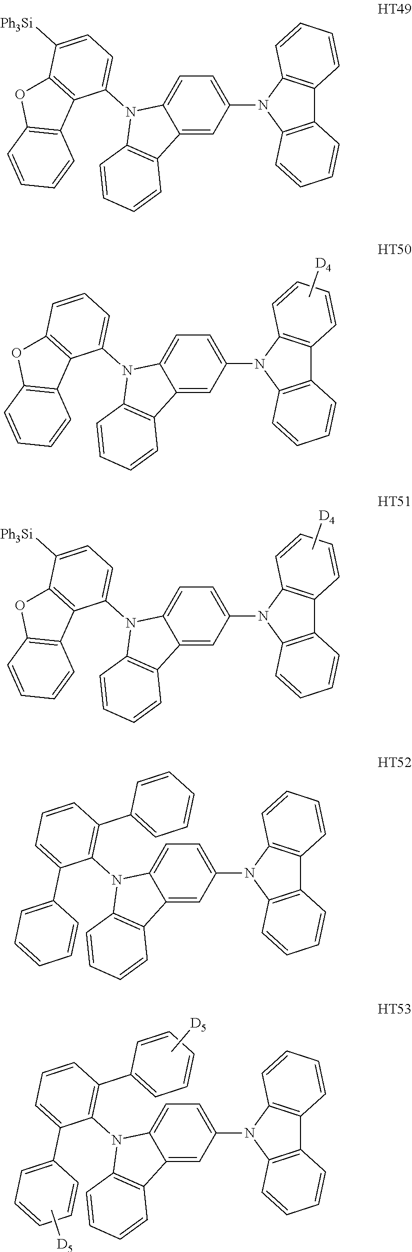

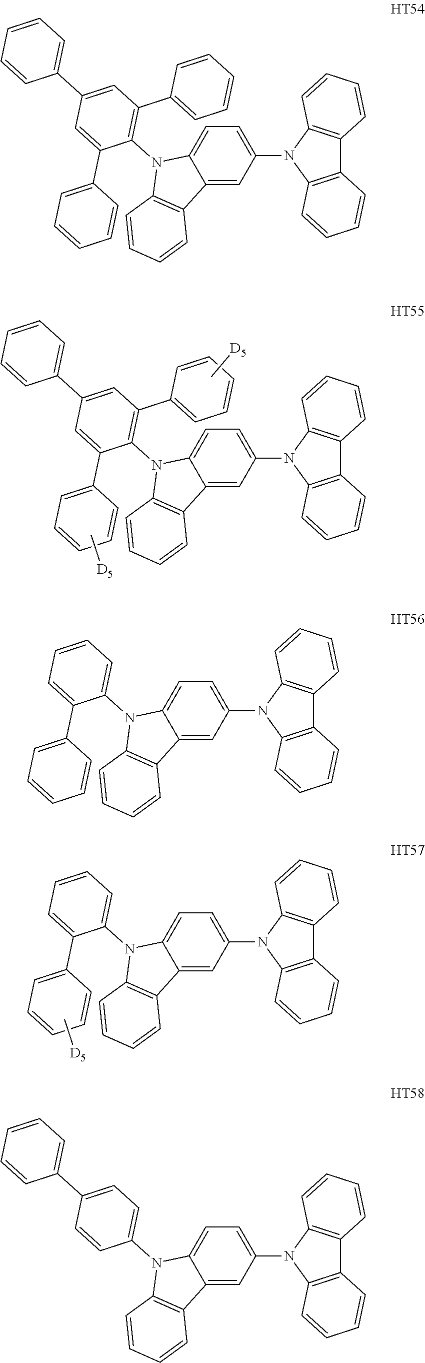

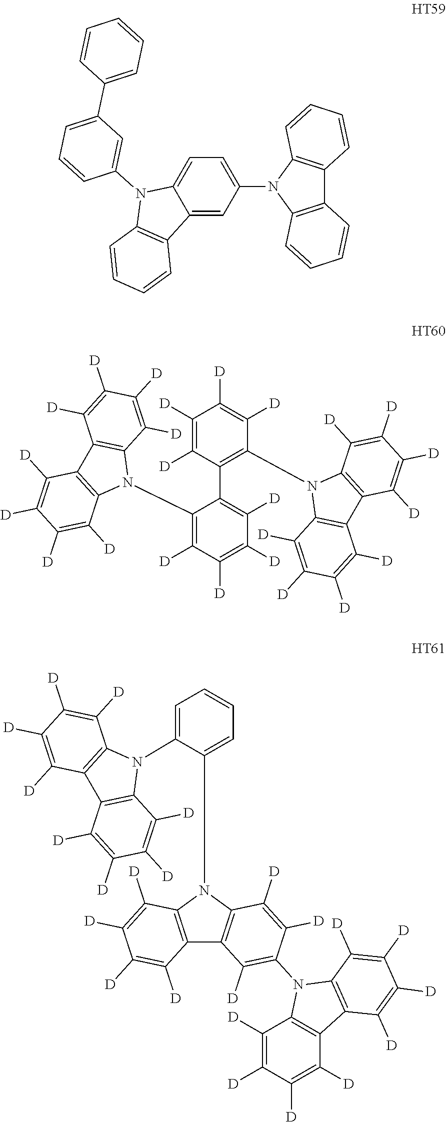 [SMILES: c1ccc(-c2cccc(-n3c4ccccc4c4cc(-n5c6ccccc6c6ccccc65)ccc43)c2)cc1 ; [2H]c1c([2H])c([2H])c(-n2c3c([2H])c([2H])c([2H])c([2H])c3c3c([2H])c([2H])c([2H])c([2H])c32)c(-c2c([2H])c([2H])c([2H])c([2H])c2-n2c3c([2H])c([2H])c([2H])c([2H])c3c3c([2H])c([2H])c([2H])c([2H])c32)c1[2H] ; [2H]c1c([2H])c([2H])c2c(c1[2H])c1c([2H])c([2H])c([2H])c([2H])c1n2-c1ccccc1-n1c2c([2H])c([2H])c([2H])c([2H])c2c2c([2H])c(-n3c4c([2H])c([2H])c([2H])c([2H])c4c4c([2H])c([2H])c([2H])c([2H])c43)c([2H])c([2H])c21]

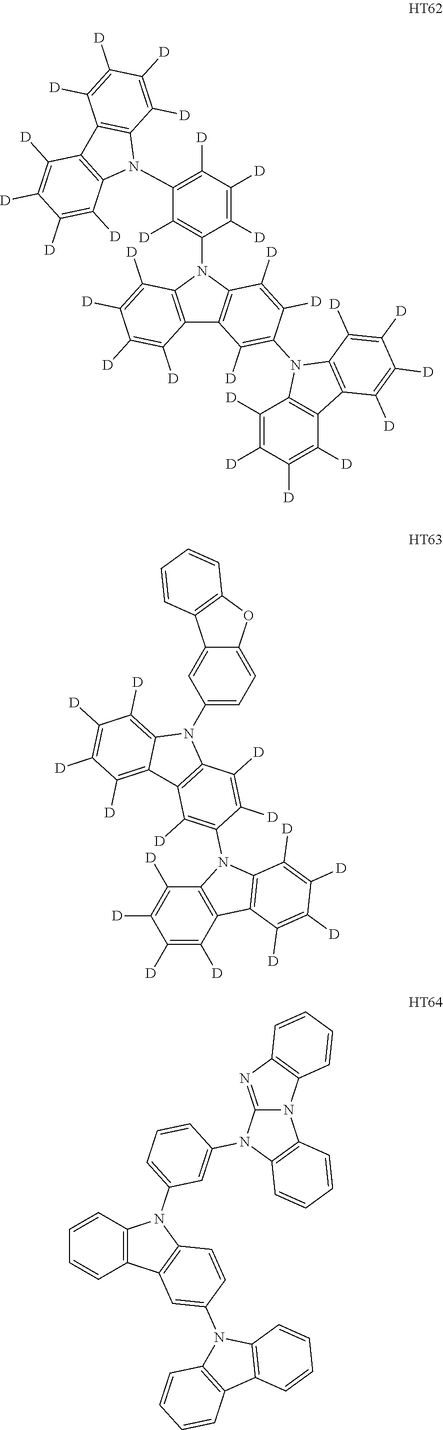 [SMILES: [2H]c1c([2H])c(-n2c3c([2H])c([2H])c([2H])c([2H])c3c3c([2H])c([2H])c([2H])c([2H])c32)c([2H])c(-n2c3c([2H])c([2H])c([2H])c([2H])c3c3c([2H])c(-n4c5c([2H])c([2H])c([2H])c([2H])c5c5c([2H])c([2H])c([2H])c([2H])c54)c([2H])c([2H])c32)c1[2H] ; [2H]c1c([2H])c([2H])c2c(c1[2H])c1c([2H])c(-n3c4c([2H])c([2H])c([2H])c([2H])c4c4c([2H])c([2H])c([2H])c([2H])c43)c([2H])c([2H])c1n2-c1ccc2oc3ccccc3c2c1 ; c1cc(-n2c3ccccc3c3cc(-n4c5ccccc5c5ccccc54)ccc32)cc(-n2c3ccccc3n3c4ccccc4nc23)c1]

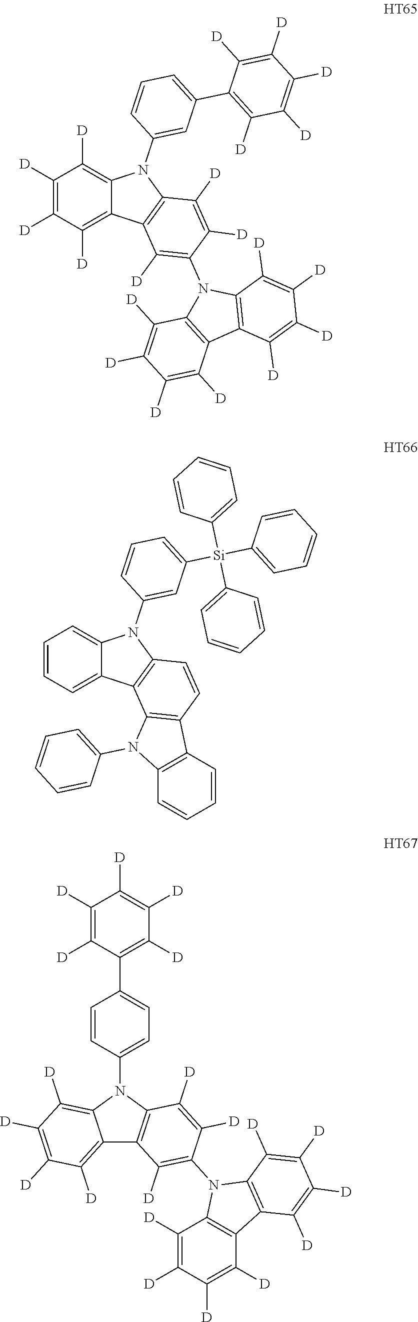 [SMILES: [2H]c1c([2H])c([2H])c(-c2cccc(-n3c4c([2H])c([2H])c([2H])c([2H])c4c4c([2H])c(-n5c6c([2H])c([2H])c([2H])c([2H])c6c6c([2H])c([2H])c([2H])c([2H])c65)c([2H])c([2H])c43)c2)c([2H])c1[2H] ; c1ccc(-n2c3ccccc3c3ccc4c(c5ccccc5n4-c4cccc([Si](c5ccccc5)(c5ccccc5)c5ccccc5)c4)c32)cc1 ; [2H]c1c([2H])c([2H])c(-c2ccc(-n3c4c([2H])c([2H])c([2H])c([2H])c4c4c([2H])c(-n5c6c([2H])c([2H])c([2H])c([2H])c6c6c([2H])c([2H])c([2H])c([2H])c65)c([2H])c([2H])c43)cc2)c([2H])c1[2H]]

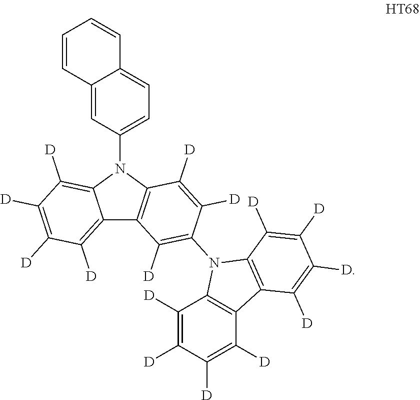

In Compound Group 1, D represents a deuterium atom, and Ph represents an unsubstituted phenyl group.

In an embodiment, the electron transporting host may include a compound represented by Formula ET-1:

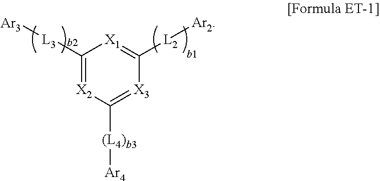

In Formula ET-1, at least one of X₁, X₂, and X₃ may be N and the remainder of X₁, X₂, and X₃ may each independently be C(R₅₆). For example, one of X₁ to X₃ may be N, and the remainder of X₁ to X₃ may each independently be C(R₅₆). Thus, the electron transporting host represented by Formula ET-1 may include a pyridine moiety. As another example, two of X₁ to X₃ may be N, and the remainder of X₁ to X₃ may be C(R₅₆). Thus, the electron transporting host represented by Formula ET-1 may include a pyrimidine moiety. As yet another example, X₁ to X₃ may each be N. Thus, the electron transporting host represented by Formula ET-1 may include a triazine moiety.

In Formula ET-1, R₅₆ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

In Formula ET-1, b1 to b3 may each independently be an integer from 0 to 10.

In Formula ET-1, Ar₂ to Ar₄ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Ar₂ to Ar₄ may each independently be a substituted or unsubstituted phenyl group or a substituted or unsubstituted carbazole group.

In Formula ET-1, L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms. When bl to b3 are each 2 or greater, multiple groups of each of L₂ to L₄ may each independently be a substituted or unsubstituted arylene group having 6 to 30 ring-forming carbon atoms or a substituted or unsubstituted heteroarylene group having 2 to 30 ring-forming carbon atoms.

In an embodiment, in the light emitting element ED, the electron transporting host may include at least one compound selected from Compound Group 2:

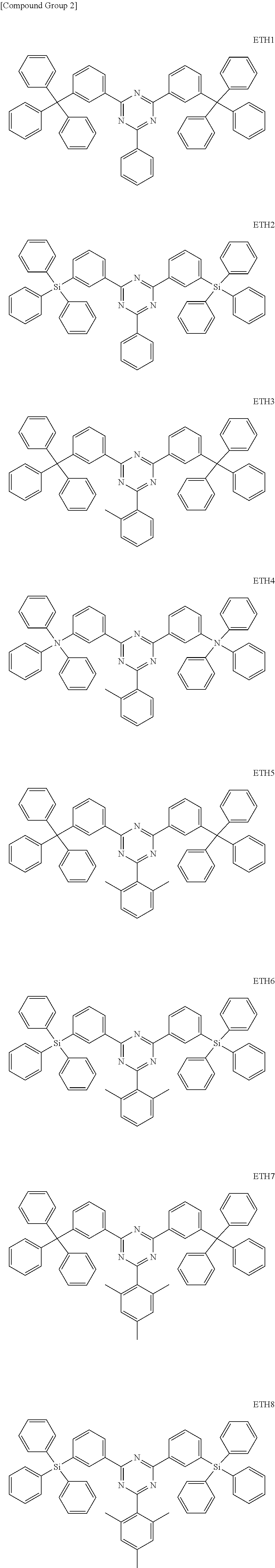

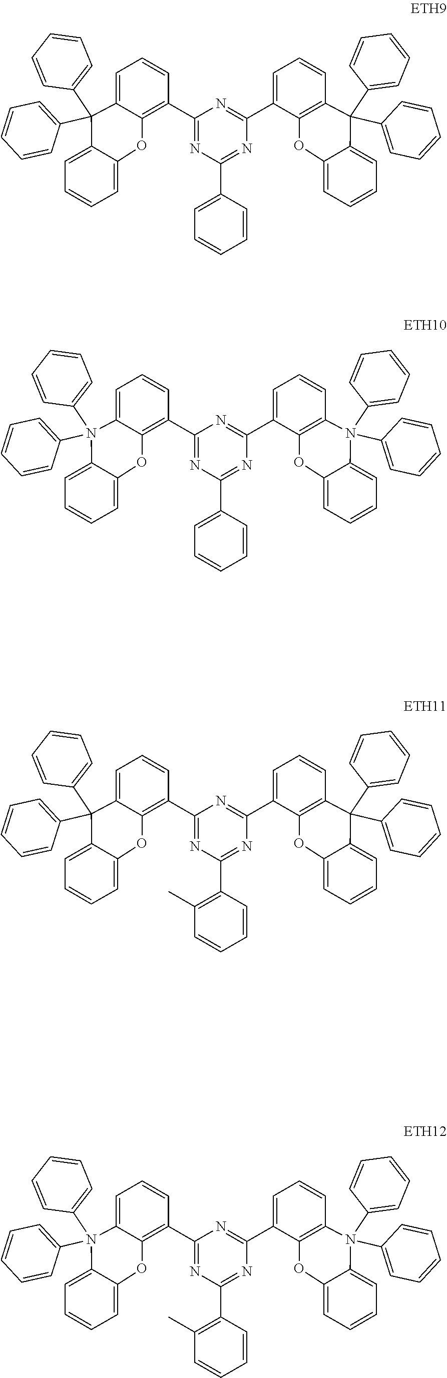

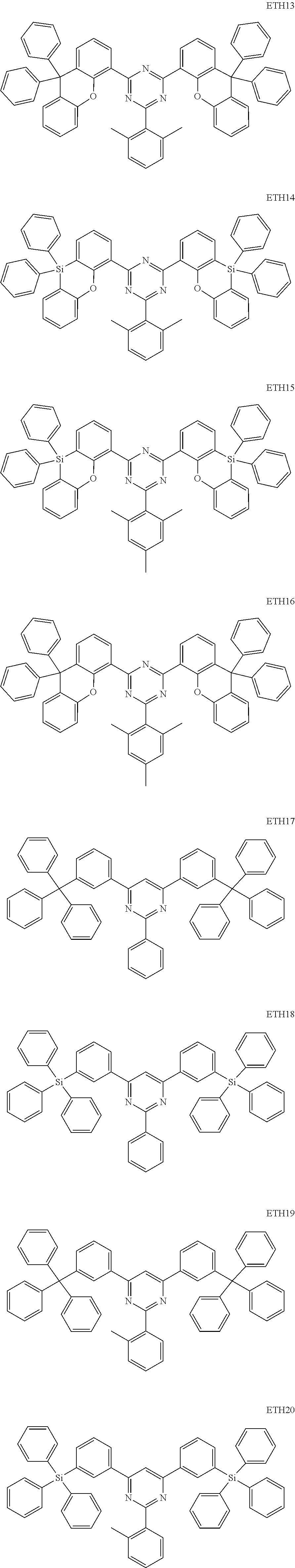

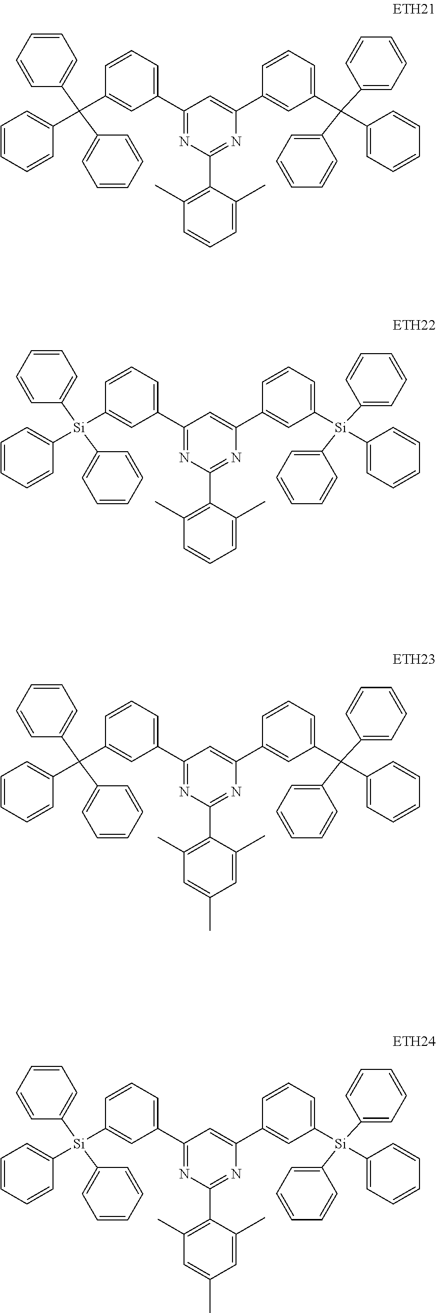 [SMILES: Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1]

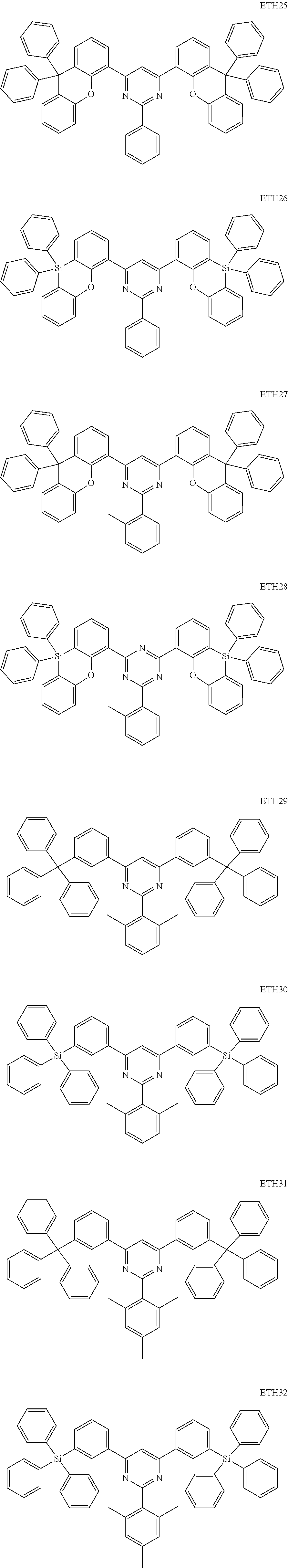

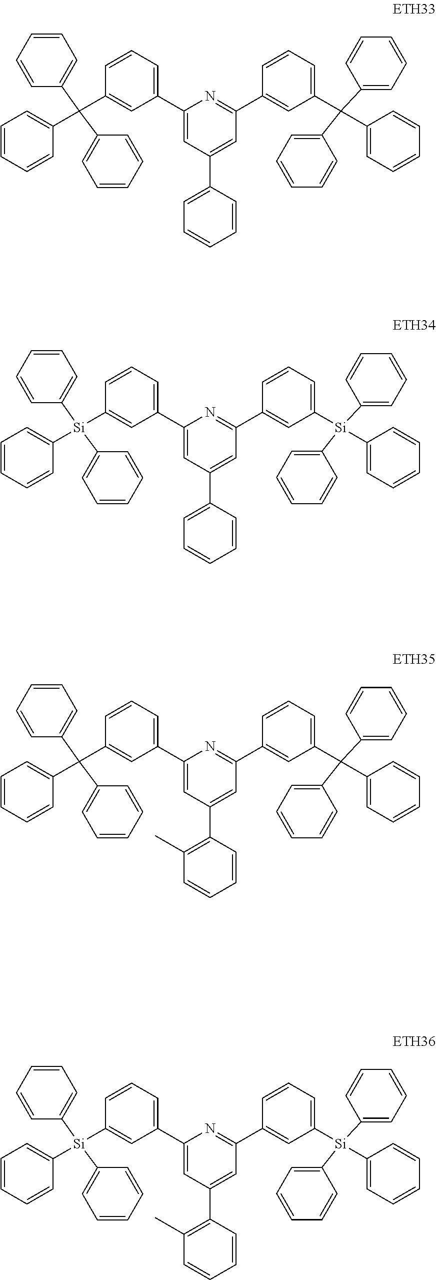 [SMILES: c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1]

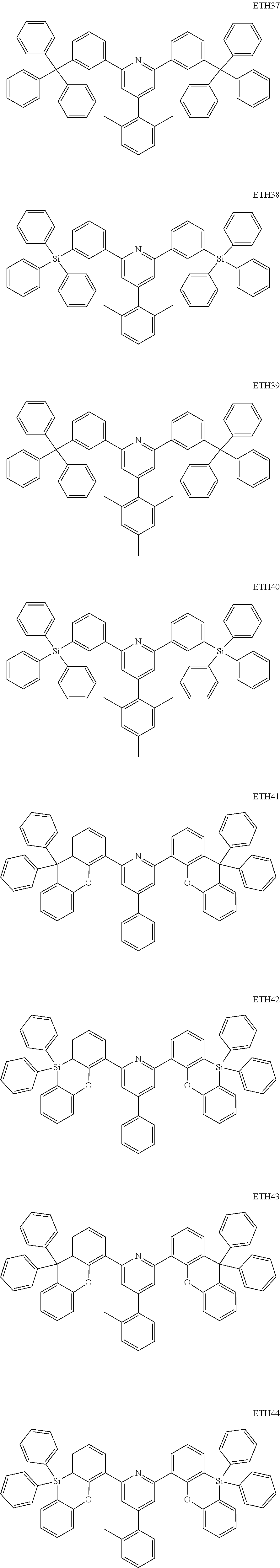

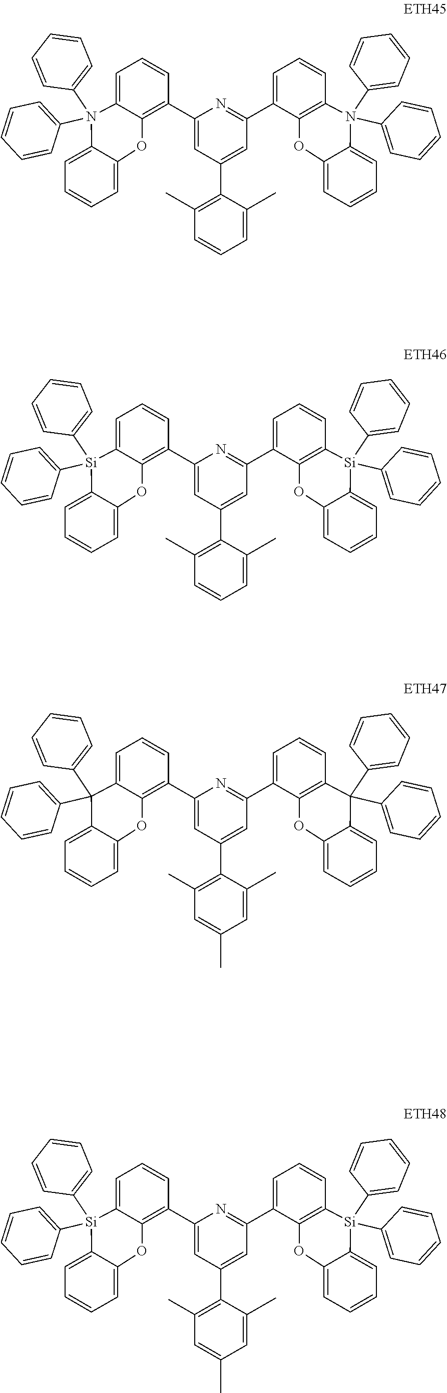

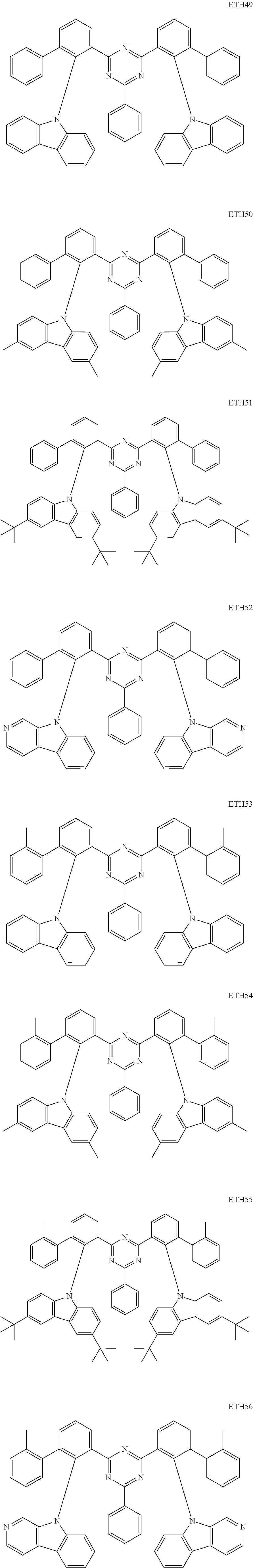

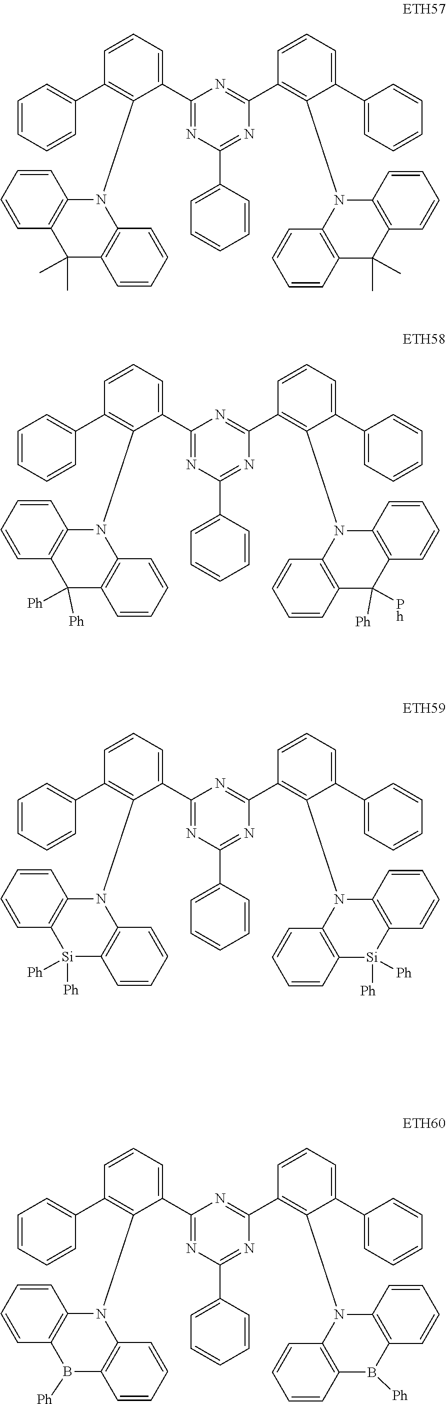

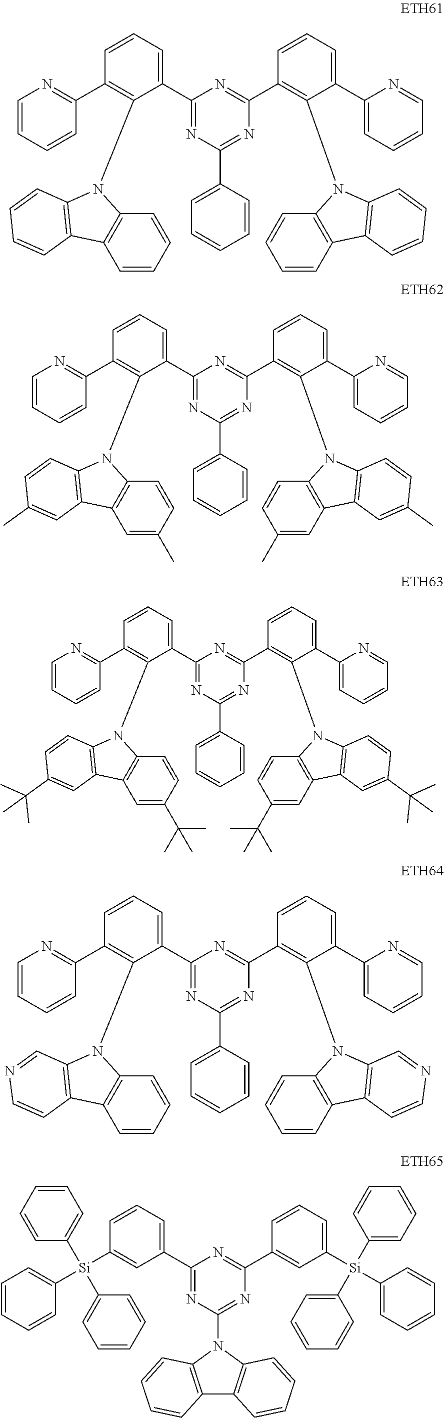

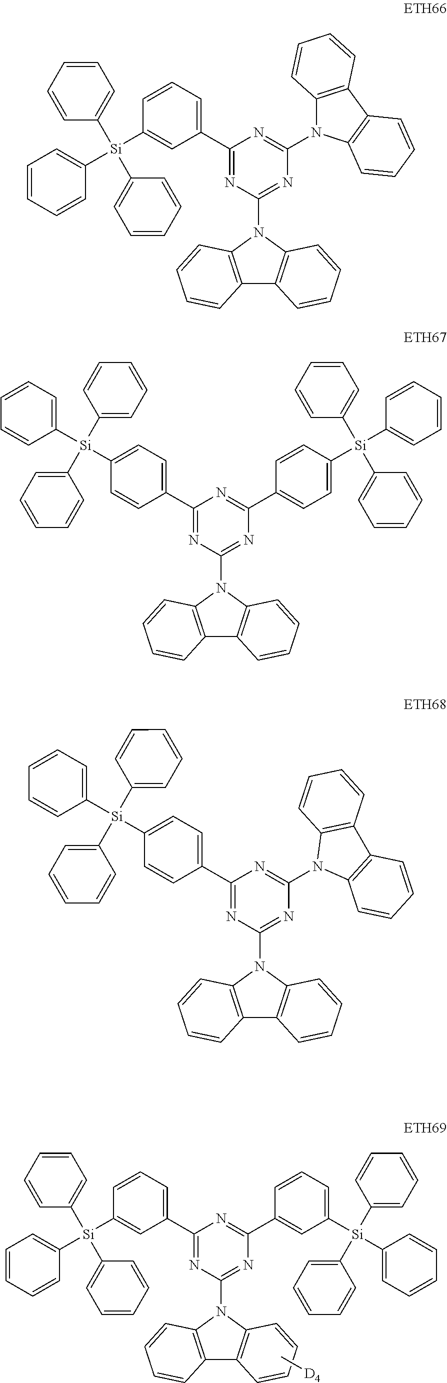

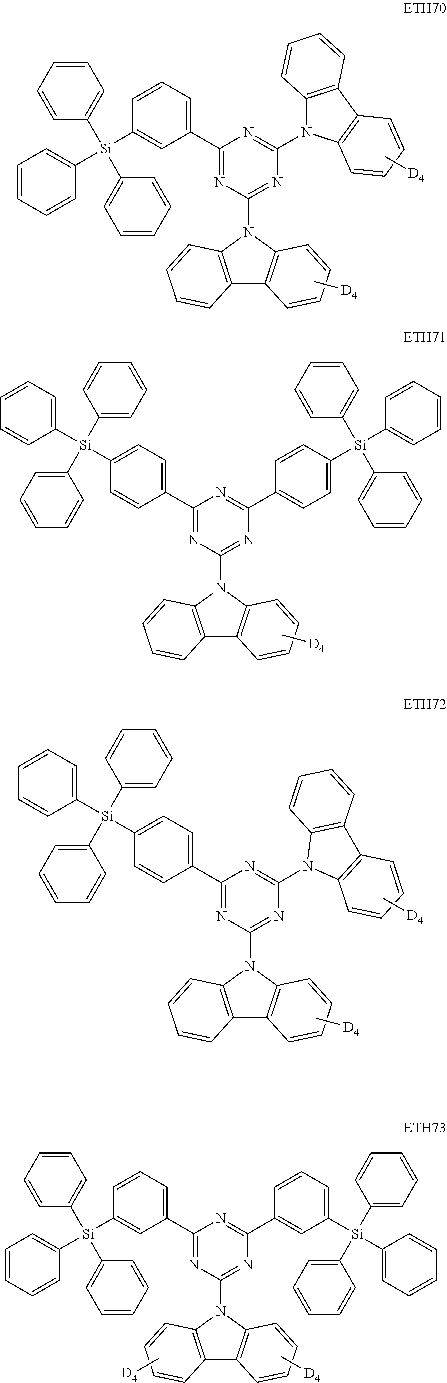

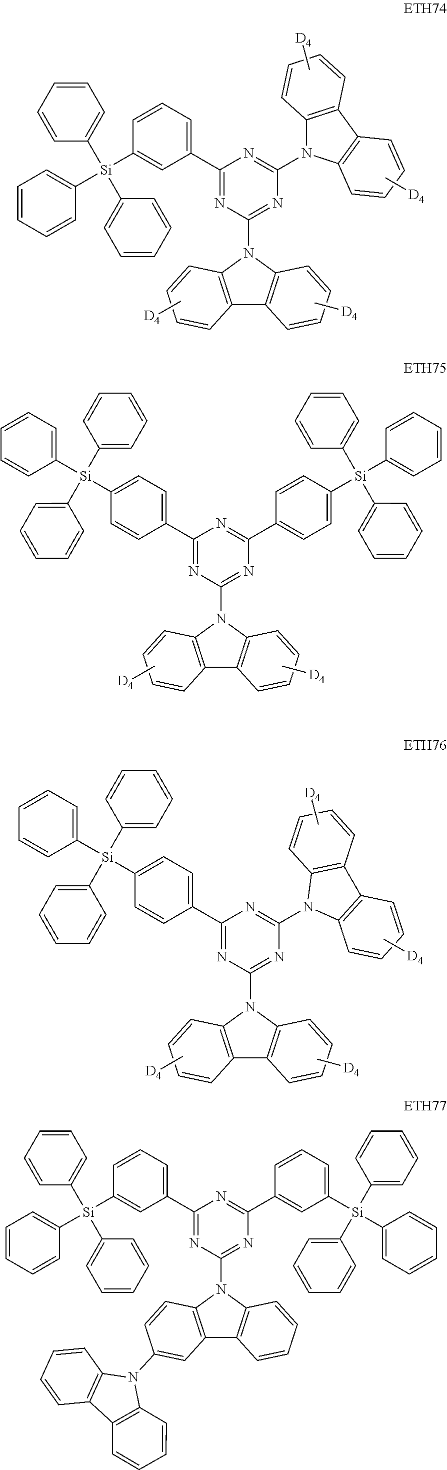

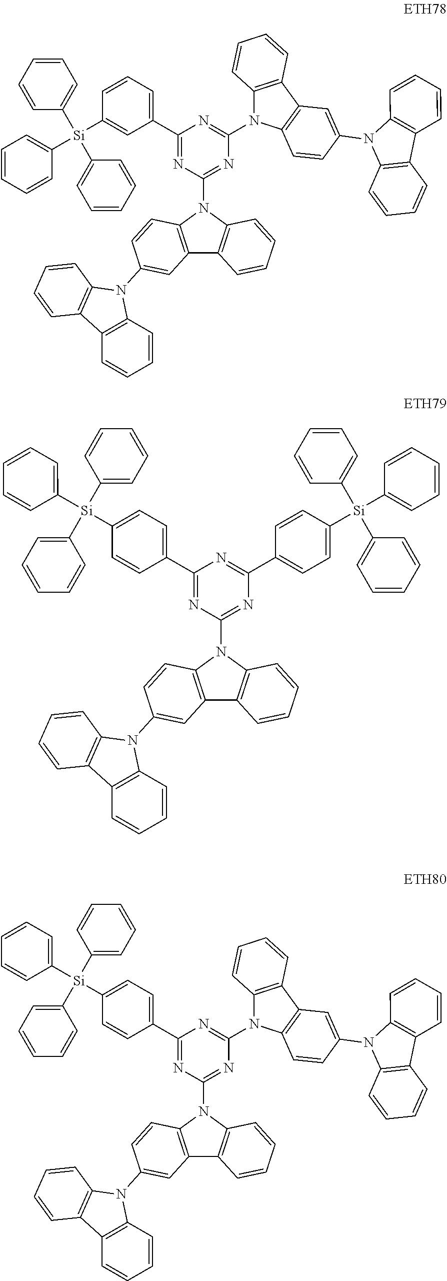 [SMILES: c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1 ; c1ccc([Si](c2ccccc2)(c2ccccc2)c2ccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)cc2)cc1]

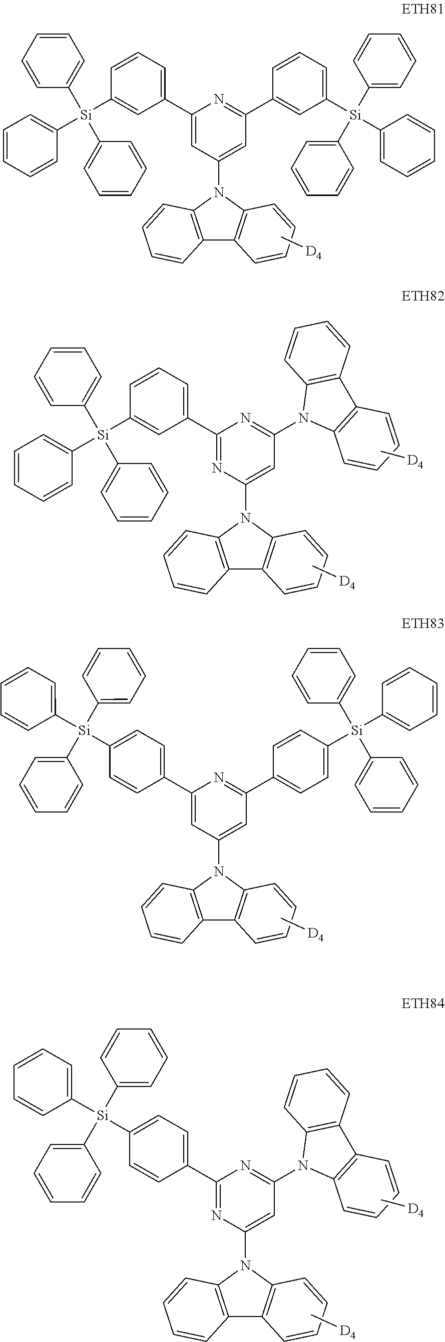

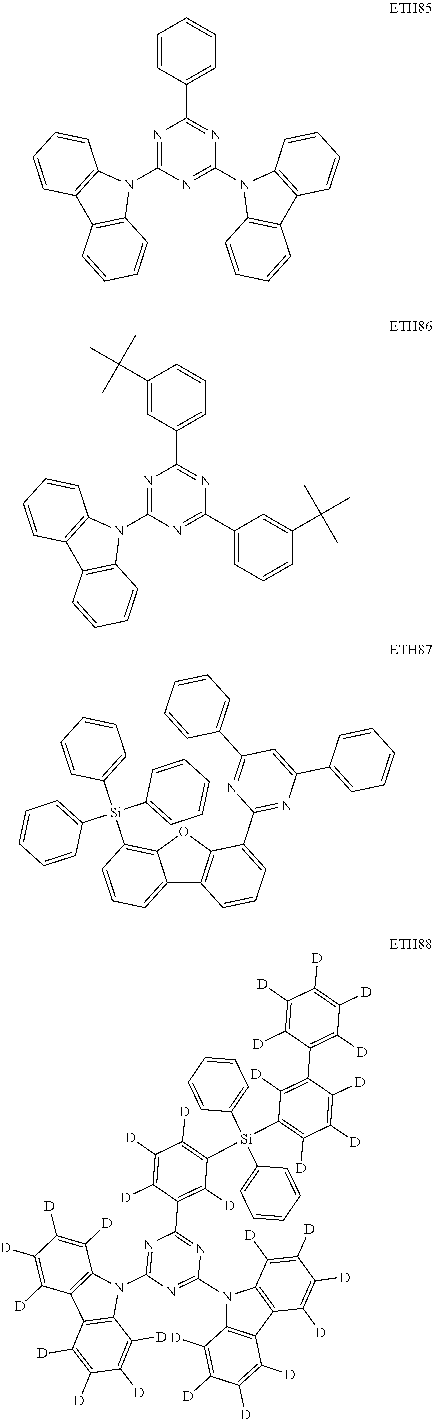

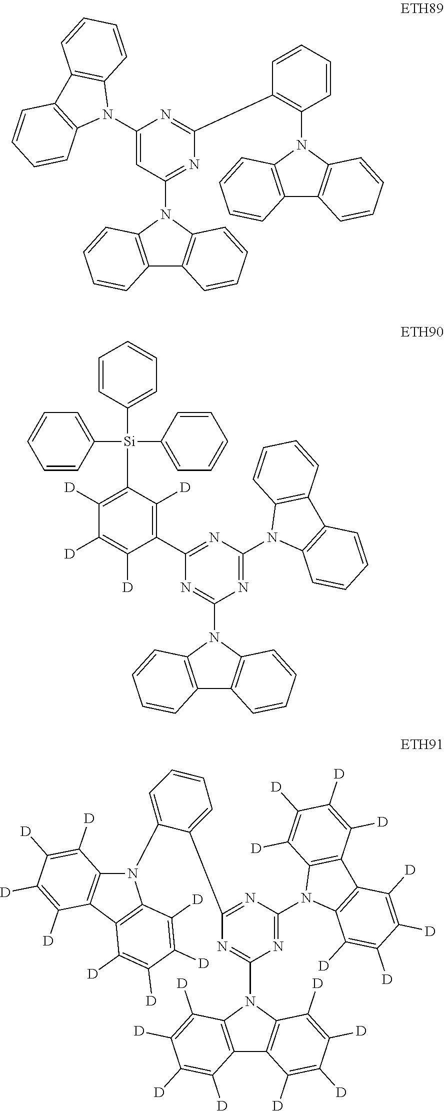 [SMILES: c1ccc(-n2c3ccccc3c3ccccc32)c(-c2nc(-n3c4ccccc4c4ccccc43)cc(-n3c4ccccc4c4ccccc43)n2)c1 ; [2H]c1c([2H])c(-c2nc(-n3c4ccccc4c4ccccc43)nc(-n3c4ccccc4c4ccccc43)n2)c([2H])c([Si](c2ccccc2)(c2ccccc2)c2ccccc2)c1[2H] ; [2H]c1c([2H])c([2H])c2c(c1[2H])c1c([2H])c([2H])c([2H])c([2H])c1n2-c1nc(-c2ccccc2-n2c3c([2H])c([2H])c([2H])c([2H])c3c3c([2H])c([2H])c([2H])c([2H])c32)nc(-n2c3c([2H])c([2H])c([2H])c([2H])c3c3c([2H])c([2H])c([2H])c([2H])c32)n1]

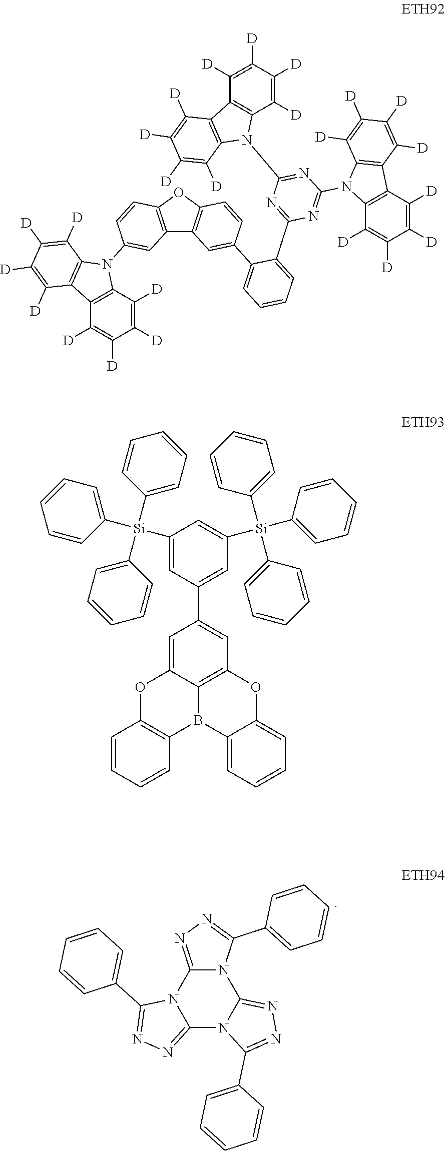 [SMILES: [2H]c1c([2H])c([2H])c2c(c1[2H])c1c([2H])c([2H])c([2H])c([2H])c1n2-c1ccc2oc3ccc(-c4ccccc4-c4nc(-n5c6c([2H])c([2H])c([2H])c([2H])c6c6c([2H])c([2H])c([2H])c([2H])c65)nc(-n5c6c([2H])c([2H])c([2H])c([2H])c6c6c([2H])c([2H])c([2H])c([2H])c65)n4)cc3c2c1 ; c1ccc([Si](c2ccccc2)(c2ccccc2)c2cc(-c3cc4c5c(c3)Oc3ccccc3B5c3ccccc3O4)cc([Si](c3ccccc3)(c3ccccc3)c3ccccc3)c2)cc1 ; c1ccc(-c2nnc3n2c2nnc(-c4ccccc4)n2c2nnc(-c4ccccc4)n32)cc1]

In Compound Group 2, D represents a deuterium atom, and Ph represents an unsubstituted phenyl group.

In the light emitting element ED, the phosphorescent sensitizer may be an organometallic complex. In an embodiment, the phosphorescent sensitizer may include platinum (Pt) as a central metal atom and ligands bonded to the central metal atom.

In an embodiment, the phosphorescent sensitizer may include a compound represented by Formula P-1:

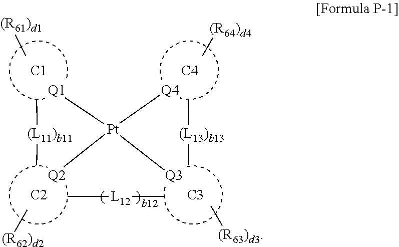

In Formula P-1, Q₁ to Q₄ may each independently be C or N. In Formula P-1, C1 to C4 may each independently be a substituted or unsubstituted hydrocarbon ring having 5 to 30 ring-forming carbon atoms or a substituted or unsubstituted heterocycle having 2 to 30 ring-forming carbon atoms.

In Formula P-1, L₁₁ to L₁₃ may each independently be a direct linkage, *—O—*, *—S—*,

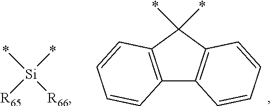

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms. In L₁₁ to L₁₃, —* represents a bond to one of C1 to C4.

In Formula P-1, b11 to b13 may each independently be 0 or 1. When b11 is 0, C1 and C2 may not be directly connected to each other. When b12 is 0, C2 and C3 may not be directly connected to each other. When b13 is 0, C3 and C4 may not be directly connected to each other.

In Formula P-1, R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 ring-forming carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring. For example, R₆₁ to R₆₆ may each independently be a substituted or unsubstituted methyl group or a substituted or unsubstituted t-butyl group.

In Formula P-1, d1 to d4 may each independently be an integer from 0 to 4. In Formula P-1, when d1 to d4 are each 0, the fourth compound may not be substituted with R₆₁ to R₆₄, respectively. A case where d1 to d4 are each 4 and R₆₁ to R₆₄ are each a hydrogen atom may be the same as a case where d1 to d4 are each 0. When d1 to d4 are each 2 or greater, multiple groups of each of R₆₁ to R₆₄ may all be the same, or at least one thereof may be different from the remainder.

In an embodiment, in Formula P-1, C1 to C4 may each independently be a substituted or unsubstituted hydrocarbon ring or a substituted or unsubstituted heterocycle that is represented by one of Formula C-1 to Formula C-4:

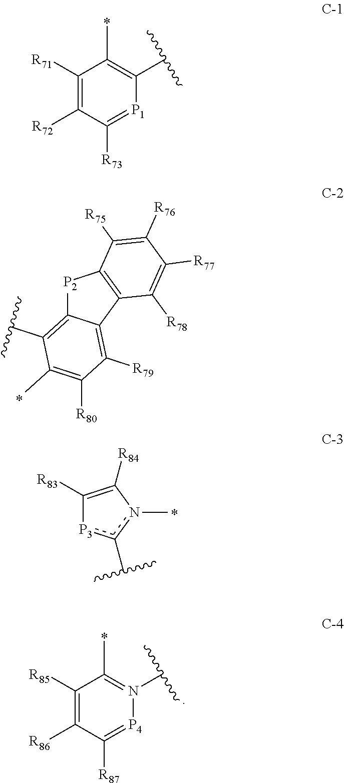

In Formula C-1 to Formula C-4, P₁ may be C—* or C(R₇₄), P₂ may be N—* or N(R₈₁), P₃ may be N—* or N(R₈₂), and P₄ may be C—* or C(R₈₈). In Formula C-1 to Formula C-4, R₇₁ to R₈₈ may each independently be a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring.

In Formula C-1 to Formula C-4,

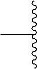

represents a bond to Pt, which is the central metal atom, and -* represents a bond to an adjacent ring group (C1 to C4) or to a linking moiety (L₁₁ to L₁₃).

In an embodiment, in the light emitting element ED, the phosphorescent sensitizer may include at least one compound selected from Compound Group 3:

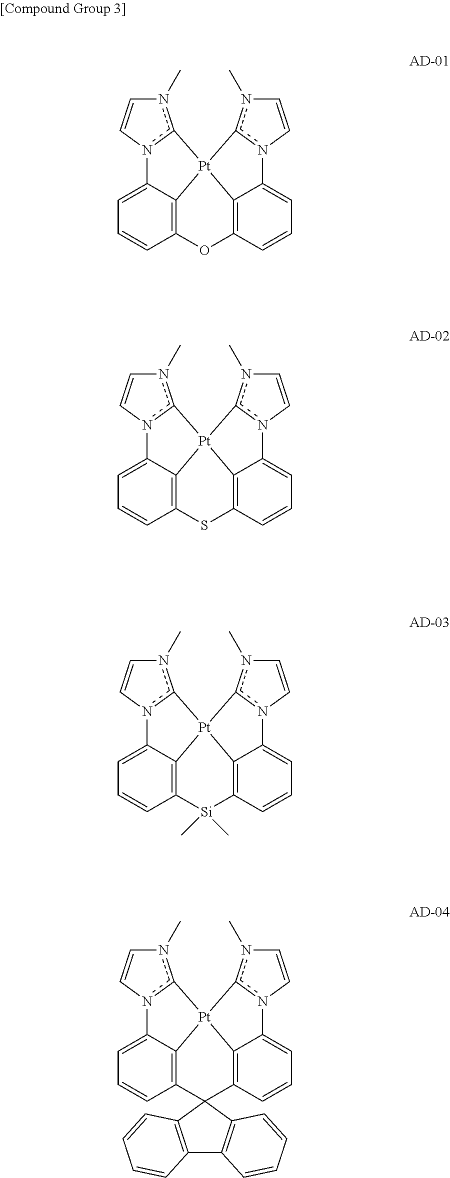

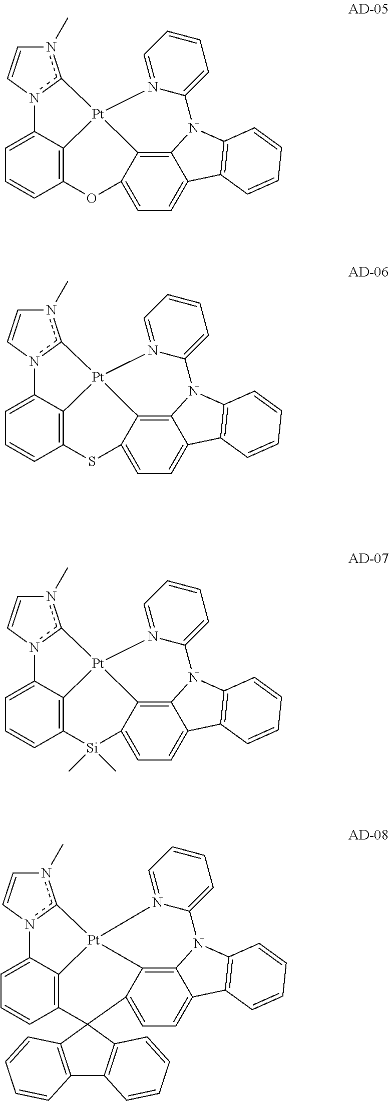

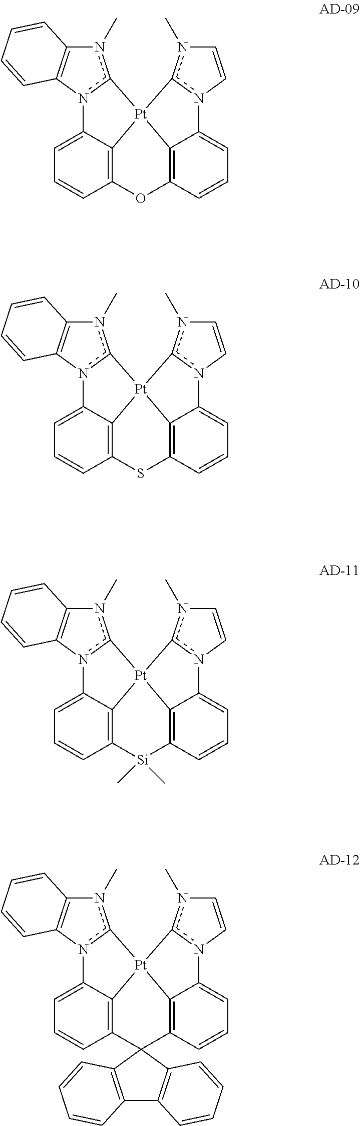

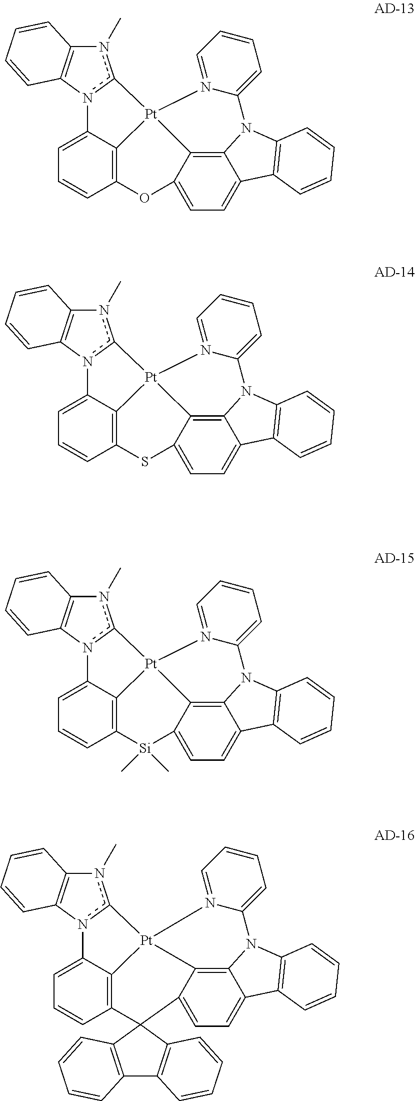

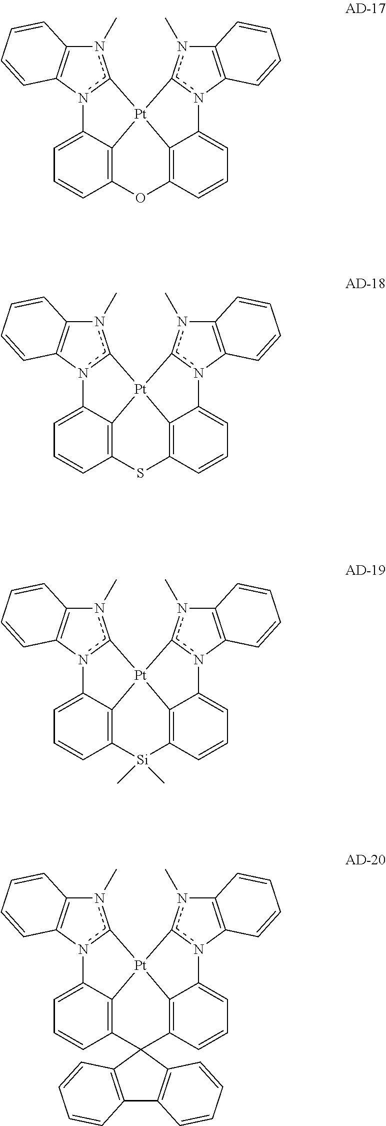

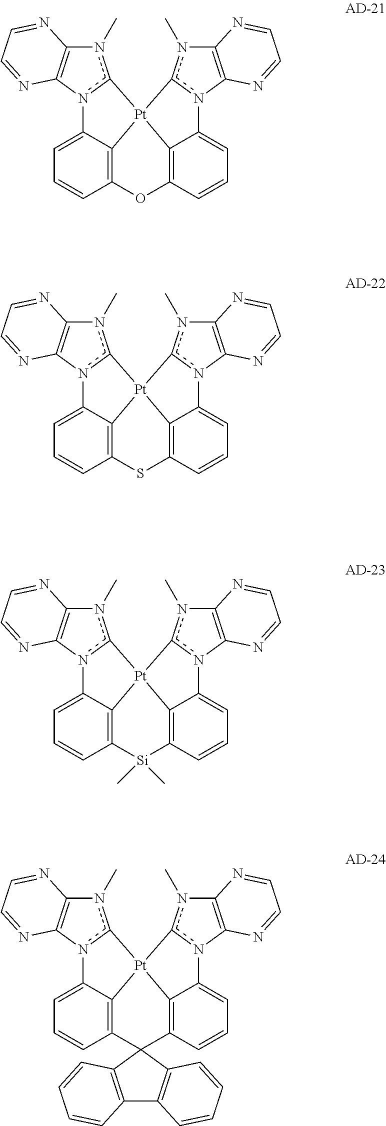

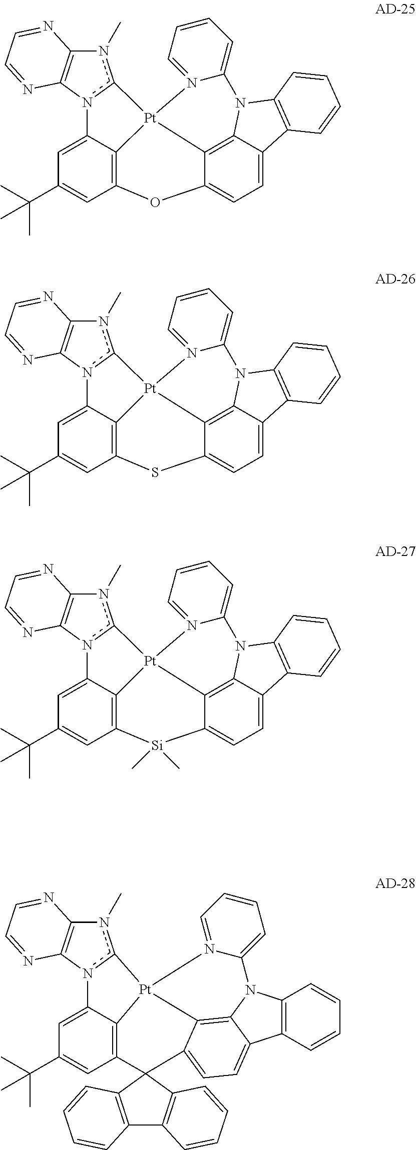

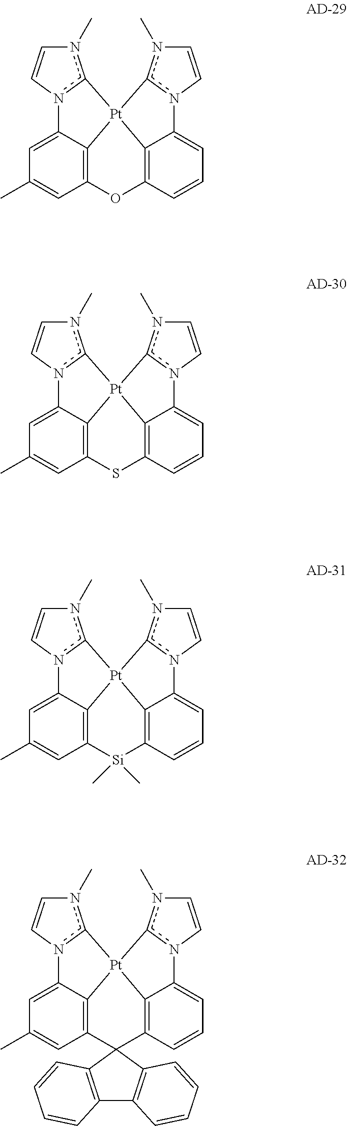

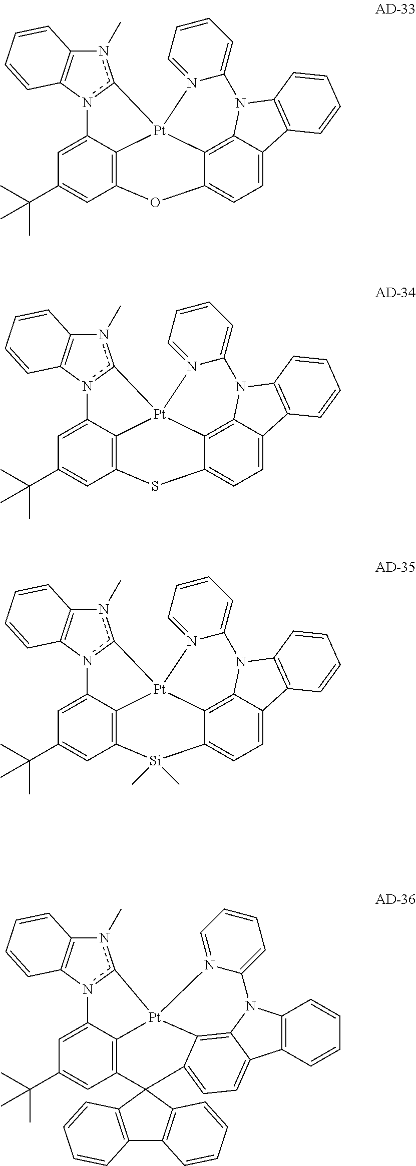

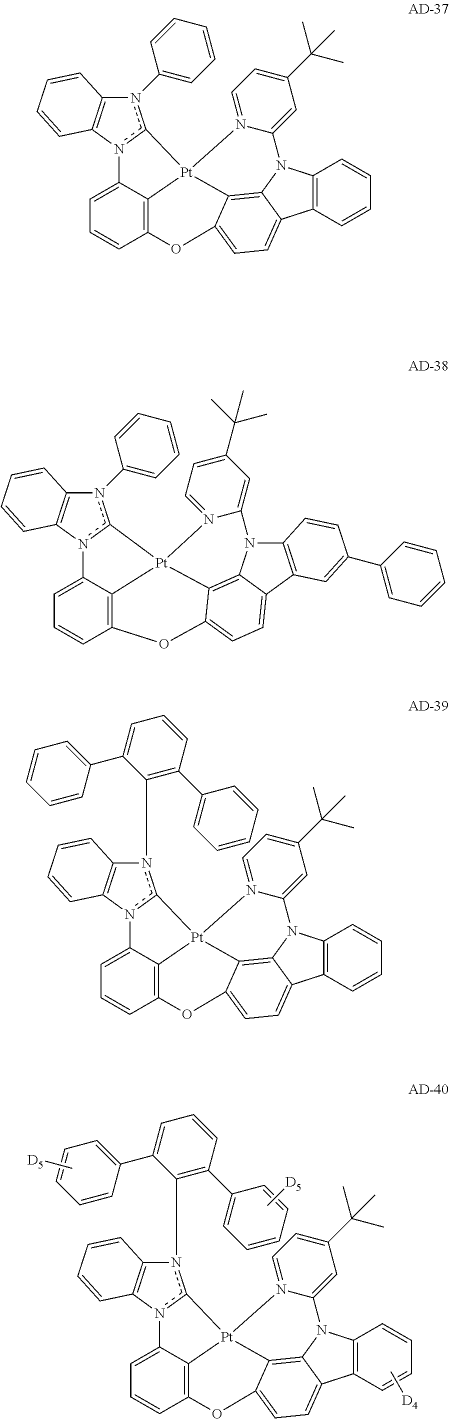

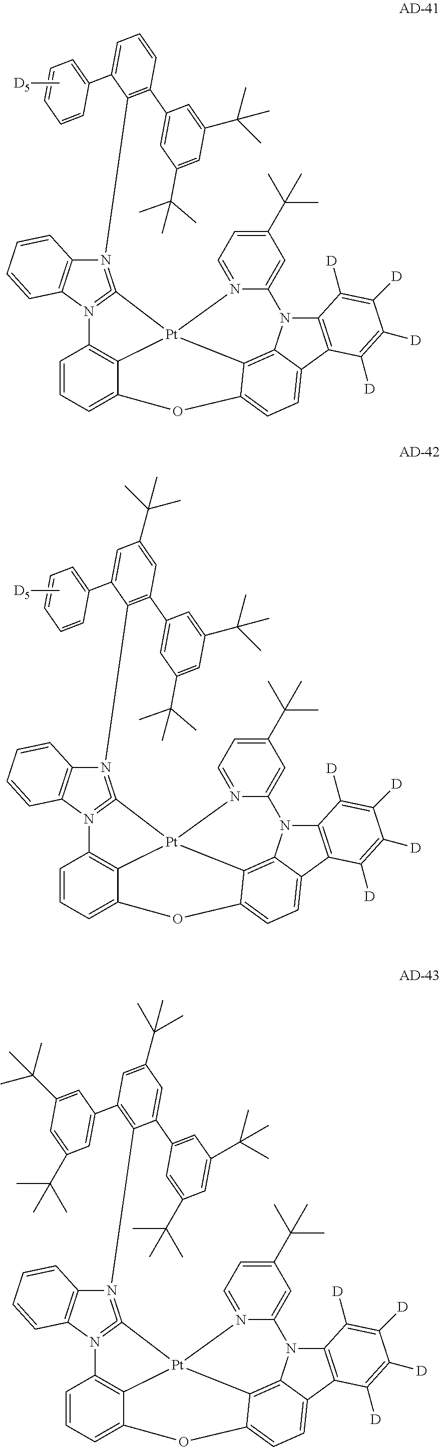

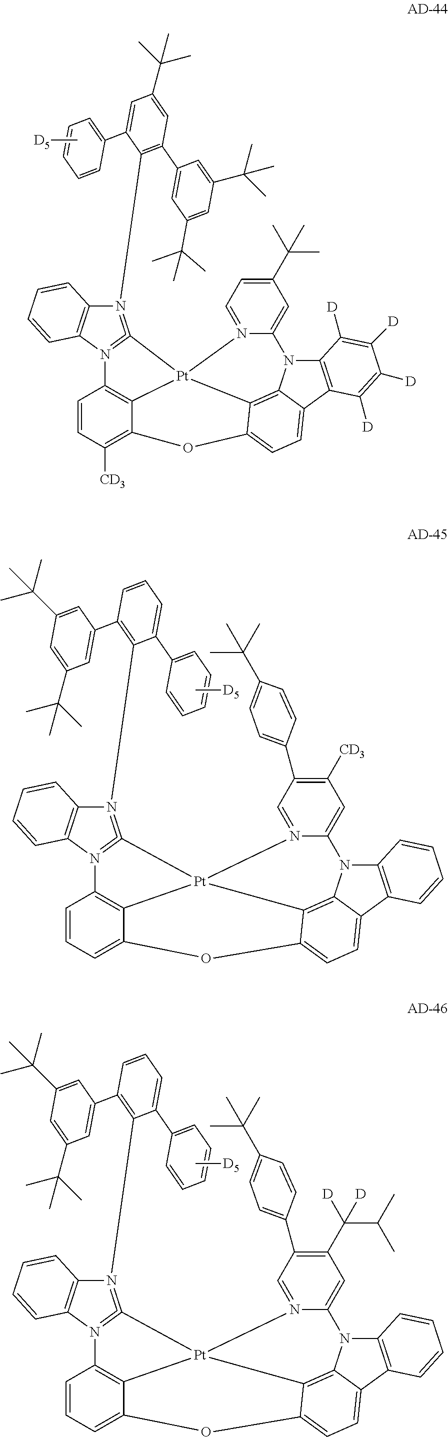

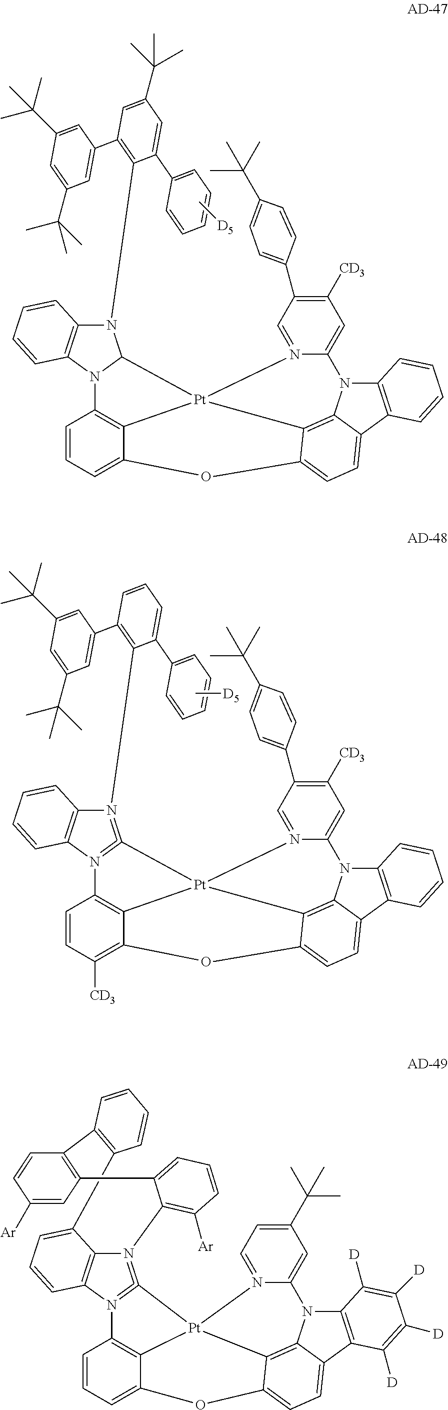

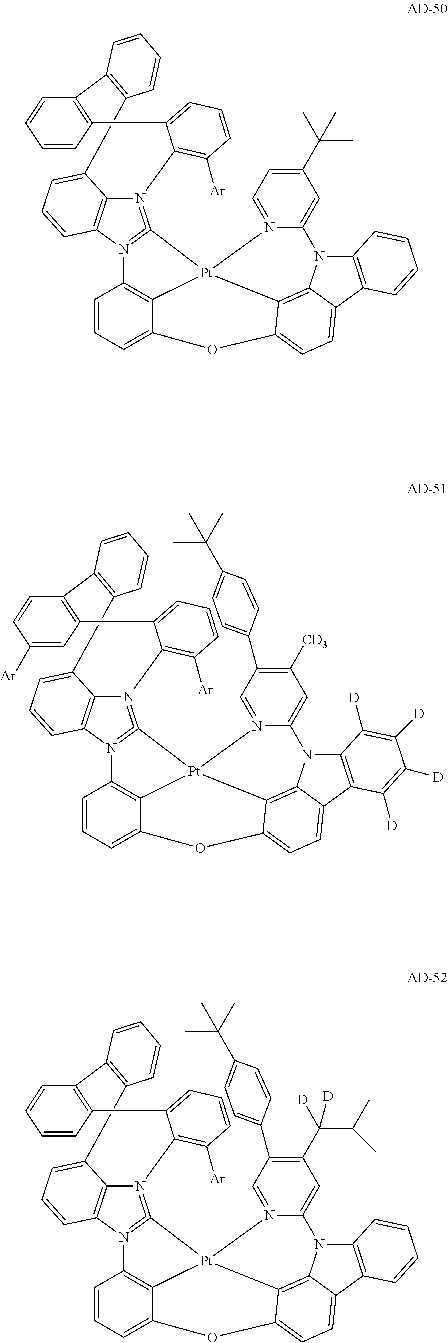

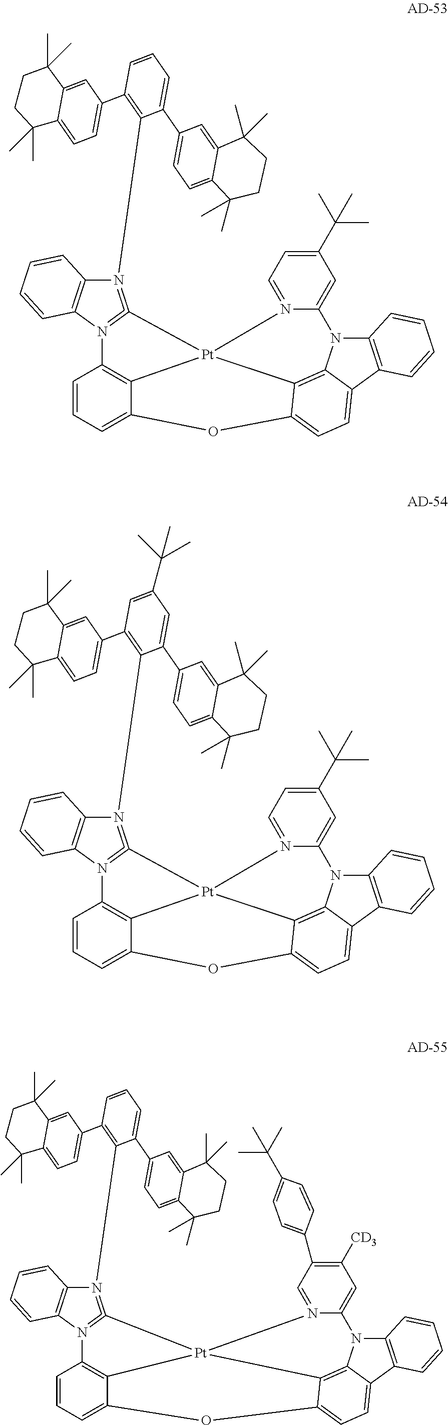

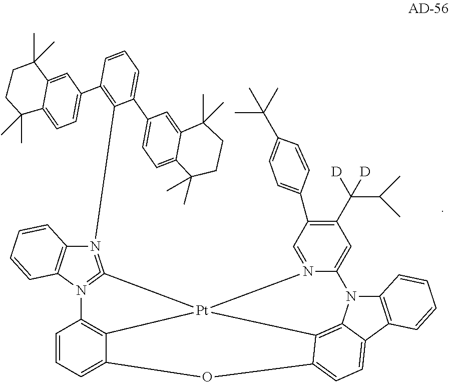

In Compound Group 3, D represents a deuterium atom. In Compound Group 3, Ar in Compound AD-49 and Compound AD-51 is a group represented by Formula Ar-a, and Ar in Compound AD-50 and Compound AD-52 is a group represented by Ar-b:

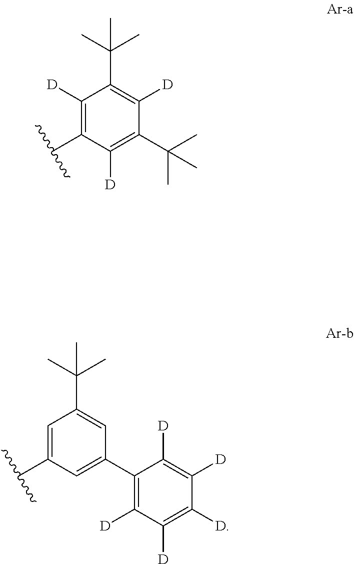

In the light emitting element ED, the light emitting dopant may be a fluorescence dopant. In an embodiment, the light emitting dopant may be a thermally activated delayed fluorescence dopant.

In an embodiment, the light emitting dopant may include a compound represented by Formula F-1:

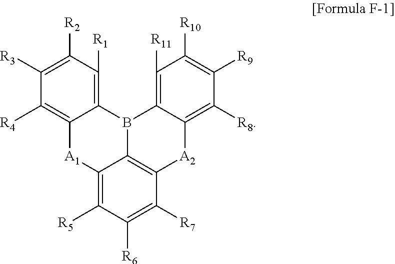

In Formula F-1, A₁ and A₂ may each independently be O, S, Se, or N(Rₘ); and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula F-1, R₁ to R₁₁ may each independently be a hydrogen atom, a deuterium atom, a halogen atom, a cyano group, a substituted or unsubstituted amine group, a substituted or unsubstituted boron group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring.

In an embodiment, in Formula F-1, A₁ and A₂ may each independently be bonded to a substituent of an adjacent ring to form a fused ring. For example, when A₁ and A₂ are each independently N(Rₘ), A₁ may be bonded to R₄ or R₈ to form a ring, and/or A₂ may be bonded to R₇ or R₈ to form a ring.

In an embodiment, in the light emitting element ED, the light emitting dopant may include at least one compound selected from Compound Group 4:

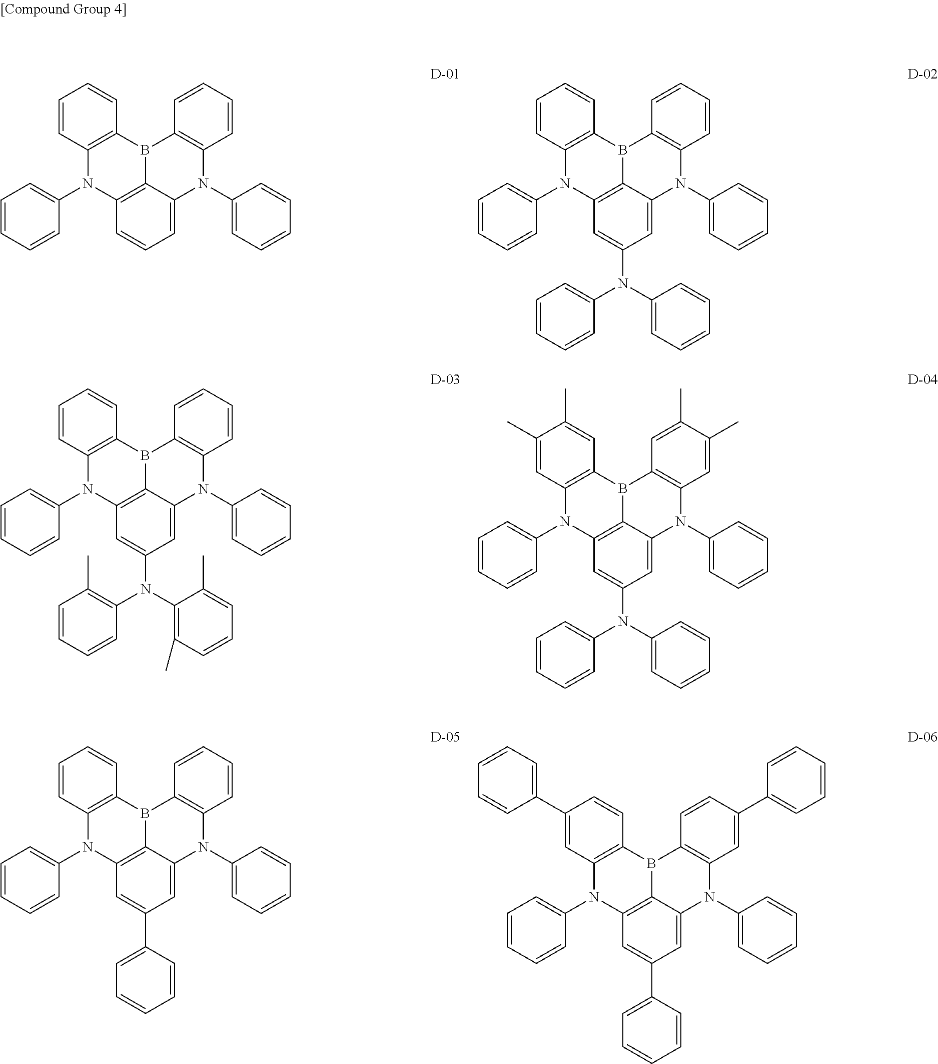

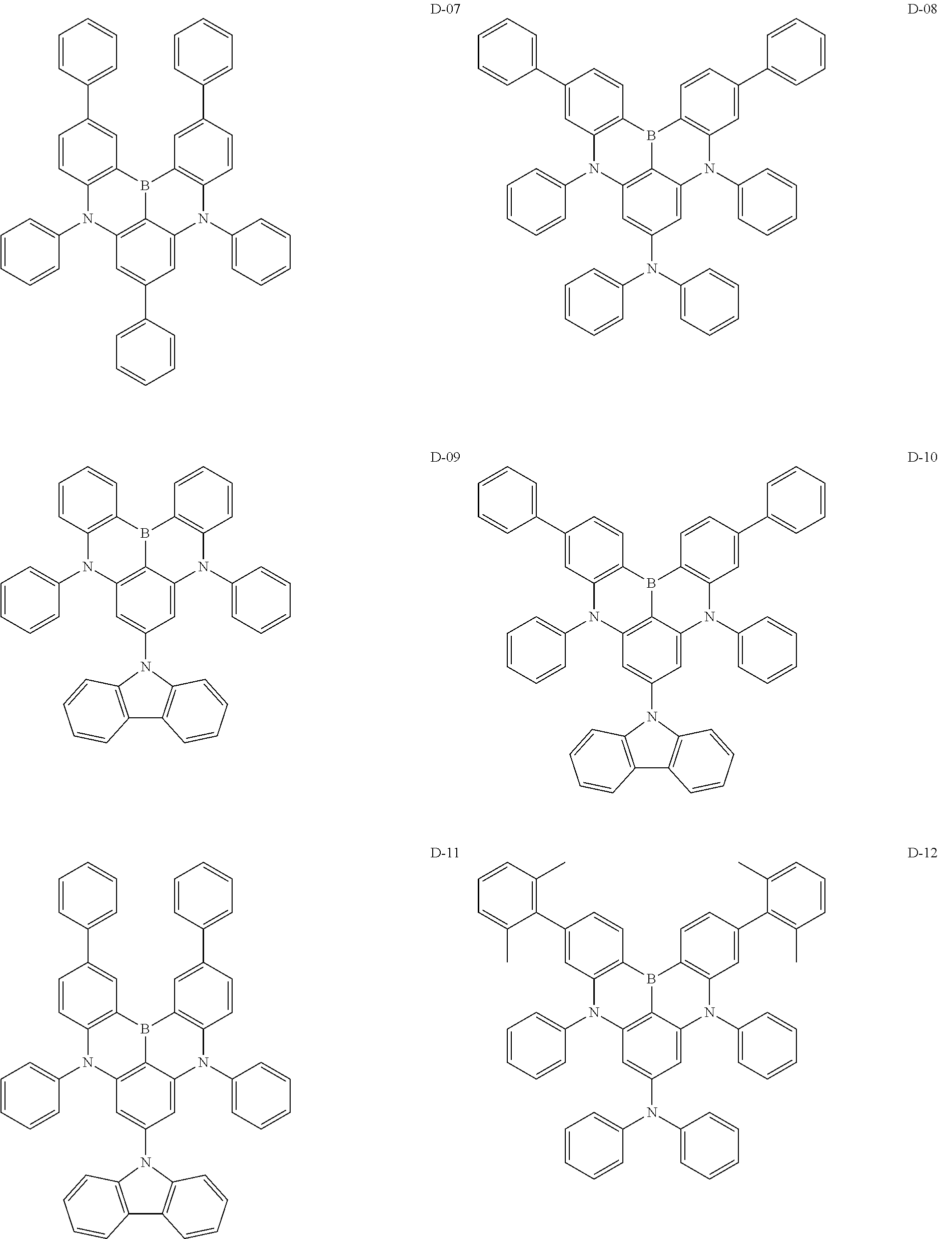

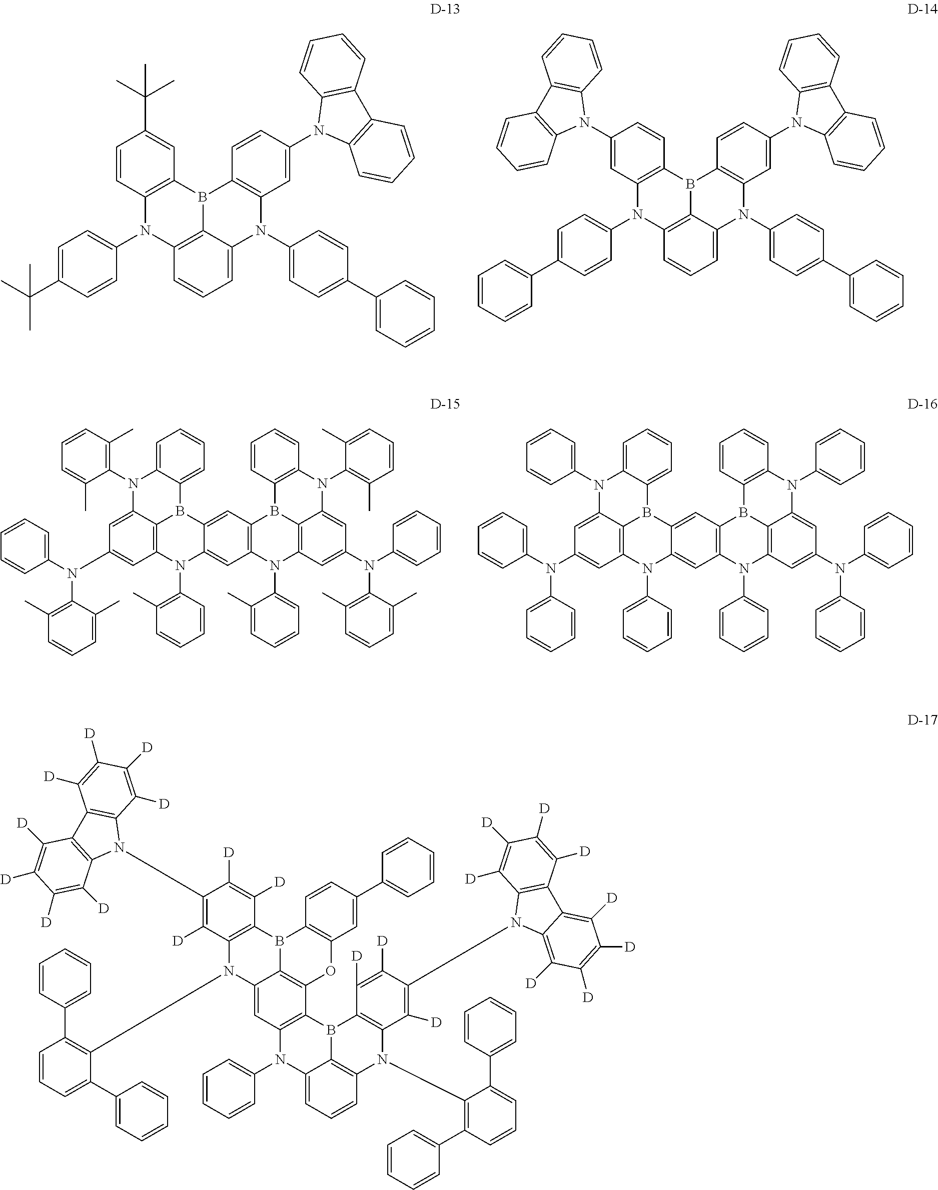

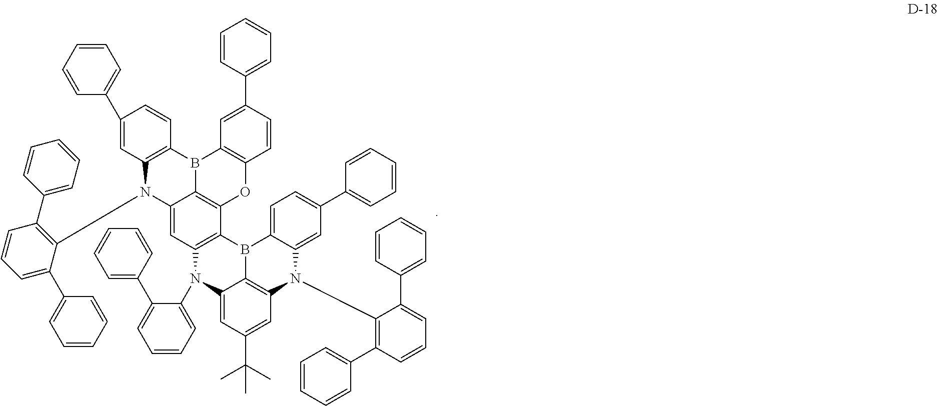

In Compound Group 4, D represents a deuterium atom.

In an embodiment, the emission layer EML may include at least one compound selected from Compound Group 1 as a hole transporting host, at least one compound selected from Compound Group 2 as an electron transporting host, at least one compound selected from Compound Group 3 as a phosphorescent sensitizer, and at least one compound selected from Compound Group 4 as a light emitting dopant.

In an embodiment, in the emission layer EML, a weight ratio of the hole transporting host to the electron transporting host may be in a range of about 7:3 to about 3:7. For example, a weight ratio of the hole transporting host to the electron transporting host in the emission layer EML may be about 5:5. When the weight ratio of hole transporting host to the electron transporting host in the emission layer EML satisfies the weight ratio described above, charge balance characteristics within the emission layer EML may be improved, and accordingly, luminous efficiency and element service life may increase. When the weight ratio of the hole transporting host to the electron transporting host deviates from the ranges and ratios described above, charge balance in the emission layer EML may be compromised, thereby reducing luminous efficiency, and causing the light emitting element to readily deteriorate.

In an embodiment, in the emission layer EML, an amount of the phosphorescent sensitizer may be in a range of about 10 wt % to about 20 wt %, with respect to a total of 100 wt % of the emission layer EML. In an embodiment, in the emission layer EML, an amount of the light emitting dopant may be in a range of about 2 wt % to about 5 wt %, with respect to a total of 100 wt % of the emission layer EML.

In an embodiment, in the emission layer EML, the hole transporting host and the electron transporting host may form an exciplex. Energy may be transferred from the exciplex to the light emitting dopant, thereby emitting light. In an embodiment, in the emission layer EML, energy may be transferred from the exciplex to the phosphorescent sensitizer and the light emitting dopant, thereby emitting light.

In an embodiment, the phosphorescent sensitizer may transfer energy from a host to the light emitting dopant. For example, the phosphorescent sensitizer may transfer energy to the light emitting dopant, thereby causing the light emitting dopant to emit light. The phosphorescent sensitizer may accelerate energy transfer to the light emitting dopant, thereby increasing a light emitting rate of the light emitting dopant.

In an embodiment, in the light emitting element ED, the emission layer EML includes different host materials such as a hole transporting host and an electron transporting host, a phosphorescent sensitizer that is an organometallic complex including Pt as a central metal atom, and a light emitting dopant that is a thermally activated delayed fluorescence dopant, and the light emitting element ED may thus exhibit enhanced luminous efficiency.

In an embodiment, the light emitting element ED includes a phosphorescent sensitizer and a light emitting dopant in the buffer layers BIL and BF that are each directly disposed on the emission layer EML, and thus the light emitting element ED may have reduced degradation that is caused by the formation of densely packed excitons in the emission layer EML. The first buffer layer BIL and the second buffer layer BF each include a phosphorescent sensitizer and a light emitting dopant to inhibit hole or electron mobility, and may thus control the injection of holes and electrons into the emission layer EML, thereby mitigating efficiency roll-off. Accordingly, the light emitting element ED that includes the buffer layers BIL and BF, which are respectively disposed on a lower portion and an upper portion of the emission layer EML and which each include a phosphorescent sensitizer and a light emitting dopant, may exhibit greater luminous efficiency and lifetime than a case in which the buffer layers BIL and BF are not included in the light emitting portion EL.

The thickness of the first buffer layer BIL t_{BI} and the thickness of the second buffer layer BF t_{BF} may each independently be in a range of about 20 Å to about 50 Å. For example, the respective thicknesses of the first buffer layer BIL and the second buffer layer BF, t_{BI} and BF, may each independently be about 25 Å to about 50 Å. In an embodiment, the thickness of the first buffer layer BIL t_{BI} and the thickness of the second buffer layer BF t_{BF} may be the same.

When the respective thicknesses of the first buffer layer BIL and the second buffer layer BF, t_{BI} and t_{BF}, are each less than about 20 Å, a light emitting region is not expandable, and thus the light emitting element fails to achieve an increased lifetime. When the respective thicknesses of the first buffer layer BIL and the second buffer layer BF, t_{BI} and t_{BF}, are each greater than 50 Å, driving voltage increases due to the increased thickness.

In an embodiment, an amount of the phosphorescent sensitizer in the first buffer layer BIL and the second buffer layer BF may each independently be in a range of about 5 wt % to about 20 wt %, and an amount of the light emitting dopant in the first buffer layer BIL and the second buffer layer BF may each independently be in a range of about 1 wt % to about 3 wt %. As the first buffer layer BIL and the second buffer layer BF each include a phosphorescent sensitizer and a light emitting dopant in the respective ranges as described above, a light emitting region is expanded to the entire light emitting portion EL, excitons are prevented from being densely packed in the emission layer EML, and accordingly, the light emitting element ED may have enhanced luminous efficiency and lifetime.

With respect to a total of 100 wt % of the first buffer layer BIL, an amount of the phosphorescent sensitizer may be included in a range of about 5 wt % to about 20 wt %, an amount of the light emitting dopant may be included in a range of about 1 wt % to about 3 wt %, and an amount of the hole transporting host may be the remainder of the weight of the first buffer layer BIL. For example, the first buffer layer BIL may include an amount of the phosphorescent sensitizer in a range of about 5 wt % to about 20 wt %, an amount of the light emitting dopant in a range of about 1 wt % to about 3 wt %, and an amount of the hole transporting host may be the balance of the weight of the first buffer layer BIL.

The first buffer layer BIL includes a hole transporting host, a phosphorescent sensitizer, and a light emitting dopant, and thus may allow some of the excitons formed in the emission layer EML to be dispersed in the first buffer layer BIL. Accordingly, degradation caused by densely packed excitons in the emission layer EML may be reduced, thereby improving the lifetime of the light emitting element ED.

The first buffer layer BIL may also serve as an electron blocking layer that controls or blocks the transfer of electrons toward the hole transport region HTR. The phosphorescent sensitizer and light emitting dopant included in the first buffer layer BIL may serve as a trap that inhibits the movement of holes or electrons. Accordingly, the first buffer layer BIL may control the movement of holes and electrons to mitigate efficiency roll-off in the light emitting portion EL.

With respect to a total of 100 wt % of the second buffer layer BF, an amount of the phosphorescent sensitizer may be included in a range of about 5 wt % to about 20 wt %, an amount of the light emitting dopant may be included in a range of about 1 wt % to about 3 wt %, and an amount of the electron transporting host may be the remainder of the weight of the second buffer layer BF. For example, the second buffer layer BF may include an amount of the phosphorescent sensitizer in a range of about 5 wt % to about 20 wt %, an amount of the light emitting dopant in a range of about 1 wt % to about 3 wt %, and an amount of the electron transporting host may be the balance of the weight of the second buffer layer BF.

The second buffer layer BF includes an electron transporting host, a phosphorescent sensitizer, and a light emitting dopant, and thus may allow some of the excitons formed in the emission layer EML to be dispersed in the second buffer layer BF. Accordingly, degradation caused by densely packed excitons in the emission layer EML may be reduced, thereby improving the lifetime of the light emitting element ED.

The second buffer layer BF may also serve as a hole blocking layer that controls or blocks the transfer of holes toward the electron transport region ETR. The phosphorescent sensitizer and light emitting dopant included in the second buffer layer BF may serve as a trap that inhibits the movement of holes or electrons. Accordingly, the second buffer layer BF may control the movement of holes and electrons to mitigate efficiency roll-off in the light emitting portion EL.

In the light emitting element ED, the electron transport region ETR may be provided on the light emitting portion EL. The electron transport region ETR may have a have a structure consisting of a layer consisting of a single material, a structure consisting of a layer including different materials, or a structure including multiple layers including different materials.

For example, the electron transport region ETR may have a single-layered structure consisting of an electron injection layer EIL or an electron transport layer ETL, or may have a single-layered structure formed of an electron injection material and an electron transport material. The electron transport region ETR may have a single-layered structure including different materials or may have a multilayered structure including multiple layers stacked from the emission layer EML. In an embodiment, the electron transport region ETR may include an electron transport layer ETL and an electron injection layer EIL. However, embodiments are not limited thereto, and the electron transport region ETR may further include functional layers such as a hole blocking layer.

The electron transport region ETR may have a thickness in a range of about 1,000 Å to about 1,500 Å. The electron transport region ETR may be formed using various methods such as a vacuum deposition method, a spin coating method, a cast method, a Langmuir-Blodgett (LB) method, an inkjet printing method, a laser printing method, and a laser induced thermal imaging (LITI) method.

The electron transport region ETR may include an anthracene-based compound. However, embodiments are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris (3-(pyridin-3-yl) biphenyl-3-yl)-1,3,5-triazine, 2-(4-(N-phenylbenzoimidazolyl-1-ylphenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(biphenyl-4-yl)-5-(4-tert-butylphenyl)-4-phenyl-4H-1,2,4-triazole (TAZ), 4-(naphthalen-1-yl)-3,5-diphenyl-4H-1,2,4-triazole (NTAZ), 2-(4-biphenyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), beryllium bis(benzoquinolin-10-olate) (Bebq₂), 9,10-di(naphthalene-2-yl) anthracene (ADN), 1,3-bis[3,5-di(pyridin-3-yl)phenyl]benzene (BmPyPhB), or a mixture thereof.

In an embodiment, the electron transport region ETR may include a metal halide such as LiF, NaCl, CsF, RbCl, RbI, CuI, and KI; a lanthanide such as Yb, or a co-deposited material of a metal halide and a lanthanide. For example, the electron transport region ETR may include KI:Yb, RbI:Yb, LiF:Yb, or the like as a co-deposited material. The electron transport region ETR include a metal oxide such as Li₂O and BaO, 8-hydroxyl-lithium quinolate (Liq), or the like, but embodiments are not limited thereto. In another embodiment, the electron transport region ETR may include a mixture material of an electron transport material and an insulating organometallic salt. The organometallic salt may be a material having an energy band gap equal to or greater than about 4 eV. For example, the organometallic salt may include a metal acetate, a metal benzoate, a metal acetoacetate, a metal acetylacetonate, or a metal stearate.

The electron transport region ETR may further include, for example, at least one of 2,9-dimethyl-4,7-diphenyl-1,10-phenanthroline (BCP), diphenyl (4-(triphenylsilyl)phenyl) phosphine oxide (TSPO1), and 4,7-diphenyl-1,10-phenanthroline (Bphen), in addition to the materials described above, but embodiments are not limited thereto.

The second electrode EL2 may be provided on the electron transport region ETR. The second electrode EL2 may be a common electrode. The second electrode EL2 may be a cathode or an anode but embodiments are not limited thereto. For example, when the first electrode EL1 is an anode, the second electrode EL2 may be a cathode, and when the first electrode EL1 is a cathode, the second electrode EL2 may be an anode.

The second electrode EL2 may be a transmissive electrode, a transflective electrode, or a reflective electrode. When the second electrode EL2 is a transmissive electrode, the second electrode EL2 may include a transparent metal oxide, for example, indium tin oxide (ITO), indium zinc oxide (IZO), zinc oxide (ZnO), indium tin zinc oxide (ITZO), or the like. When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof (e.g., AgMg, AgYb, or MgYb). In an embodiment, the second electrode EL2 may have a multilayered structure that includes a reflective film or a transflective film formed of the above-described materials, and a transparent conductive film formed of indium tin oxide (ITO), indium zinc oxide (IZO), zinc oxide (ZnO), indium tin zinc oxide (ITZO), or the like. For example, the second electrode EL2 may include the above-described metal materials, a combination of two or more of the above-described metal materials, or oxides of the above-described metal materials.

Although not shown in the drawings, the second electrode EL2 may be electrically connected to an auxiliary electrode. When the second electrode EL2 is electrically connected to an auxiliary electrode, resistance of the second electrode EL2 may decrease.

In an embodiment, the light emitting element ED may further include a capping layer CPL disposed on the second electrode EL2. The capping layer CPL may have a single-layered structure or a multilayered structure.

In an embodiment, the capping layer CPL may include an organic layer or an inorganic layer. For example, when the capping layer CPL includes an inorganic material, the inorganic material may include an alkali metal compound such as LiF, an alkaline earth metal compound such as MgF₂, SiON, SiN_{X}, SiO_{y}, or the like.

For example, when the capping layer CPL includes an organic material, the organic material may include α-NPD, NPB, TPD, m-MTDATA, Alq₃ CuPc, N4,N4,N4′,N4′-tetra (biphenyl-4-yl) biphenyl-4,4′-diamine (TPD15), 4,4′,4″-tris(carbazol sol-9-yl) triphenylamine (TCTA), or the like, or may include an epoxy resin or an acrylate such as methacrylate. However, embodiments are not limited thereto, and the capping layer CPL may include at least one of Compound P1 to P5:

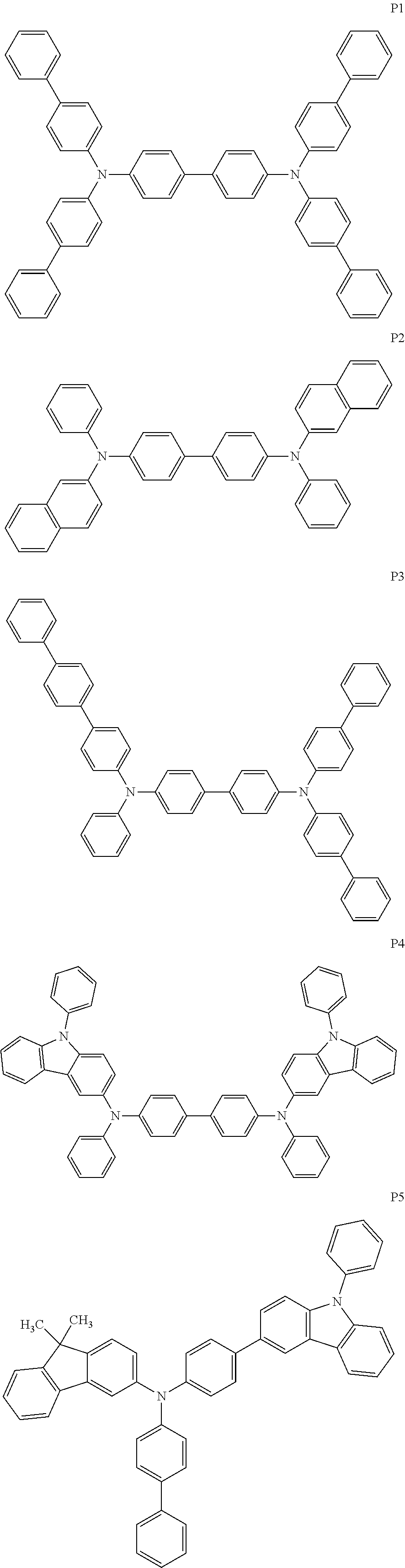 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

The capping layer CPL may have a refractive index equal to or greater than about 1.6. For example, the capping layer CPL may have a refractive index equal to or greater than about 1.6 in a wavelength range of about 550 nm to about 660 nm.

The light emitting element ED according to an embodiment includes an emission layer EML, and further includes buffer layers BIL and BF, which are respectively disposed on a lower portion and an upper portion of the emission layer EML. The buffer layers BIL and BF each include a phosphorescent sensitizer and a light emitting dopant, and thus the density of excitons in the emission layer EML is reduced, thereby mitigating degradation and emission roll-off in the emission layer EML. Accordingly, the light emitting element ED exhibits increased lifetime and increased luminous efficiency characteristics, and a display device DD including the light emitting element ED may exhibit excellent efficiency and reliability characteristics. The thicknesses of the first buffer layer BIL and the second buffer layer BF included in the light emitting element ED are each independently in a range of about 20 Å to about 50 Å, thereby minimizing an increase in driving voltage and increasing the luminous efficiency of the light emitting element ED without decreasing lifetime.

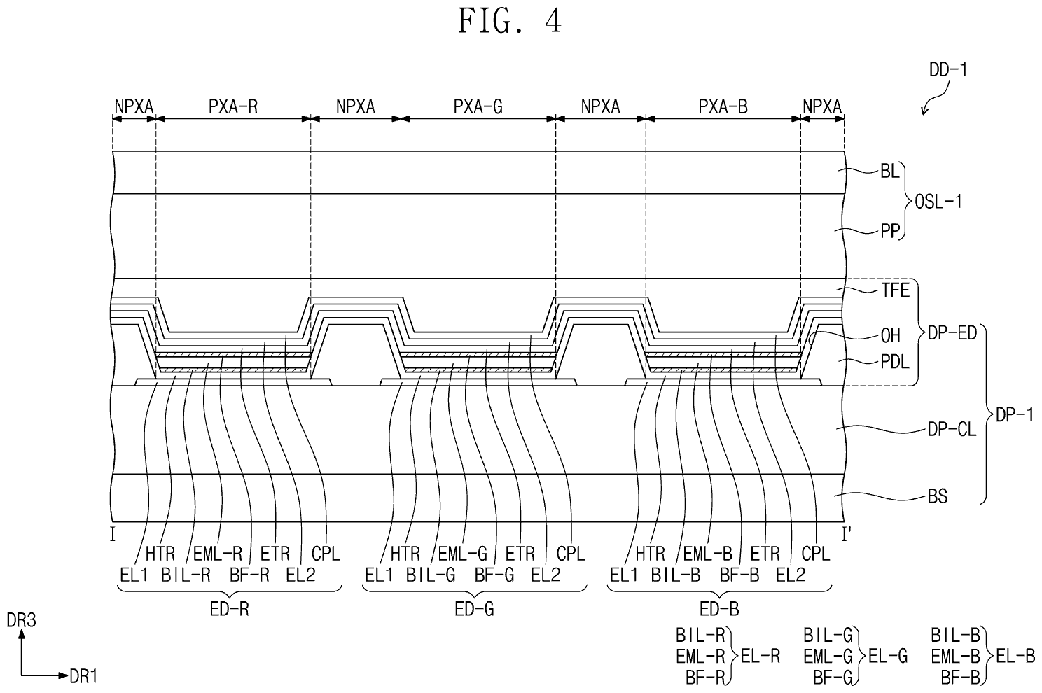

FIG. 4 is a schematic cross-sectional view of a display device according to an embodiment. FIG. 4 is a schematic cross-sectional view of a portion corresponding to virtual line I-I′ in FIG. 1.

Referring to FIG. 4, a display device DD-1 according to an embodiment may include a display panel DP-1 that includes a display element layer DP-ED, and an optical control panel OSL-1 disposed on the display panel DP-1. In the descriptions of the display device DD-1 according to an embodiment with reference to FIG. 4, the features that have been described above with respect to FIGS. 1 to 3 will not be explained again, and differing features will be described.

In the embodiment shown in FIG. 4, the display panel DP-1 may include a base layer BS, a circuit layer DP-CL provided on the base layer BS, and a display element layer DP-ED, and the display element layer DP-ED may include light emitting elements ED-R, ED-G, and ED-B.

The display device DD-1 may include non-light emitting regions NPXA and pixel regions PXA-R, PXA-G, and PXA-B. The pixel regions PXA-R, PXA-G, and PXA-B may each be a region that emits light respectively generated from the light emitting elements ED-R, ED-B, and ED-G.

The pixel regions PXA-R, PXA-G, and PXA-B may be regions that are separated from each other by a pixel defining film PDL. The non-light emitting regions NPXA may be regions between neighboring pixel regions PXA-R, PXA-G, and PXA-B, and which may correspond to the pixel defining film PDL. The light emitting portions EL-R, EL-G, and EL-B of the light emitting elements ED-R, ED-G, and ED-B may be disposed in the openings OH defined by the pixel defining film PDL and separated from each other.

In the display device DD-1, the light emitting elements ED-R, ED-G, and ED-B may emit light having different wavelength ranges. In an embodiment, the display device DD-1 may include a first light emitting element ED-R that emits red light, a second light emitting element ED-G that emits green light, and a third light emitting element ED-B that emits blue light. For example, the red light emitting region PXA-R, the green light emitting region PXA-G, and the blue light emitting region PXA-B of the display device DD-1 may respectively correspond to the first light emitting element ED-R, the second light emitting element ED-G, and the third light emitting element ED-B.

The light emitting elements ED-R, ED-G, and ED-B may each include a first electrode EL1, a hole transport region HTR, light emitting portions EL-R, EL-G, and EL-B, an electron transport region ETR, a second electrode EL2, and a capping layer CPL. The first to third light emitting elements ED-R, ED-G, and ED-B shown in FIG. 4 may each have a structure according to the structure of the light emitting element ED as described above with reference to FIG. 3.

The first light emitting portion EL-R of the first light emitting element ED-R may include a first emission layer EML-R that emits red light, and red portion buffer layers BIL-R and BF-R each disposed adjacent to the first emission layer EML-R. The second light emitting portion EL-G of the second light emitting element ED-G may include a second emission layer EML-G that emits green light, and green portion buffer layers BIL-G and BF-G each disposed adjacent to the second emission layer EML-G. The third light emitting portion EL-B of the third light emitting element ED-B may include a third emission layer EML-B that emits blue light, and blue portion buffer layers BIL-B and BF-B each disposed adjacent to the third emission layer EML-B.

In FIG. 4, the first to third light emitting elements ED-R, ED-G, and ED-B are each shown as including first buffer layers BIL-R, BIL-G, and BIL-B and second buffer layer BF-R, BF-G, and BF-B, but embodiments are not limited thereto. Although not shown in FIG. 4, in an embodiment, among the first to third light emitting elements ED-R, ED-G, and ED-B, only the third light emitting element ED-B may include the buffer layers BIL-B and BF-B.

In an embodiment, at least one of the red portion buffer layers BIL-R and BF-R included in the first light emitting element ED-R, the green portion buffer layers BIL-G and BF-G included in the second light emitting element ED-G, and the blue portion buffer layers BIL-B and BF-B included in the third light emitting element ED-B may each include a phosphorescent sensitizer and a light emitting dopant.

For example, in an embodiment, the third light emitting element ED-B emitting blue light may include the blue portion first buffer layer BIL-B disposed between the third emission layer EML-B and the hole transport region HTR, and the blue portion second buffer layer BF-B disposed between the third emission layer EML-B and the electron transport region ETR. The third emission layer EML-B may include a hole transporting host, an electron transporting host, a phosphorescent sensitizer, and a light emitting dopant; the blue portion first buffer layer BIL-B may include a hole transporting host, a phosphorescent sensitizer, and a light emitting dopant; and the blue portion second buffer layer BF-B may include an electron transporting host, a phosphorescent sensitizer, and a light emitting dopant. Accordingly, the third light emitting element ED-B may have further improved luminous efficiency and lifetime characteristics.

The buffer layers BIL-R and BF-R of the first light emitting element ED-R and the buffer layers BIL-G and BF-G of the second light emitting element ED-G may also include some of the dopant materials included in the respective adjacent emission layers EML-R and EML-G. For example, the red portion buffer layers BIL-R and BF-R and the green portion buffer layers BIL-G and BF-G may each include a phosphorescent sensitizer and a light emitting dopant, and thus, the first light emitting element ED-R and the second light emitting element ED-G may each have improved luminous efficiency and lifetime characteristics.

In the display device DD-1 shown in FIG. 4, the third light emitting element ED-B may have a same structure as the light emitting element ED described with reference to FIG. 3, and thus the third pixel region PXA-B may have further improved luminous efficiency and lifetime characteristics. In the display device DD-1 shown in FIG. 4, in addition to the third light emitting element ED-B, at least one of the first light emitting element ED-R and the second light emitting element ED-G may also have a same structure as the light emitting element ED described with reference to FIG. 3 with respect to the inclusion and structure of the buffer layers, so that the first light emitting element ED-R and/or the second light emitting element ED-G may also have improved luminous efficiency and lifetime characteristics.

The display device DD-1 according to an embodiment includes the light emitting elements ED-R, ED-G, and ED-B including buffer layers that each include a phosphorescent sensitizer and a light emitting dopant in the display panel DP-1, and may thus exhibit improved characteristics of light efficiency and reliability.

The first electrode EL1, the second electrode EL2, the hole transport region HTR, the electron transport region ETR, and the capping layer CPL of the first light emitting element ED-R, the second light emitting element ED-G, and the third light emitting element ED-B may each be the same as described for the light emitting element ED as explained above with reference to FIG. 3. The emission layer EML-R of the first light emitting element ED-R includes a host and a dopant material that emit red light, and the emission layer EML-G of the second light emitting element ED-G includes a host and a dopant material that emit green light, which may each be different from the configuration of the emission layer EML-B of the third light emitting element ED-B.

In the display device DD-1, the optical control panel OSL-1 may include an optical layer PP. The optical layer PP may be disposed on the display panel DP-1 to control light that is reflected at the display panel DP-1 from an external light. The optical layer PP may include, for example, a polarizing layer or a color filter layer. Although not shown in the drawings, in an embodiment, the optical layer PP may be omitted from the display device DD-1.

A base substrate BL may be disposed on the optical layer PP. The base substrate BL may provide a base surface on which the optical layer PP is disposed. The base substrate BL may be a glass substrate, a metal substrate, a plastic substrate, or the like. However, embodiments are not limited thereto, and the base substrate BL may include an inorganic layer, an organic layer, or a composite material layer. Although not shown in the drawings, in an embodiment, the base substrate BL may be omitted.

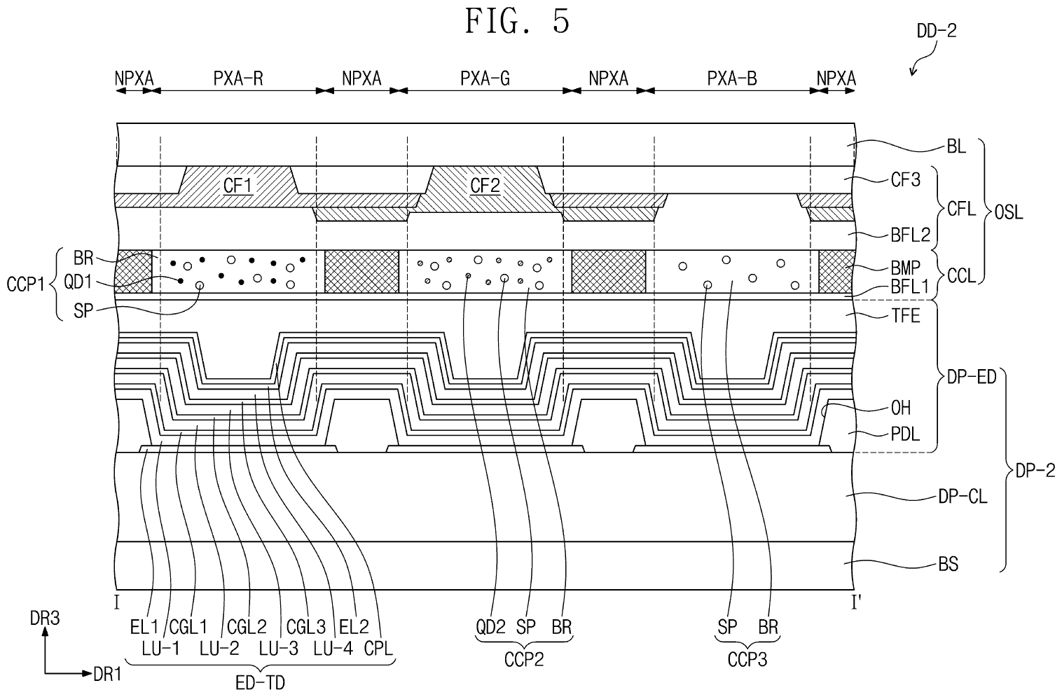

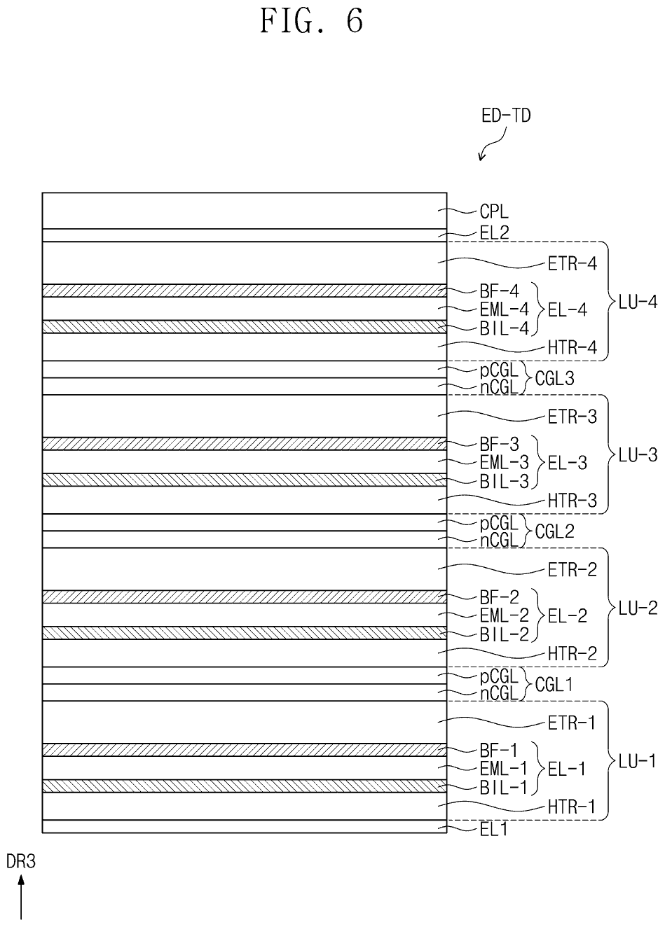

FIG. 5 is a schematic cross-sectional view of a display device according to an embodiment. FIG. 5 is a schematic cross-sectional view of a portion corresponding to virtual line I-I′ in FIG. 1. FIG. 6 is a schematic cross-sectional view of a light emitting element according to an embodiment. FIG. 6 shows the light emitting element ED-TD included in the display panel DP-2 of FIG. 5 in further detail.

Referring to FIG. 5, a display device DD-2 according to an embodiment may include a display panel DP-2 that includes a display element layer DP-ED, and an optical control panel OSL disposed on the display panel DP-2. In the descriptions of the display device DD-2 and the light emitting element ED-TD according to an embodiment with reference to FIGS. 5 and 6, that features that have been described above with respect to FIGS. 1 to 4 will not be explained again, and differing features will be described.

In the display device DD-2, the display panel DP-2 may include a base layer BS, a circuit layer DP-CL, and a display element layer DP-ED. In an embodiment, in the display device DD-2, the optical control panel OSL may be disposed on the display panel DP-2. The optical control panel OSL may include a light control layer CCL, and may further include a color filter layer CFL that include a barrier layer BFL2, and a base substrate BL.

In the display device DD-2 according to an embodiment, the light emitting element ED-TD may include light emitting structures LU-1, LU-2, LU-3, and LU-4. At least one of the light emitting structures LU-1, LU-2, LU-3, and LU-4 may respectively include a first buffer layer BIL-1, BIL-2, BIL-3, and BIL-4 and may respectively include a second buffer layer BF-1, BF-2, BF-3, and BF-4, which have described above with respect to the light emitting structure LU (FIG. 3). Accordingly, a light emitting structure including the buffer layers may exhibit improved luminous efficiency and lifetime characteristics, and accordingly, the light emitting element ED-TD including at least one light emitting structure as described herein may exhibit improved luminous efficiency and lifetime characteristics.

In an embodiment, the light emitting element ED-TD may include a first electrode EL1 and a second electrode EL2 that face each other, and the light emitting structures LU-1, LU-2, LU-3, and LU-4, which may be sequentially stacked in a thickness direction between the first electrode EL1 and the second electrode EL2. For example, the light emitting element ED-TD may include three or more light emitting structures disposed between the first electrode EL1 and the second electrode EL2. The light emitting element ED-TD may include charge generation layers CGL1, CGL2, and CGL3, each disposed between adjacent structures among the light emitting structures LU-1, LU-2, LU-3, and LU-4.

The light emitting structures LU-1, LU-2, LU-3, and LU-4 may each be provided as a common structure throughout the pixel regions PXA-R, PXA-G, and PXA-B. However, embodiments are not limited thereto. For example, at least one of the light emitting structures LU-1, LU-2, LU-3, and LU-4 may be formed separately for each of the first to third pixel regions PXA-R, PXA-G, and PXA-B. In an embodiment, at least one of the light emitting structures LU-1, LU-2, LU-3, and LU-4 may be patterned in the opening OH and separately provided in each of the first to third pixel regions PXA-R, PXA-G, and PXA-B.

The charge generation layers CGL1, CGL2, and CGL3 may each be provided as a common layer throughout the pixel regions PXA-R, PXA-G, and PXA-B. However, embodiments are not limited thereto.

Referring to FIGS. 5 and 6, the light emitting element ED-TD may include the first light emitting structure LU-1, the second light emitting structure LU-2, the third light emitting structure LU-3, and the fourth light emitting structure LU-4, which are stacked in that order. For example, in an embodiment, the first light emitting structure LU-1, the second light emitting structure LU-2, and the third light emitting structure LU-3 may each be a blue light emitting structure, and the fourth light emitting structure LU-4 may be a green light emitting structure. However, embodiments are not limited thereto, and the position of the green light emitting structure and the number of green light emitting structures included in the light emitting element ED-TD may vary.

The light emitting element ED-TD according to an embodiment may include a first charge generation layer CGL1 disposed between the first light emitting structure LU-1 and the second light emitting structure LU-2, a second charge generation layer CGL2 disposed between the second light emitting structure LU-2 and the third light emitting structure LU-3, and a third charge generation layer CGL3 disposed between the third light emitting structure LU-3 and the fourth light emitting structure LU-4.

When a voltage is applied to the light emitting element ED-TD, the charge generation layers CGL1, CGL2, and CGL3 each form a complex through an oxidation-reduction reaction, thereby generating charges (electrons and holes). The charge generation layers CGL1, CGL2, and CGL3 may each provide the generated charges to the adjacent light emitting structures LU-1, LU-2, LU-3, and LU-4. The charge generation layers CGL1, CGL2, and CGL3 may increase the efficiency of the current generated in each of the adjacent light emitting structures LU-1, LU-2, LU-3, and LU-4, and may adjust the balance of charges between adjacent light emitting structures LU-1, LU-2, LU-3, and LU-4.

The charge generation layers CGL1, CGL2, and CGL3 may each have a structure in which an n-type charge generation layer nCGL and a p-type charge generation layer pCGL are disposed adjacent to each other.

The n-type charge generation layer nCGL may provide electrons to adjacent light emitting structures LU-1, LU-2, and LU-3. The n-type charge generation layer nCGL may include a base material that is doped with an n-dopant. The p-type charge generation layer pCGL may provide holes to adjacent light emitting structures LU-2, LU-3, and LU-4. The p-type charge generation layer pCGL may include a base material that is doped with a p-dopant.

Although not shown in the drawings, in an embodiment, the light emitting element ED-TD may further include a buffer layer (not shown) disposed between the n-type charge generation layer nCGL and the p-type charge generation layer pCGL.

The charge generating layers CGL1, CGL2, and CGL3 may each include an n-type arylamine-based material or a p-type metal compound. For example, the charge generating layers CGL1, CGL2, and CGL3 may each independently include an arylamine-based organic compound, a metal, a metal oxide, a metal carbide, a metal fluoride, or a mixture thereof.

For example, the arylamine-based organic compound may be α-NPD, 2-TNATA, TDATA, MTDATA, spiro-TAD, or spiro-NPB. Examples of a metal may include cesium (Cs), molybdenum (Mo), vanadium (V), titanium (Ti), tungsten (W), barium (Ba), and lithium (Li). Examples of a metal oxide, a metal carbide, or a metal fluoride may include Re₂O₇, MoO₃, V₂O₅, WO₃, TiO₂, Cs₂CO₃, BaF, LiF, and CsF.

The light emitting structures LU-1, LU-2, LU-3, and LU-4 respectively include light emitting portions EL-1, EL-2, EL-3, and EL-4. The light emitting structures LU-1, LU-2, LU-3, and LU-4 may respectively include hole transport regions HTR-1, HTR-2, HTR-3, and HTR-4, respectively include light emitting portions EL-1, EL-2, EL-3, and EL-4, and respectively include electron transport regions ETR-1, ETR-2, ETR-3, and ETR-4, and the respective hole transport regions, light emitting portions, and electron transport regions of each light emitting structure may be stacked in that order. The light emitting portions EL-1, EL-2, EL-3, and EL-4 may respectively include emission layers EML-1, EML-2, EML-3, and EML-4. Thus, the light emitting element ED-TD according to an embodiment may be a light emitting element having a tandem structure that includes multiple emission layers stacked in a thickness direction.

At least one of the light emitting portions EL-1, EL-2, EL-3, and EL-4 may respectively include first buffer layers BIL-1, BIL-2, BIL-3, and BIL-4 and respectively include second buffer layers BF-1, BF-2, BF-3, and BF-4. The first buffer layers BIL-1, BIL-2, BIL-3, and BIL-4 and the second buffer layers BF-1, BF-2, BF-3, and BF-4 may each include a portion of dopant materials included in the respectively adjacent emission layers EML-1, EML-2, EML-3, and EML-4. Accordingly, in the light emitting portions EL-1, EL-2, EL-3, and EL-4, excitons are not densely packed in the emission layers EML-1, EML-2, EML-3, and EML-4 and are thus dispersed in the buffer layers, so that degradation in the emission layers EML-1, EML-2, EML-3, and EML-4 is reduced and luminous efficiency may be increased.

In FIG. 6, the light emitting structures LU-1, LU-2, LU-3, and LU-4 disposed between the first electrode EL1 and the second electrode EL2 are shown as respectively including the first buffer layers BIL-1, BIL-2, BIL-3, and BIL-4 and respectively including the second buffer layers BF-1, BF-2, BF-3, and BF-4, but embodiments are not limited thereto. For example, at least one of the light emitting structures LU-1, LU-2, LU-3, and LU-4 may include the first and second buffer layers, and the remaining light emitting structures may not include the first and second buffer layers. For example, among the light emitting structures LU-1, LU-2, LU-3, and LU-4, a light emitting structure that emits blue light may include the first and second buffer layers as described with reference to FIG. 3.

In an embodiment, the first buffer layers BIL-1, BIL-2, BIL-3, and BIL-4 and the second buffer layers BF-1, BF-2, BF-3, and BF-4 may each include a phosphorescent sensitizer and a light emitting dopant as described with reference to FIG. 3. The first buffer layers BIL-1, BIL-2, BIL-3, and BIL-4 may each include a hole transporting host, a phosphorescent sensitizer, and a light emitting dopant; and the second buffer layers BF-1, BF-2, BF-3, and BF-4 may each include an electron transporting host, a phosphorescent sensitizer, and a light emitting dopant. The thicknesses of the first buffer layers BIL-1, BIL-2, BIL-3, and BIL-4 and the second buffer layers BF-1, BF-2, BF-3, and BF-4 may each independently be in a range of about 20 Å to about 50 Å.

An amount of the phosphorescent sensitizer in the first buffer layers BIL-1, BIL-2, BIL-3, and BIL-4 and the second buffer layers BF-1, BF-2, BF-3, and BF-4 may each independently be in a range of about 5 wt % to about 20 wt % and an amount of the light emitting dopant in the first buffer layers BIL-1, BIL-2, BIL-3, and BIL-4 and the second buffer layers BF-1, BF-2, BF-3, and BF-4 may each independently be in a range of about 1 wt % to about 3 wt %. The first buffer layers BIL-1, BIL-2, BIL-3, and BIL-4 may each include a hole transporting host, a phosphorescent sensitizer, and a light emitting dopant; and the second buffer layers BF-1, BF-2, BF-3, and BF-4 may each include an electron transporting host, a phosphorescent sensitizer, and a light emitting dopant. The hole transporting host, the electron transporting host, the phosphorescent sensitizer, and the light emitting dopant described herein with respect to the first buffer layers BIL-1, BIL-2, BIL-3, and BIL-4 and the second buffer layers BF-1, BF-2, BF-3, and BF-4 may be the same as the description of the emission layer materials and the buffer layer materials described above with respect to FIG. 3.

The first buffer layers BIL-1, BIL-2, BIL-3, and BIL-4 may be directly disposed below the emission layers EML-1, EML-2, EML-3, and EML-4, respectively, and the second buffer layers BF-1, BF-2, BF-3, and BF-4 may be directly disposed above the emission layers EML-1, EML-2, EML-3, and EML-4, respectively.

The first buffer layers BIL-1, BIL-2, BIL-3, and BIL-4 and the second buffer layers BF-1, BF-2, BF-3, and BF-4 each include a phosphorescent sensitizer and a light emitting dopant to control hole mobility and electron mobility and to reduce the density of excitons in an emission layer, and may thus mitigate efficiency roll-off and degradation of the emission layer, thereby improving luminous efficiency and lifetime of the light emitting element ED-TD.

The light emitting element ED-TD providing source light has improved efficiency, and accordingly, the display device DD-2 according to an embodiment may exhibit excellent efficiency characteristics and reliability, and improved display quality.

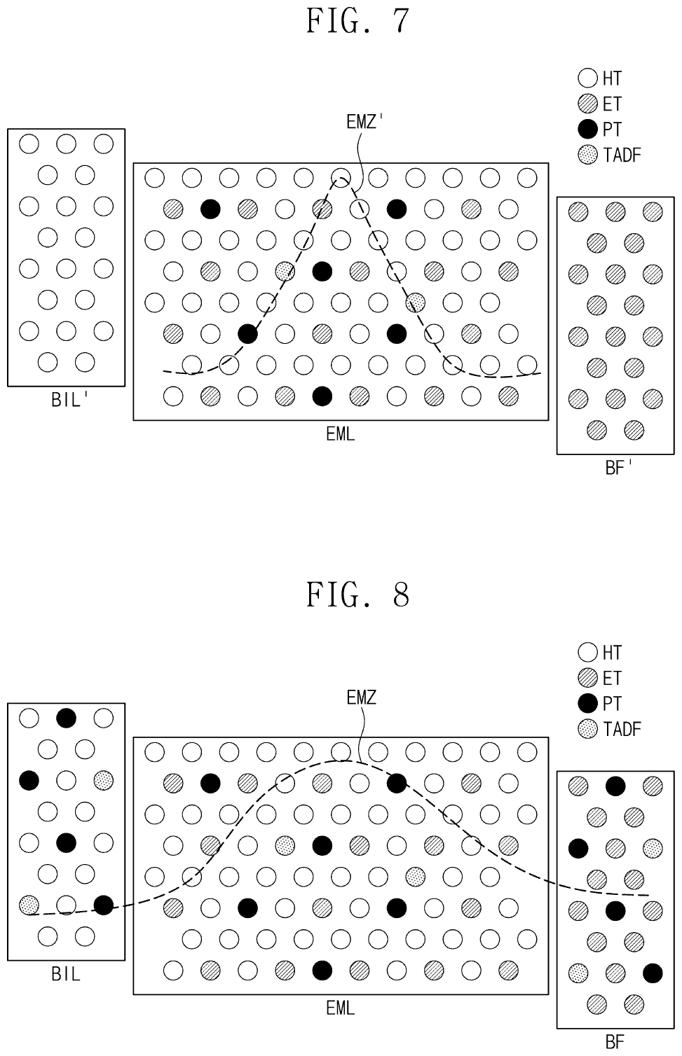

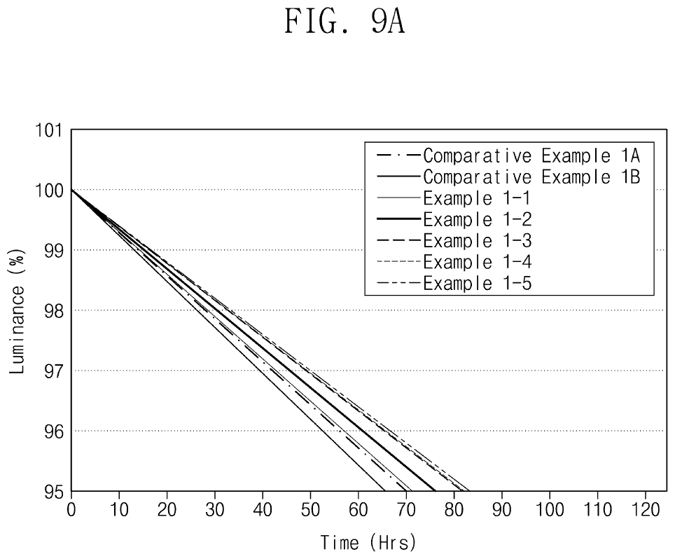

FIGS. 7 and 8 are each a schematic diagram of a configuration of a light emitting structure. FIG. 7 is a schematic diagram of a light emitting structure of a light emitting element according to the related art, and FIG. 8 is a schematic diagram of a light emitting structure of a light emitting element according to an embodiment.

Referring to FIGS. 7 and 8, the emission layer EML may include a hole transporting host HT, an electron transporting host ET, a phosphorescent sensitizer PT, and a light emitting dopant TADF. In the light emitting element according to a Comparative Example, a first buffer layer BIL′ may include only the hole transporting host HT, and a second buffer layer BF′ may include only the electron transporting host ET. In comparison, in the light emitting element according to an embodiment, the first buffer layer BIL may include the hole transporting host HT, the phosphorescent sensitizer PT, and the light emitting dopant TADF, and the second buffer layer BF may include the electron transporting host ET, the phosphorescent sensitizer PT, and the light emitting dopant TADF.

EMZ′ in FIG. 7 and EMZ in FIG. 8 each indicate an exciton emission zone. In the light emitting element according to the related art as shown in FIG. 7, the EMZ′ is distributed only within the emission layer EML, and shows a tendency for excitons to be confined within in a relatively narrow region. In comparison, in the light emitting element according to an embodiment as shown in FIG. 8, the EMZ may extend over a wide region of the emission layer EML, and a portion of the EMZ may extend and be distributed into the first buffer layer BIL and the second buffer layer BF.

Referring to FIGS. 7 and 8, the light emitting element according to an embodiment, as compared to a light emitting element according to the related art, includes the buffer layers BIL and BF each disposed adjacent to the emission layer EML and including a phosphorescent sensitizer and a light emitting dopant as dopant materials, and may thus reduce excessive exciton concentration in the emission layer EML. Accordingly, the light emitting element ED according to an embodiment has reduced degradation of the emission layer EML, and may thus exhibit improved lifetime characteristics.

Hereinafter, a light emitting element according to an embodiment will be described in detail with reference to the Examples and the Comparative Examples. The Examples described below are only provided to facilitate in understanding the disclosure, and the scope thereof is not limited thereto.

### EXAMPLES

### <Preparation of Light Emitting Elements>

A glass substrate, on which an ITO having a thickness of 150 nm was patterned, was subjected to ultrasonic cleaning using isopropyl alcohol and pure water for 5 minutes each. The glass substrate was irradiated with UV for 30 minutes, and treated with ozone to form a first electrode.

On the first electrode, HAT-CN was deposited at a thickness of 10 nm, α-NPD was deposited at a thickness of 80 nm, and mCP was deposited at a thickness of 5 nm to form a hole transport region.

A light emitting portion having a stacked structure of a first buffer layer, an emission layer, and a second buffer layer was formed on the hole transport region.

In the light emitting elements of the Examples, an emission layer was formed by co-deposition to include Compounds HT67, ETH66, AD-41, and D-11, which are respectively a hole transporting host, an electron transporting host, a phosphorescent sensitizer, and a light emitting dopant. The first buffer layer was formed to include Compounds HT67, AD-41, and D-11 used in the emission layer, and the second buffer layer was formed to include Compounds ETH66, AD-41, and D-11 used in the emission layer.

The emission layer was formed to have a thickness of 40 nm.

An electron transport region and a second electrode were sequentially formed on the light emitting portion.

On the second buffer layer, TBPi was deposited at a thickness of 30 nm, and LiF was deposited at a thickness of 0.5 nm to form an electron transport region. On electron transport region, Al was deposited to form a second electrode having a thickness of 100 nm, thereby preparing a light emitting element.

In the light emitting elements of the Examples, the hole transport region, the emission layer, the electron transport region, and the second electrode were each formed using a vacuum deposition apparatus.

### (Materials Used in Preparation of Light Emitting Elements)

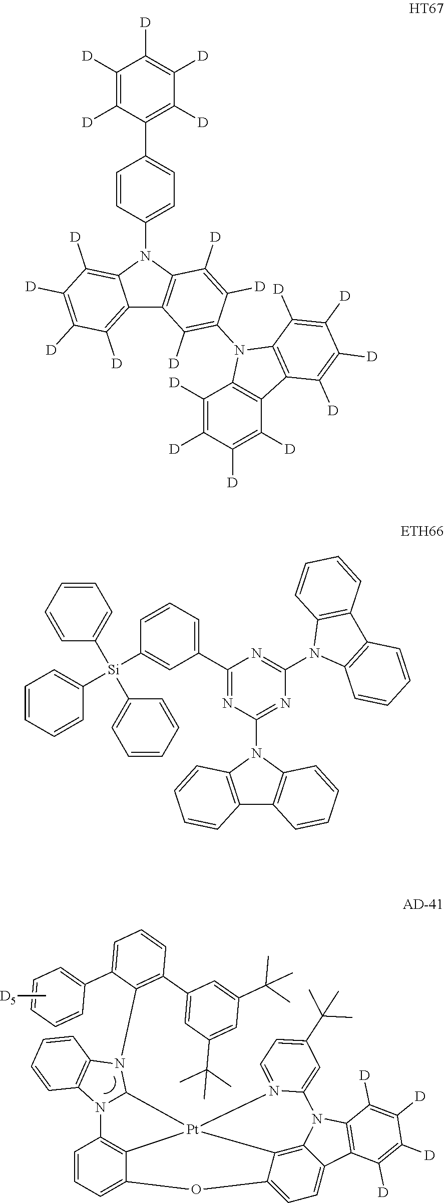

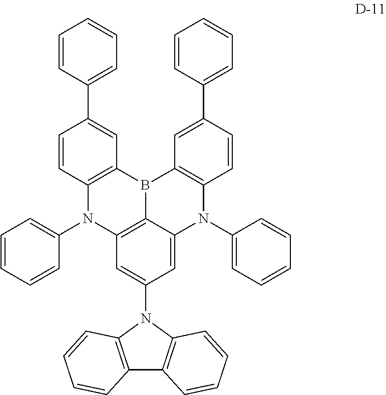 [SMILES: c1ccc(-c2ccc3c(c2)B2c4cc(-c5ccccc5)ccc4N(c4ccccc4)c4cc(-n5c6ccccc6c6ccccc65)cc(c42)N3c2ccccc2)cc1]

### (Evaluation of Light Emitting Elements)

Tables 1 and 2 compare and show the evaluation results of light emitting elements. Tables 1 and 2 compare the driving voltage, color coordinate (CIE_y), luminous efficiency with respect to color coordinate (cd/A/y), maximum emission wavelength (λₘₐₓ), and element service life (T95) of the prepared light emitting elements. The maximum emission wavelength indicates a maximum emission wavelength value in an emission spectrum of a light emitting element, and the element service life (T95) indicates an absolute time taken for the brightness to drop to 95% at a brightness of 1000 nits.

Table 1 shows the characteristics of light emitting elements evaluated while changing the thickness of first and second buffer layers in Examples 1-1 to 1-5, compared to Comparative Example 1A, which includes no phosphorescent sensitizer or light emitting dopant in first and second buffer layers, and Comparative Example 1B, which includes a phosphorescent sensitizer and a light emitting dopant in first and second buffer layers but having a thickness of 10 Å each.

In Comparative Example 1B and Examples 1-1 to 1-5 evaluated and shown in Table 1, the first buffer layer included Compounds HT67, AD-41, and D-11, and Compounds HT67, AD-41, and D-11 in the first buffer layer were co-deposited at a weight ratio (wt %) of 88:10:2. In Comparative Example 1B and Examples 1-1 to 1-5 evaluated and shown in Table 1, the second buffer layer included Compounds ETH66, AD-41, and D-11, and Compounds ETH66, AD-41, and D-11 in the second buffer layer were co-deposited at a weight ratio (wt %) of 88:10:2.

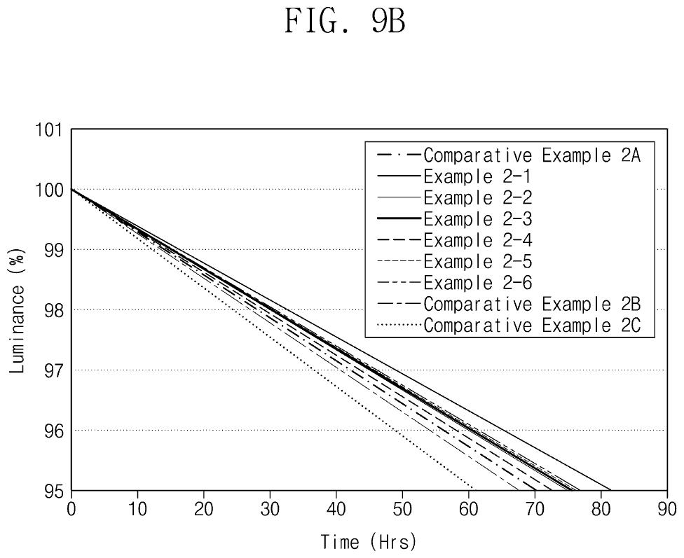

FIG. 9A is a graph showing changes in luminance over time. FIG. 9A also shows changes in luminance of Comparative Example 1A, Comparative Example 1B, and Examples 1-1 to 1-5 in Table 1.

TABLE 1

| | BIL | BF | Driving | | Color luminous | | |
|---|---|---|---|---|---|---|---|
| | thickness | thickness | voltage | | efficiency | λₘₐₓ | T95 |
| Item | (Å) | (Å) | (V) | CIE_y | (cd/A/y) | (nm) | (hrs) |
| Comparative | 50 | 50 | 4.5 | 0.162 | 98.1 | 462 | 70.5 |
| Example 1A | | | | | | | |
| Comparative | 10 | 10 | 4.2 | 0.158 | 80.1 | 462 | 66.0 |
| Example 1B | | | | | | | |
| Example 1-1 | 25 | 25 | 4.4 | 0.161 | 92.4 | 461 | 71.7 |
| Example 1-2 | 40 | 40 | 4.5 | 0.162 | 110.7 | 461 | 76.5 |
| Example 1-3 | 50 | 50 | 4.7 | 0.158 | 121.2 | 462 | 82.1 |
| Example 1-4 | 75 | 75 | 5.3 | 0.161 | 120.7 | 461 | 82.5 |
| Example 1-5 | 100 | 100 | 6.1 | 0.162 | 117.7 | 461 | 83.7 |

Referring to the results in Table 1, it is seen that Examples 1-1 to 1-5 exhibit improved color luminous efficiency and long life characteristics, as compared to Comparative Examples 1A and 1B. Example 1-3 having a same buffer layer thickness as Comparative Example 1A exhibited excellent luminous efficiency and lifetime characteristics, as compared to Comparative Example 1A. Accordingly, it is determined that the light emitting elements of the Examples including a phosphorescent sensitizer and a light emitting dopant in a buffer layer, at a same buffer layer thickness, may have improved luminous efficiency and lifetime characteristics.

When Comparative Example 1B is compared with Examples 1-1 to 1-5, it is seen that Examples 1-1 to 1-5 exhibit excellent luminous efficiency and lifetime characteristics. Thus, when the buffer layers each have a thickness as thin as about 10 A, luminous efficiency and lifetime are significantly reduced even when a phosphorescent sensitizer and a light emitting dopant are included.

Examples 1-4 and 1-5 exhibited excellent element characteristics as compared to Comparative Examples 1A and 1B, but showed high driving voltage as compared to Examples 1-1 to 1-3. Thus, when the thickness of the buffer layers increases, there is an improvement in luminous efficiency and lifetime, but the driving voltage tends to increase.

Referring to the results of luminance change in FIG. 9A, it is seen that the light emitting elements of the Examples exhibit excellent lifetime characteristics compared to the light emitting elements of the Comparative Examples (Comparative Examples 1A and 1B). The degree of decrease in luminance over time is smaller in the Examples than in the Comparative Examples, indicating that the Examples exhibit long lifetime characteristics as compared to the Comparative Examples.

Table 2 shows the results of evaluation by changing the content of a phosphorescent sensitizer or light emitting dopant included in the first buffer layer and the second buffer layer. For Comparative Examples 2A to 2C and Examples 2-1 to 2-6 evaluated in Table 2, the thicknesses of the first buffer layer and the second buffer layer were each set to 50 Å. In Examples 2-1 to 2-3, the content of a phosphorescent sensitizer in the buffer layer was fixed and the content of a light emitting dopant was changed, and in Examples 2-4 to 2-6, the content of a light emitting dopant was fixed and the content of a phosphorescent sensitizer was changed.

Comparative Example 2A is a case in which the first buffer layer and the second buffer layer include no phosphorescent sensitizer and no light emitting dopant, and Comparative Example 2B is a case having a greater content of light emitting dopant than the Examples, with 5 wt % of the light emitting dopant in the first and second buffer layers. Comparative Example 2C is a case having a greater content of phosphorescent sensitizer than the Examples, with 30 wt % of the phosphorescent sensitizer in the first and second buffer layers.

FIG. 9B is a graph showing changes in luminance over time. FIG. 9B also shows changes in luminance of Comparative Examples 2A to 2C, and Examples 2-1 to 2-6 in Table 2.

TABLE 2

| | | | | | Color | | |
|---|---|---|---|---|---|---|---|
| | BIL | BF | Driving | | luminous | | |
| | (HT67:AD- | (ETH66:AD- | voltage | | efficiency | λₘₐₓ | T95 |
| Item | 41:D-11) | 41:D-11) | (V) | CIE_y | (cd/A/y) | (nm) | (hrs) |
| Comparative | 100:0:0 | 100:0:0 | 4.5 | 0.162 | 98.1 | 462 | 70.5 |
| Example 2A | | | | | | | |
| Comparative | 75:20:5 | 75:20:5 | 4.7 | 0.157 | 102.3 | 461 | 68.2 |
| Example 2B | | | | | | | |
| Comparative | 68:30:2 | 68:30:2 | 4.7 | 0.188 | 77.1 | 464 | 61.5 |
| Example 2C | | | | | | | |
| Example 2-1 | 88:10:2 | 88:10:2 | 4.7 | 0.158 | 121.2 | 462 | 82.1 |
| Example 2-2 | 89:10:1 | 89:10:1 | 4.7 | 0.161 | 126.5 | 461 | 75.4 |
| Example 2-3 | 87:10:3 | 87:10:3 | 4.7 | 0.162 | 110.5 | 461 | 76.1 |
| Example 2-4 | 93:5:2 | 93:5:2 | 4.7 | 0.160 | 100.8 | 461 | 73.1 |
| Example 2-5 | 83:15:2 | 83:15:2 | 4.7 | 0.161 | 111.0 | 461 | 76.7 |
| Example 2-6 | 78:20:2 | 78:20:2 | 4.7 | 0.162 | 128.7 | 461 | 77.3 |

Referring to the results in Table 2, Examples 2-1 to 2-6 had slightly increased driving voltage as compared to Comparative Example 2A, but Examples 2-1 to 2-6 exhibited high color luminous efficiency and improved lifetime characteristics, compared to Comparative Example 2A, which does not include the first and second buffer layers according to embodiments. Examples 2-1 to 2-6 exhibited high color luminous efficiency and improved lifetime characteristics, as compared to Comparative Example 2B, which includes a light emitting dopant in an amount of greater than 3 wt % in each of the first and second buffer layers. Examples 2-1 to 2-6 exhibited high color luminous efficiency and improved lifetime characteristics, as compared to Comparative Example 2C, which includes a phosphorescent sensitizer in an amount of greater than 20 wt % in each of the first and second buffer layers. Referring to the results in Table 2, Examples 2-1 to 2-3 having different contents of the light emitting dopant in the buffer layer were all found to exhibit excellent element characteristics, as compared to Comparative Examples 2A and 2B. Thus, it is determined that when the first buffer layer and the second buffer layer each include a phosphorescent sensitizer and an amount of a light emitting dopant in a range of 1 wt % to 3 wt %, efficiency and lifetime characteristics of an element may be improved.

Examples 2-4 to 2-6, in which the content of the phosphorescent sensitizer in the buffer layer was different, all exhibited excellent element characteristics, as compared to Comparative Examples 2A and 2C. Thus, it is determined that when the first buffer layer and the second buffer layer each include a light emitting dopant and an amount of a phosphorescent sensitizer in a range of about 5 wt % to about 20 wt %, efficiency and lifetime characteristics of an element may be improved.

The light emitting element according to an embodiment includes buffer layers disposed above and below an emission layer and the buffer layers each include a phosphorescent sensitizer and a light emitting dopant, and may thus mitigate excessive exciton concentration in the emission layer and may control the mobility of holes and electrons, thereby exhibiting improved characteristics of luminous efficiency and lifetime.

A display device according to an embodiment includes a light emitting element providing a source light in which the light emitting element includes buffer layers disposed above and below an emission layer and the buffer layers each include a phosphorescent sensitizer and a light emitting dopant, thereby increasing luminous efficiency and lifetime, and may thus exhibit high light emission efficiency and improved reliability, resulting in excellent display quality.

A light emitting element according to an embodiment includes a buffer layer disposed adjacent to each of a lower portion and an upper portion of an emission layer and including a dopant material, and may thus exhibit improved lifetime characteristics and high efficiency characteristics.

A display device according to an embodiment may exhibit excellent display quality and reliability.

Embodiments have been disclosed herein, and although terms are employed, they are used and are to be interpreted in a generic and descriptive sense only and not for the purposes of limitation. In some instances, as would be apparent to one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light emitting element comprising:
a first electrode;
a hole transport region disposed on the first electrode;
an emission layer disposed on the hole transport region;
an electron transport region disposed on the emission layer;
a second electrode disposed on the electron transport region;
a first buffer layer disposed between the hole transport region and the emission layer; and
a second buffer layer disposed between the emission layer and the electron transport region, wherein
the emission layer includes:
a hole transporting host;
an electron transporting host;
a phosphorescent sensitizer; and
a light emitting dopant,
the first buffer layer includes:
the hole transporting host;
the phosphorescent sensitizer; and
the light emitting dopant,
the second buffer layer includes:
the electron transporting host;
the phosphorescent sensitizer; and
the light emitting dopant, and
the first buffer layer and the second buffer layer each independently have a thickness in a range of about 20 Å to about 50 Å.

2. The light emitting element of claim 1, wherein
an amount of the phosphorescent sensitizer in the first buffer layer and the second buffer layer is each independently in a range of about 5 wt % to about 20 wt %, and
an amount of the light emitting dopant in the first buffer layer and the second buffer layer is each independently in a range of about 1 wt % to about 3 wt %.

3. The light emitting element of claim 1, wherein the first buffer layer and the second buffer layer are each directly disposed on the emission layer.

4. The light emitting element of claim 1, wherein
the hole transport region comprises:
a hole transport layer; and
a hole injection layer disposed between the first electrode and the hole transport layer,
the electron transport region comprises:
an electron transport layer; and
an electron injection layer disposed between the electron transport layer and the second electrode,
the first buffer layer is directly disposed between the hole transport layer and the emission layer, and
the second buffer layer is directly disposed between the emission layer and the electron transport layer.

5. The light emitting element of claim 1, wherein in the emission layer, a weight ratio of the hole transporting host to the electron transporting host is in a range of about 3:7 to about 7:3.

6. The light emitting element of claim 1, wherein in the emission layer,
an amount of the phosphorescent sensitizer is in a range of about 10 wt % to about 20 wt %, and
an amount of the light emitting dopant is in a range of about 2 wt % to about 5 wt %.

7. The light emitting element of claim 1, wherein
the hole transporting host comprises at least one compound selected from Compound Group 1, and
the electron transporting host comprises at least one compound selected from Compound Group 2: 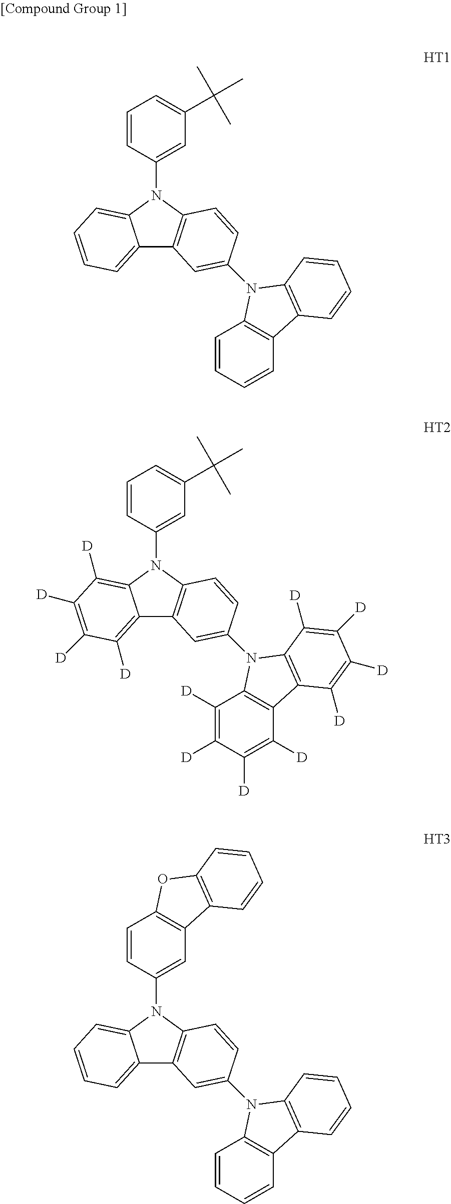 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12] 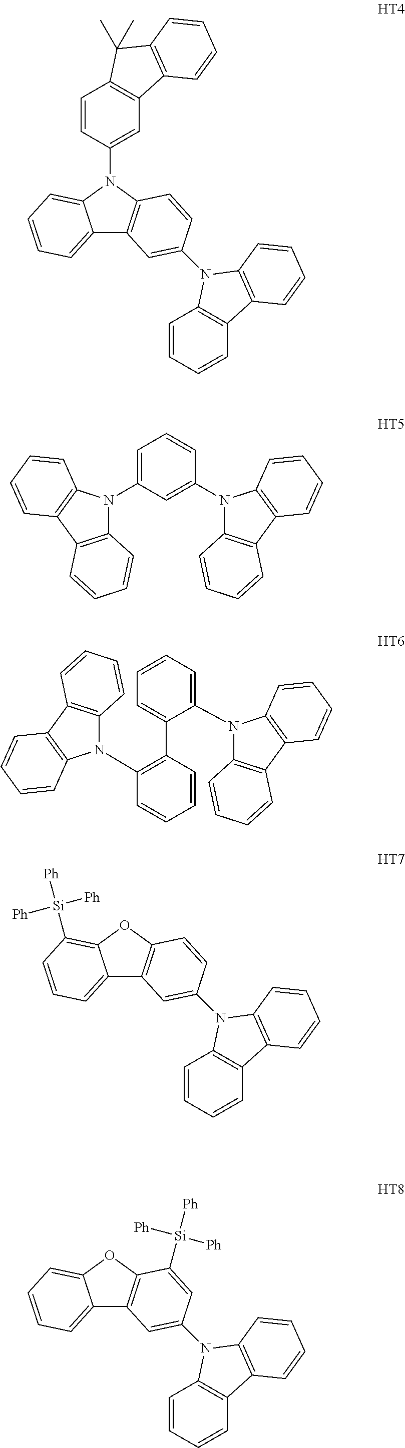 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1 ; c1ccc([Si](c2ccccc2)(c2ccccc2)c2cc(-n3c4ccccc4c4ccccc43)cc3c2oc2ccccc23)cc1] 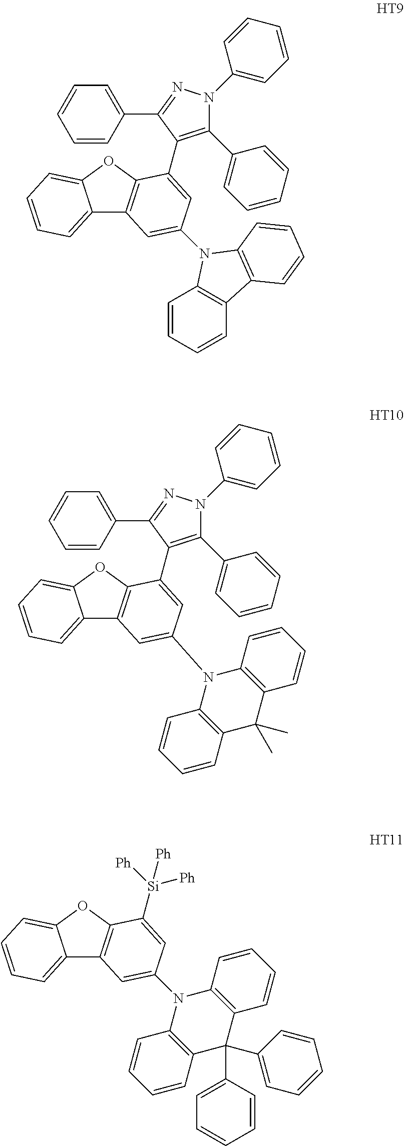 [SMILES: c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1] 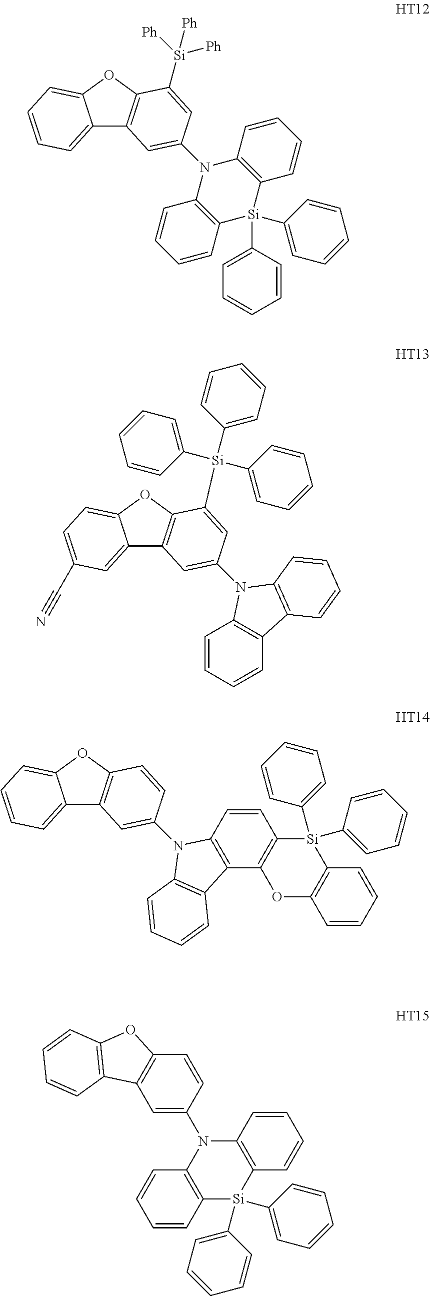 [SMILES: c1ccc([Si]2(c3ccccc3)c3ccccc3N(c3cc([Si](c4ccccc4)(c4ccccc4)c4ccccc4)c4oc5ccccc5c4c3)c3ccccc32)cc1 ; N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1] 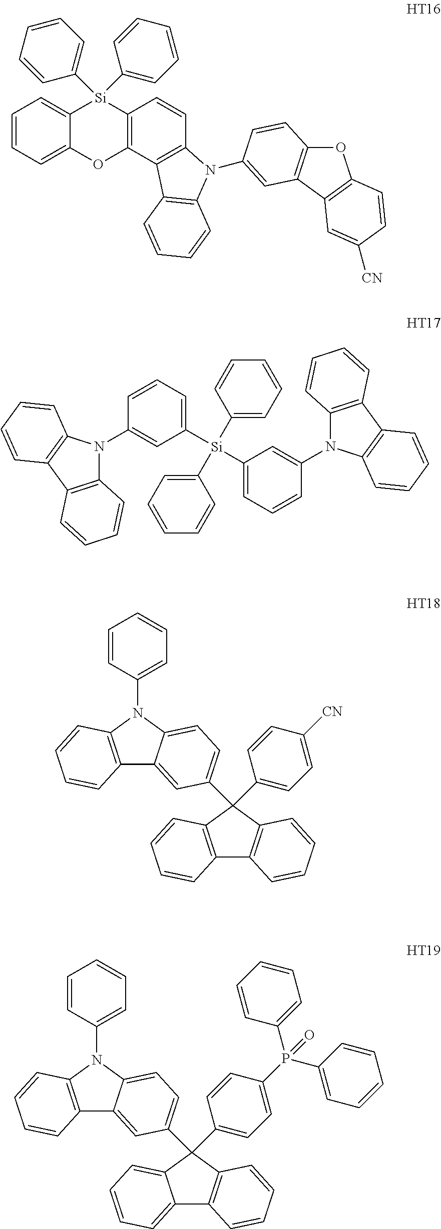 [SMILES: N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1] 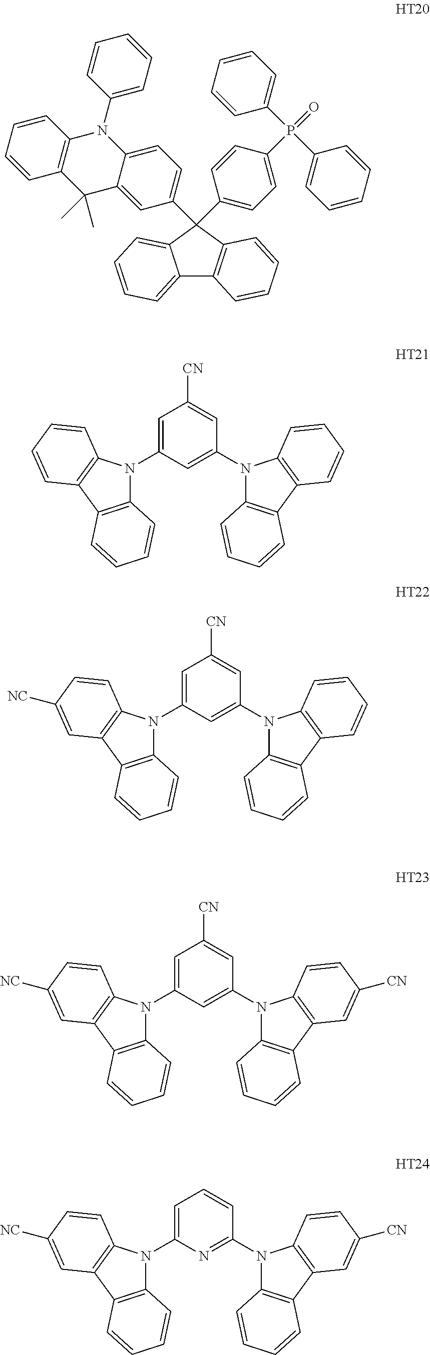 [SMILES: CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1] 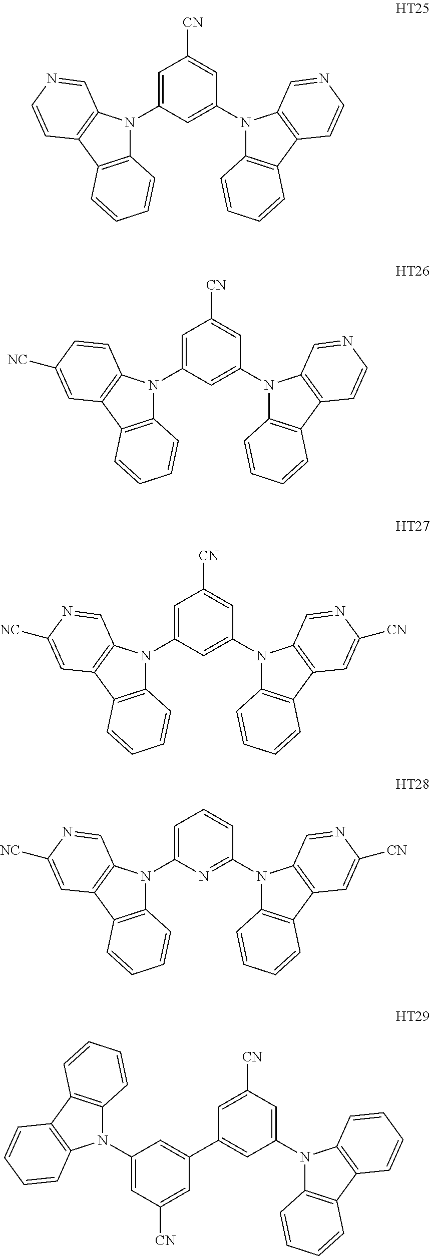 [SMILES: N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1] 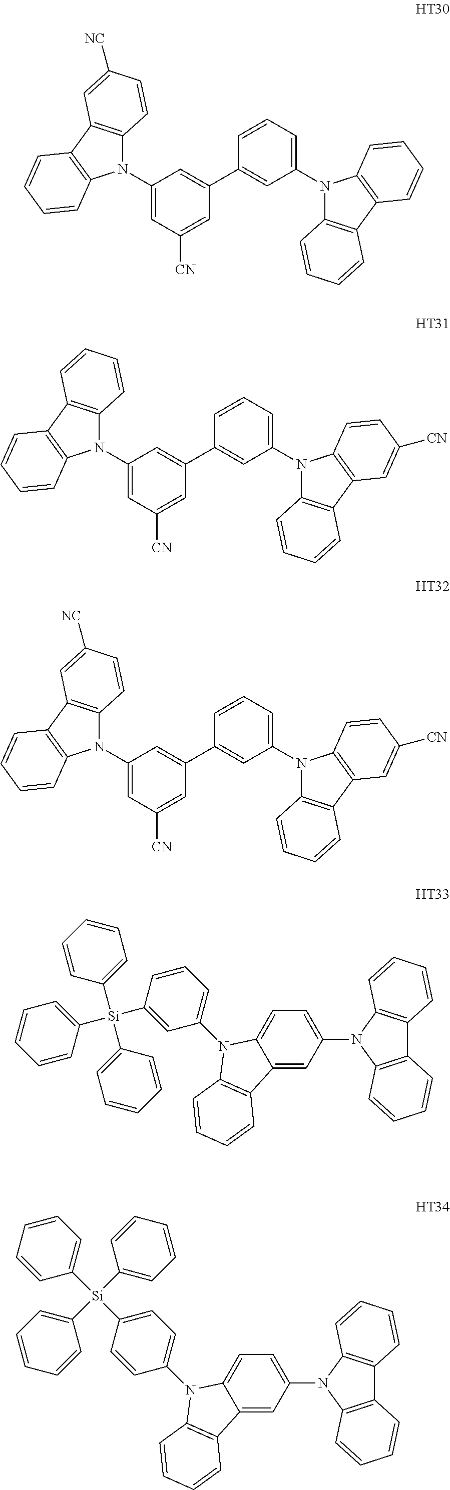 [SMILES: N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1 ; c1ccc([Si](c2ccccc2)(c2ccccc2)c2cccc(-n3c4ccccc4c4cc(-n5c6ccccc6c6ccccc65)ccc43)c2)cc1 ; c1ccc([Si](c2ccccc2)(c2ccccc2)c2ccc(-n3c4ccccc4c4cc(-n5c6ccccc6c6ccccc65)ccc43)cc2)cc1] 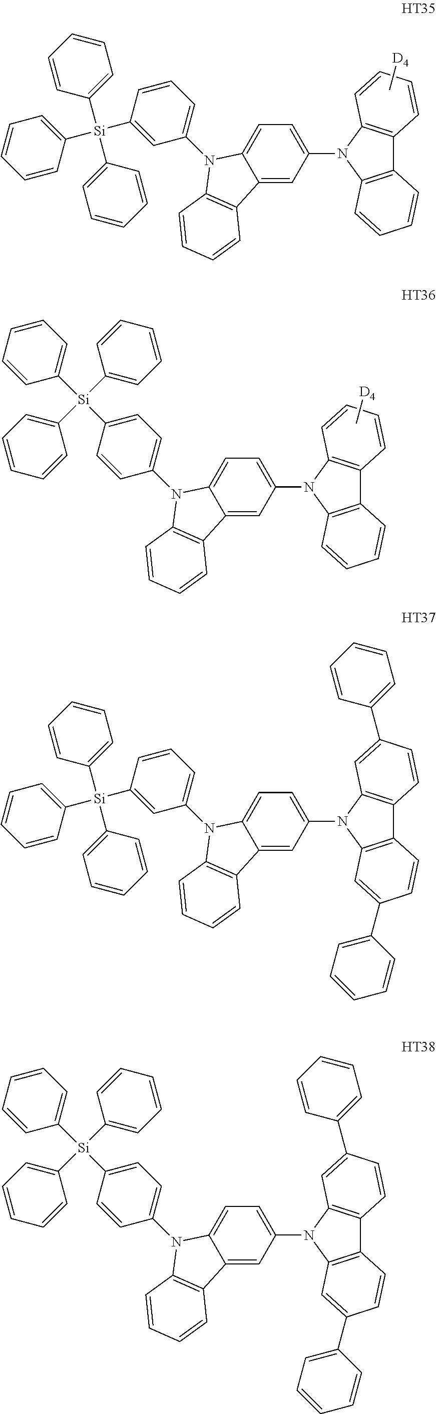 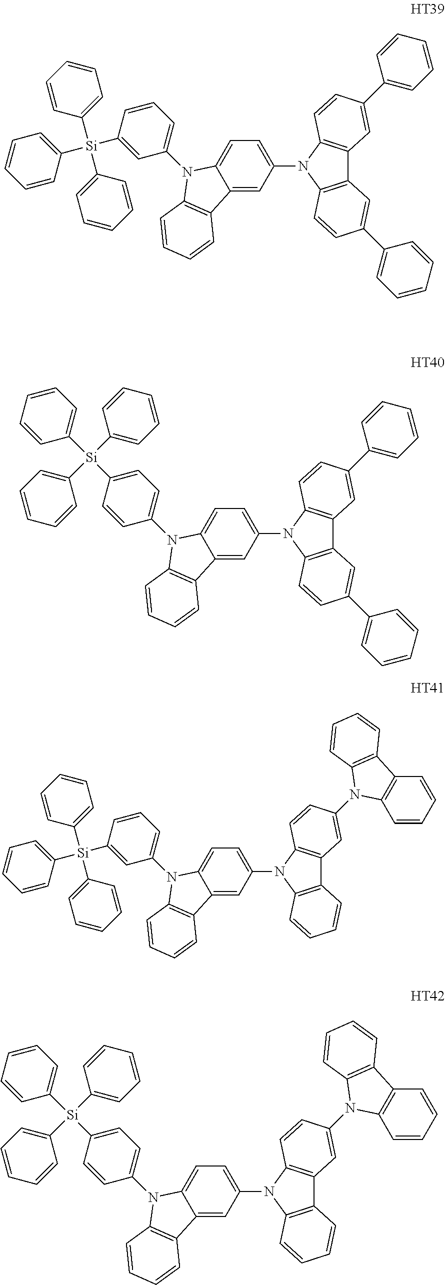 [SMILES: c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1] 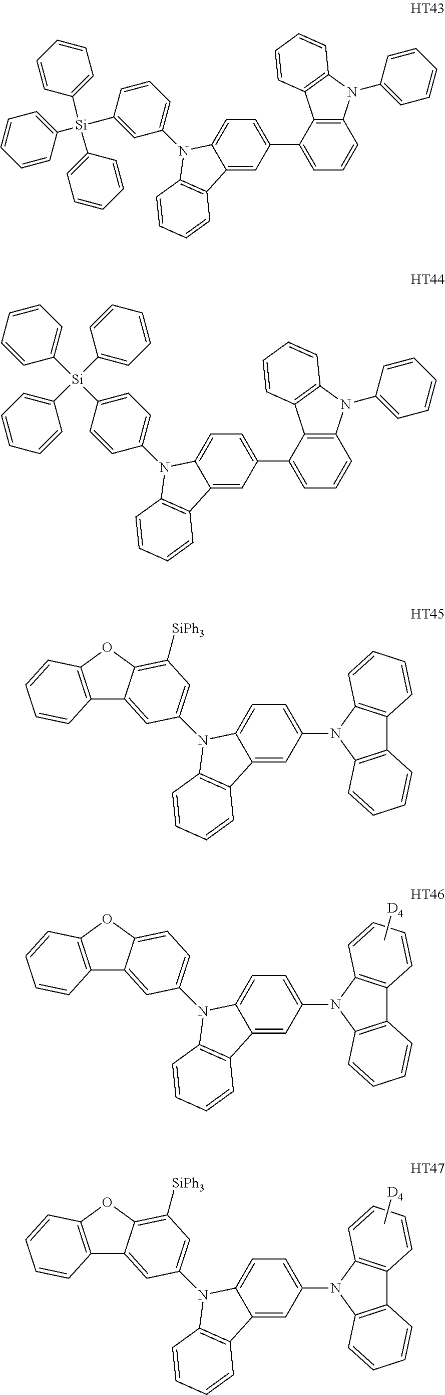 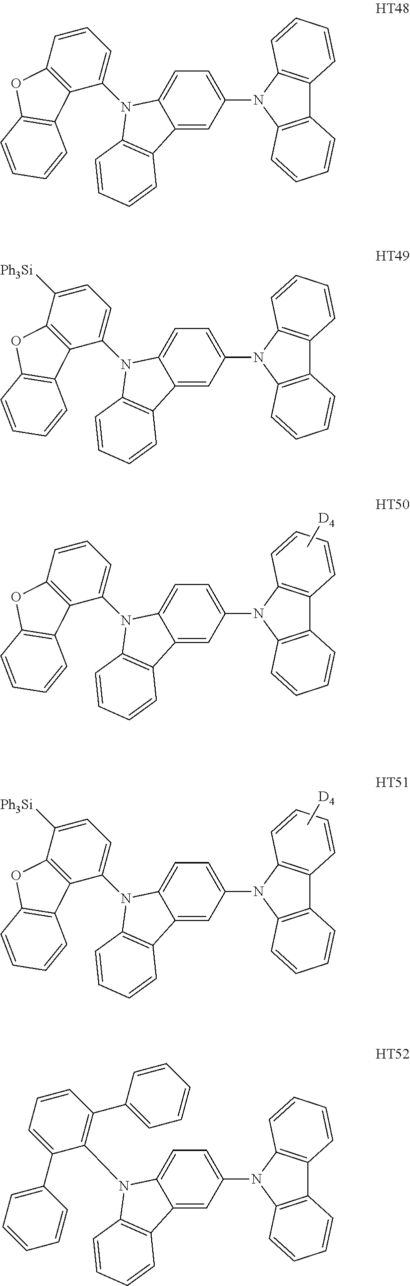 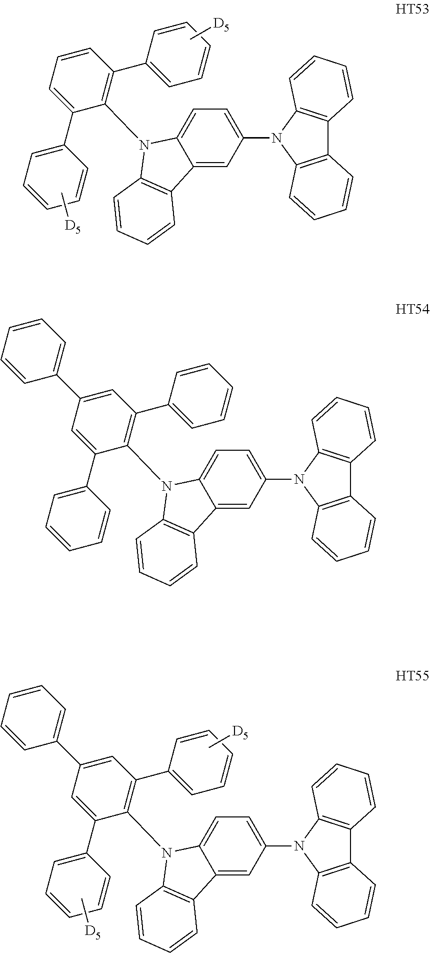 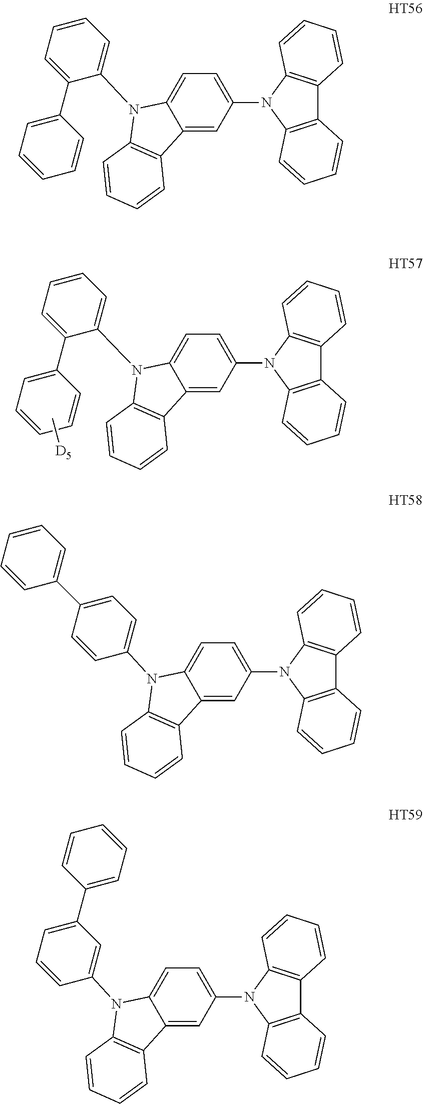 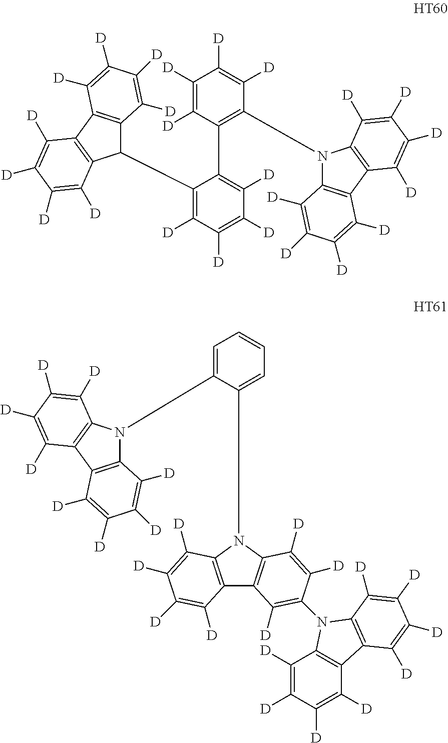 [SMILES: [2H]c1c([2H])c([2H])c2c(c1[2H])-c1c([2H])c([2H])c([2H])c([2H])c1C2c1c([2H])c([2H])c([2H])c([2H])c1-c1c([2H])c([2H])c([2H])c([2H])c1-n1c2c([2H])c([2H])c([2H])c([2H])c2c2c([2H])c([2H])c([2H])c([2H])c21 ; [2H]c1c([2H])c([2H])c2c(c1[2H])c1c([2H])c([2H])c([2H])c([2H])c1n2-c1ccccc1-n1c2c([2H])c([2H])c([2H])c([2H])c2c2c([2H])c(-n3c4c([2H])c([2H])c([2H])c([2H])c4c4c([2H])c([2H])c([2H])c([2H])c43)c([2H])c([2H])c21] 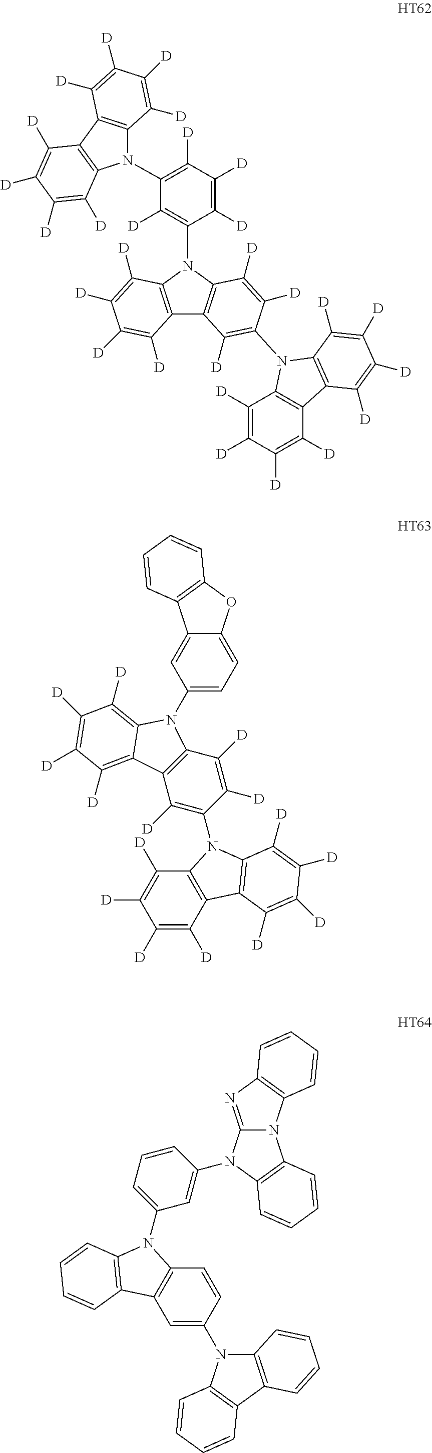 [SMILES: [2H]c1c([2H])c(-n2c3c([2H])c([2H])c([2H])c([2H])c3c3c([2H])c([2H])c([2H])c([2H])c32)c([2H])c(-n2c3c([2H])c([2H])c([2H])c([2H])c3c3c([2H])c(-n4c5c([2H])c([2H])c([2H])c([2H])c5c5c([2H])c([2H])c([2H])c([2H])c54)c([2H])c([2H])c32)c1[2H] ; [2H]c1c([2H])c([2H])c2c(c1[2H])c1c([2H])c(-n3c4c([2H])c([2H])c([2H])c([2H])c4c4c([2H])c([2H])c([2H])c([2H])c43)c([2H])c([2H])c1n2-c1ccc2oc3ccccc3c2c1 ; c1cc(-n2c3ccccc3c3cc(-n4c5ccccc5c5ccccc54)ccc32)cc(-n2c3ccccc3n3c4ccccc4nc23)c1] 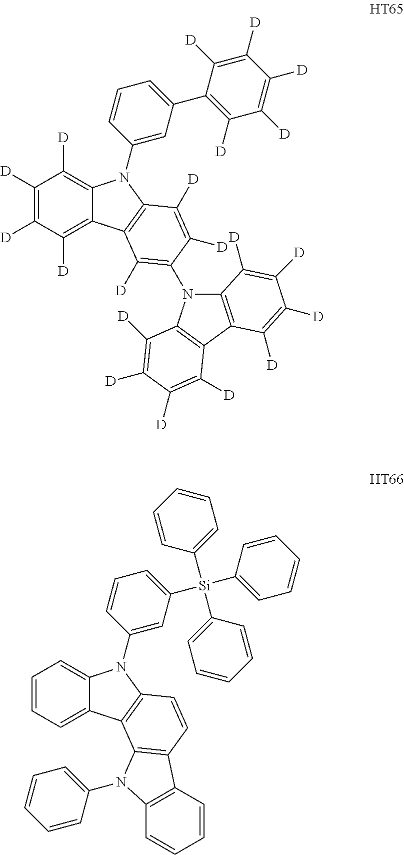 [SMILES: [2H]c1c([2H])c([2H])c(-c2cccc(-n3c4c([2H])c([2H])c([2H])c([2H])c4c4c([2H])c(-n5c6c([2H])c([2H])c([2H])c([2H])c6c6c([2H])c([2H])c([2H])c([2H])c65)c([2H])c([2H])c43)c2)c([2H])c1[2H] ; c1ccc(-n2c3ccccc3c3ccc4c(c5ccccc5n4-c4cccc([Si](c5ccccc5)(c5ccccc5)c5ccccc5)c4)c32)cc1] 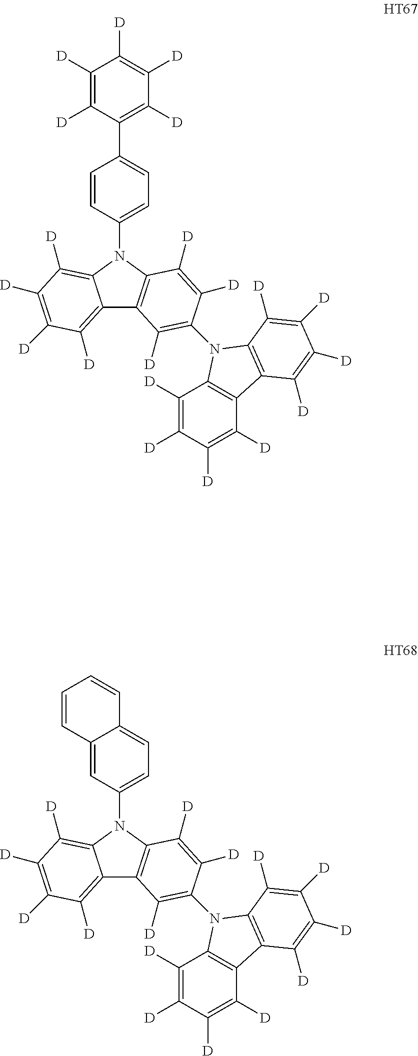 [SMILES: [2H]c1c([2H])c([2H])c(-c2ccc(-n3c4c([2H])c([2H])c([2H])c([2H])c4c4c([2H])c(-n5c6c([2H])c([2H])c([2H])c([2H])c6c6c([2H])c([2H])c([2H])c([2H])c65)c([2H])c([2H])c43)cc2)c([2H])c1[2H] ; [2H]c1c([2H])c([2H])c2c(c1[2H])c1c([2H])c(-n3c4c([2H])c([2H])c([2H])c([2H])c4c4c([2H])c([2H])c([2H])c([2H])c43)c([2H])c([2H])c1n2-c1ccc2ccccc2c1] 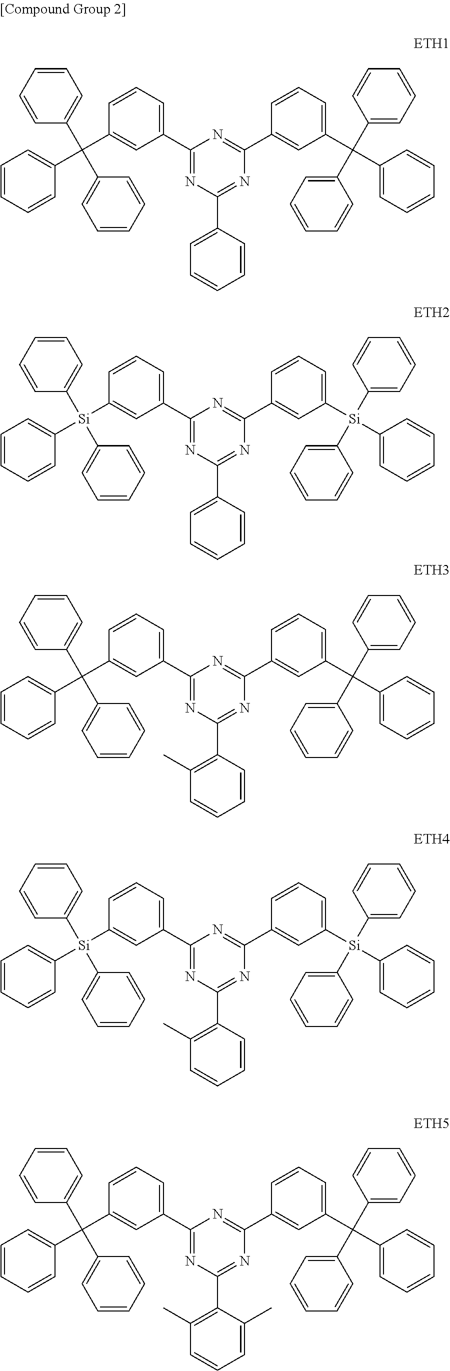 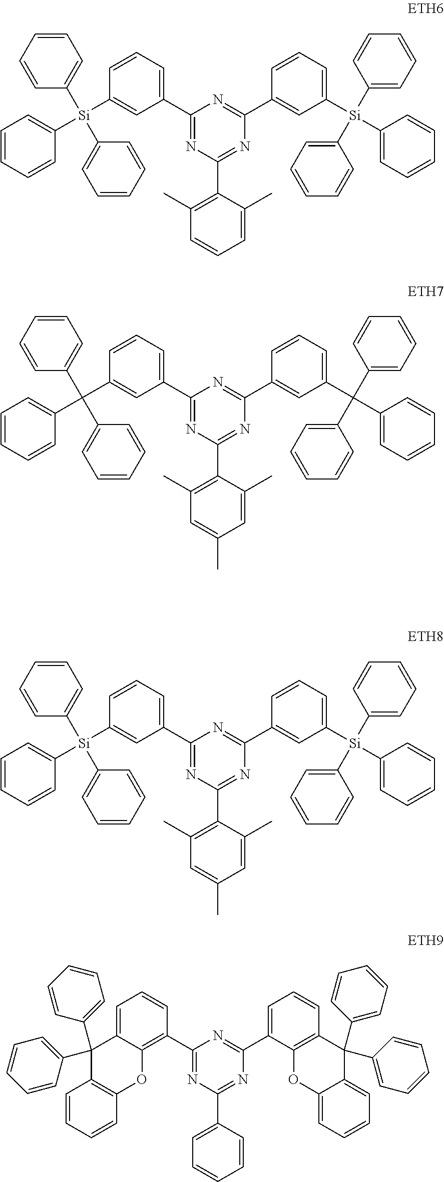 [SMILES: Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1 ; c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1] 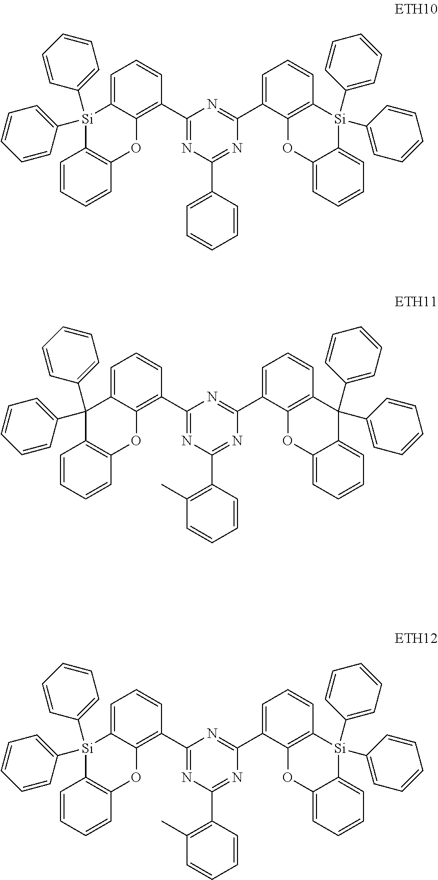 [SMILES: c1ccc(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1] 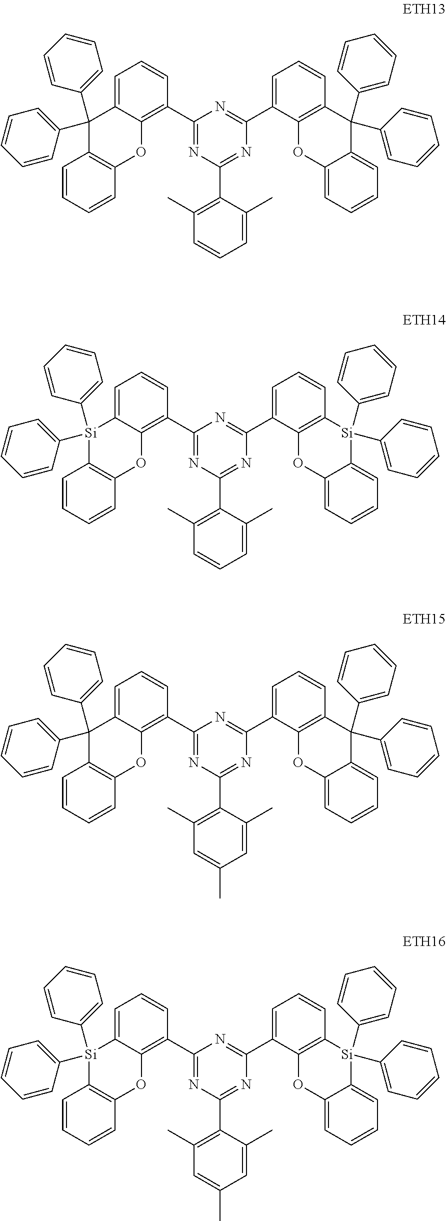 [SMILES: Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1] 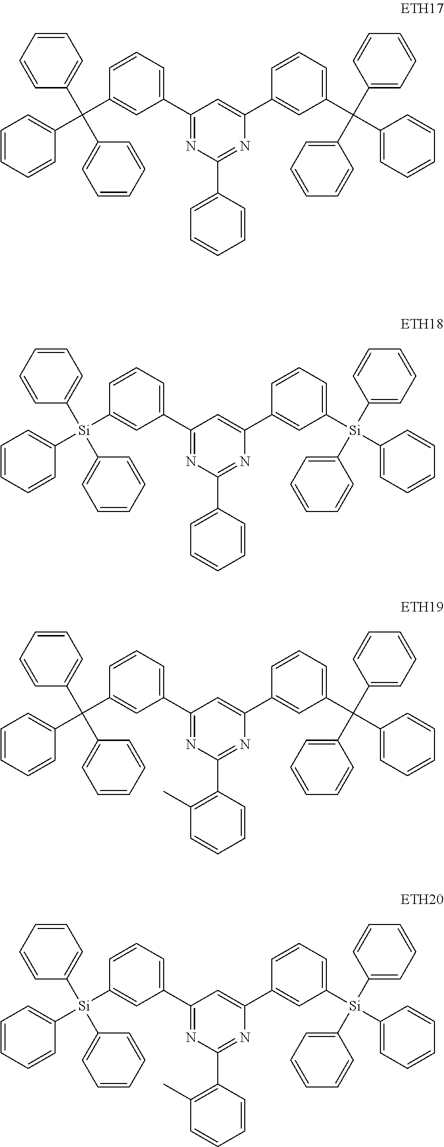 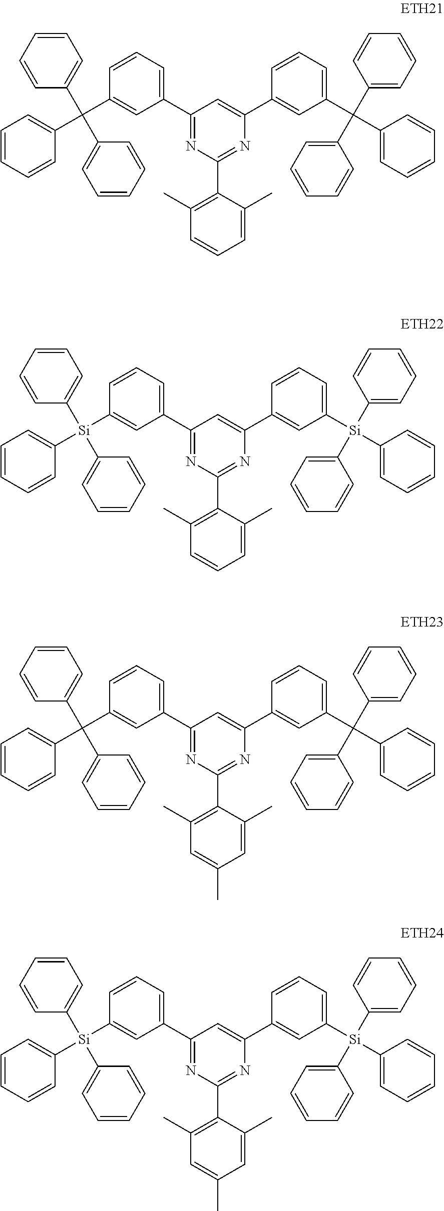 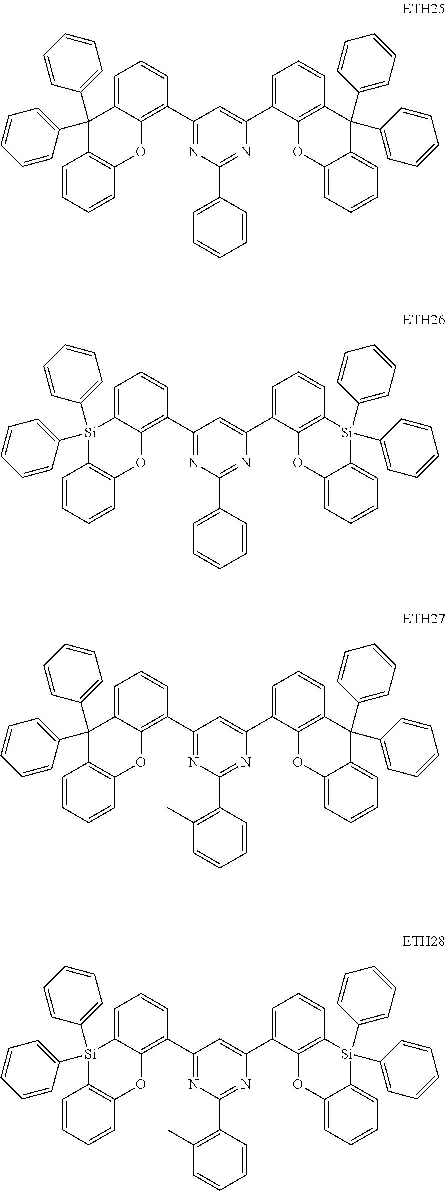 [SMILES: c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1] 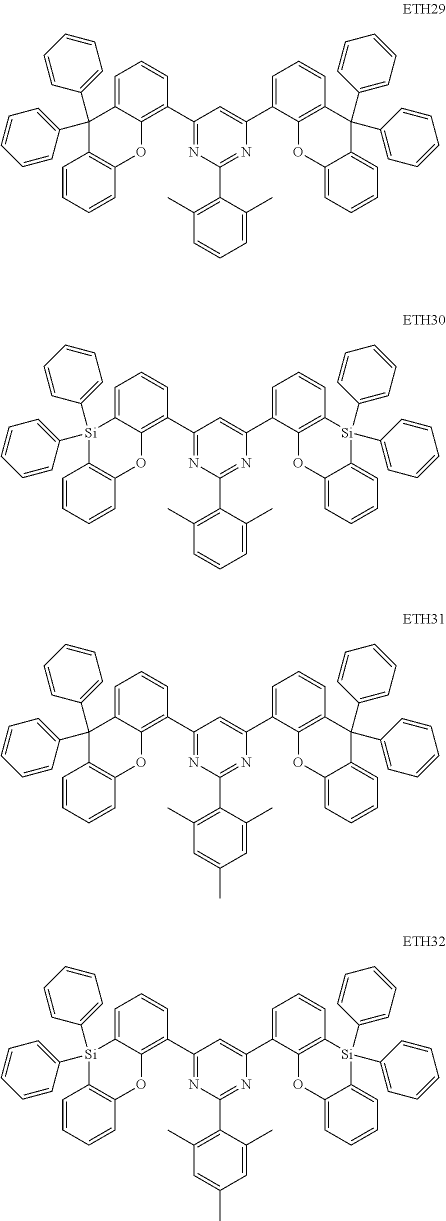 [SMILES: Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1] 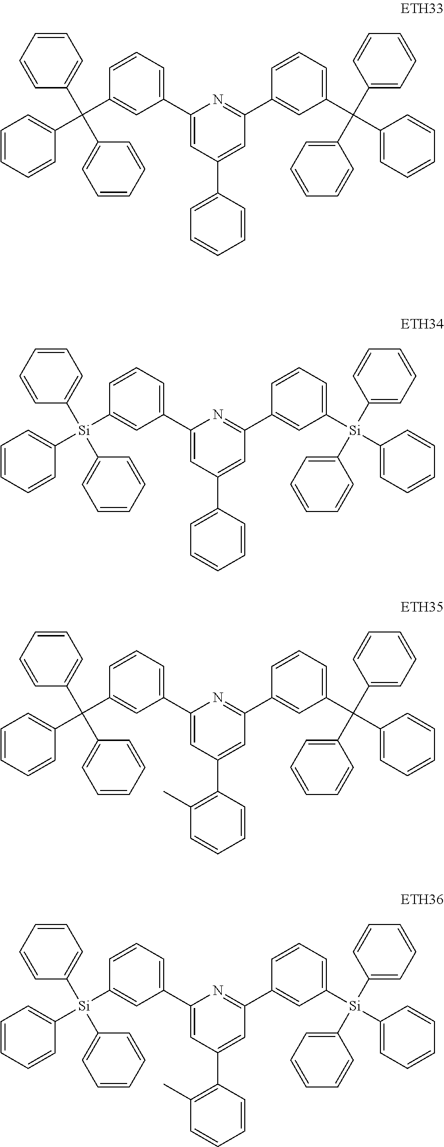 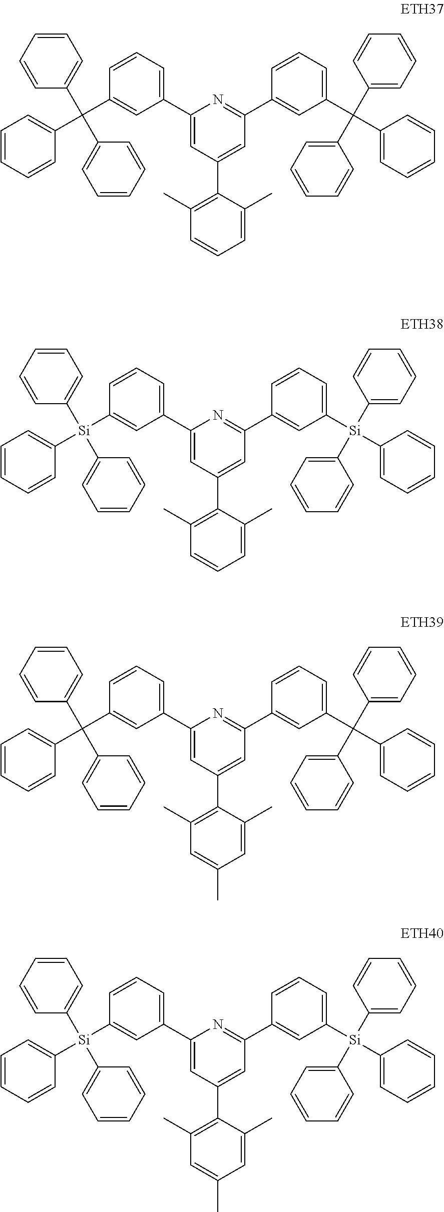 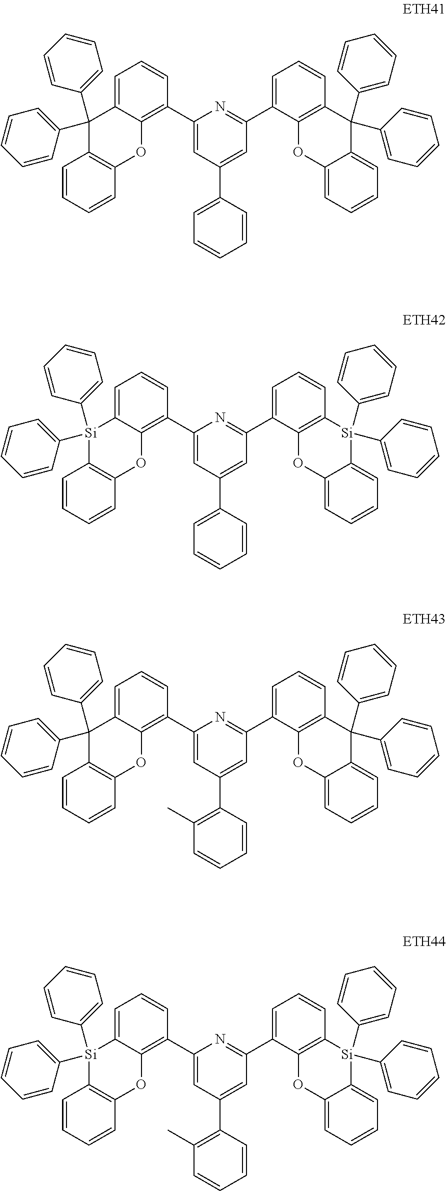 [SMILES: c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1] 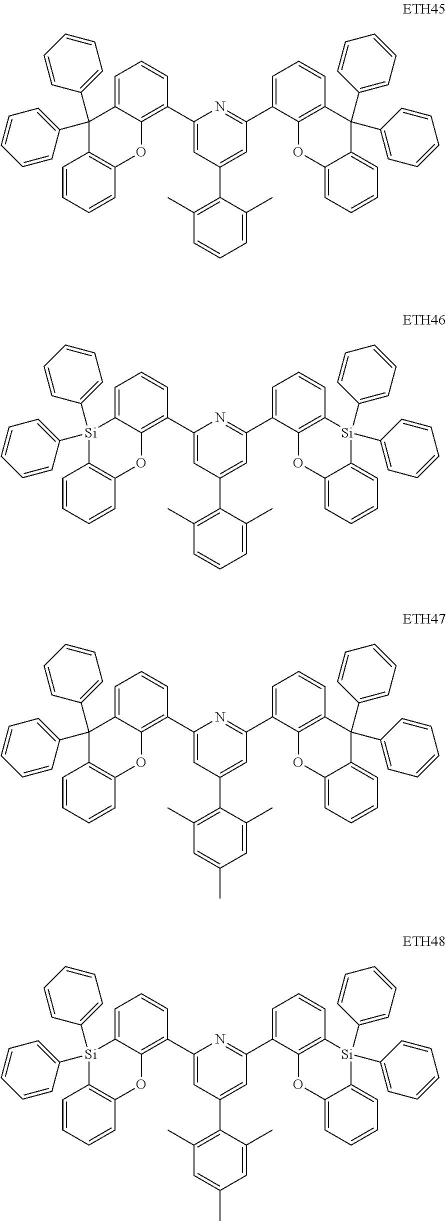 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1] 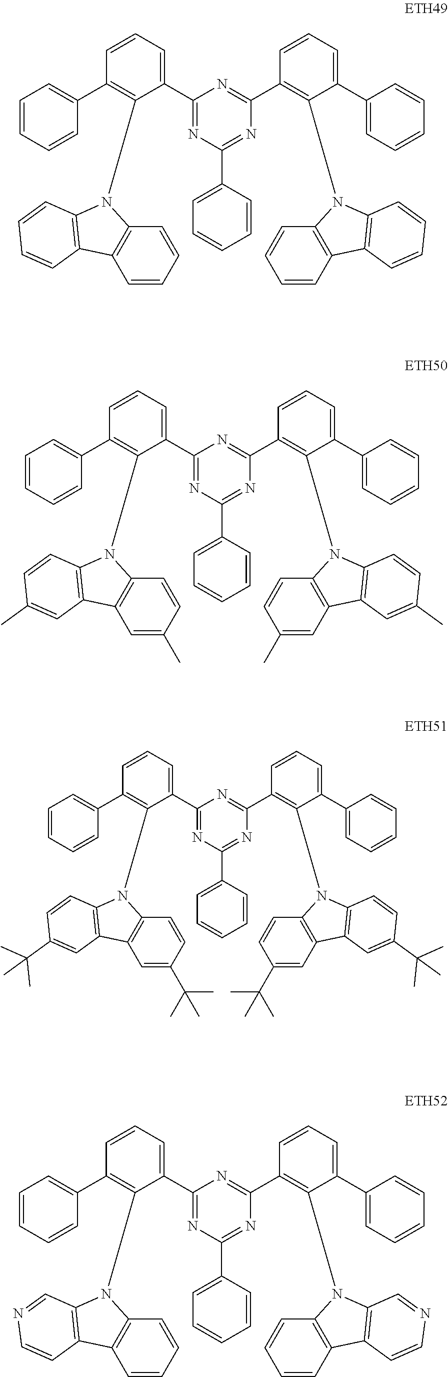 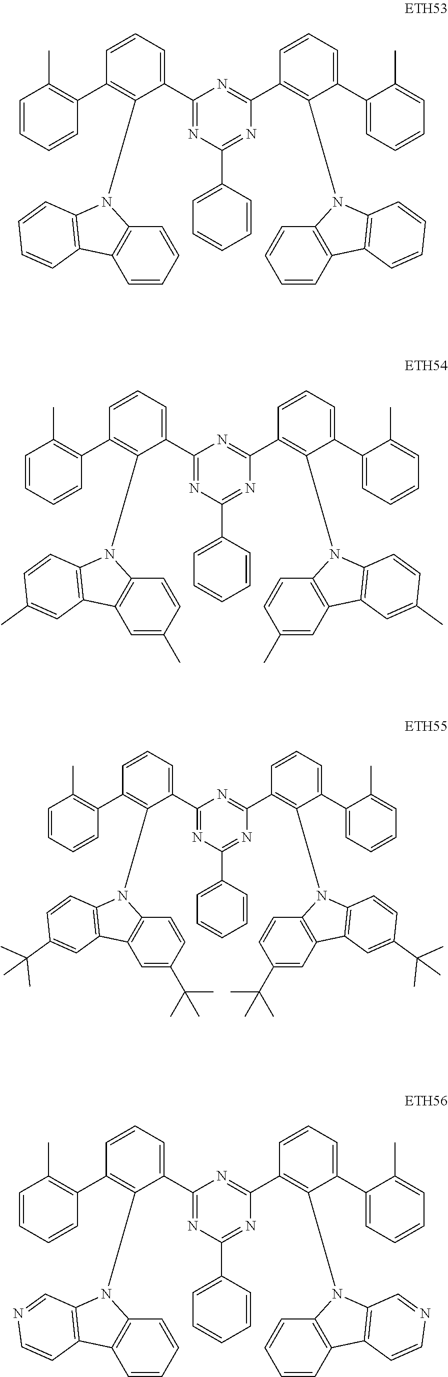 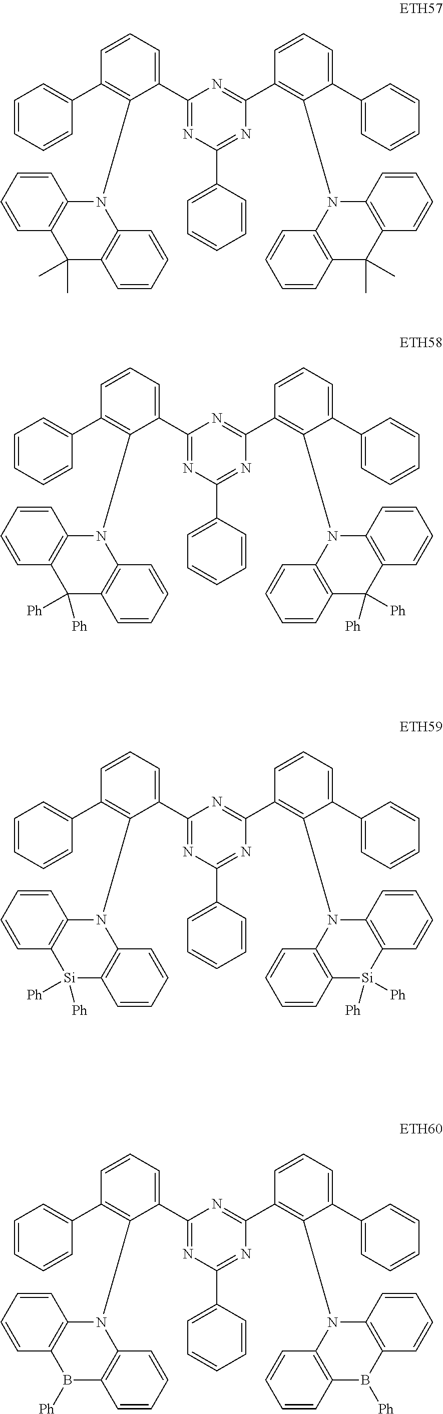 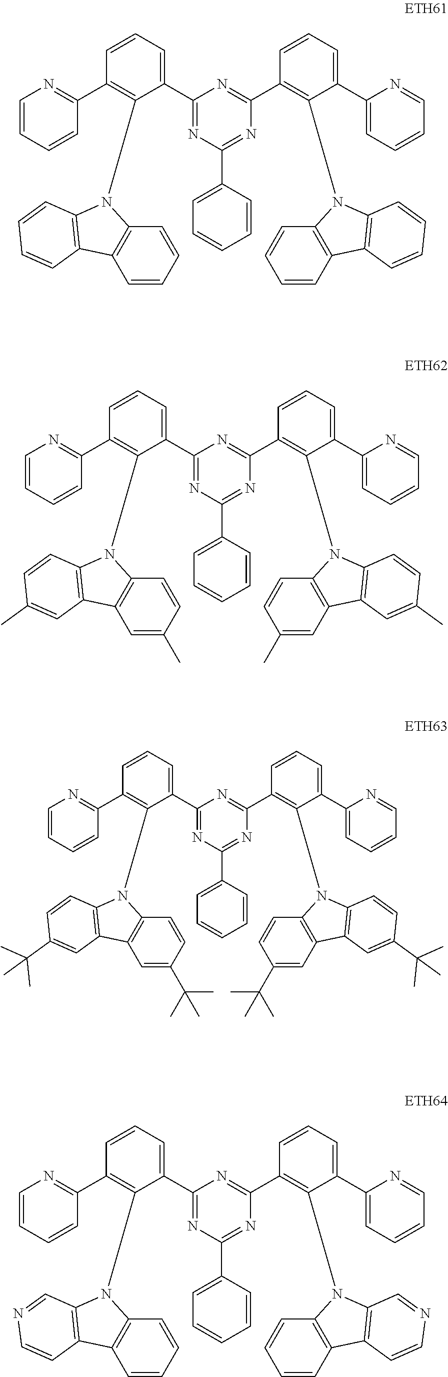 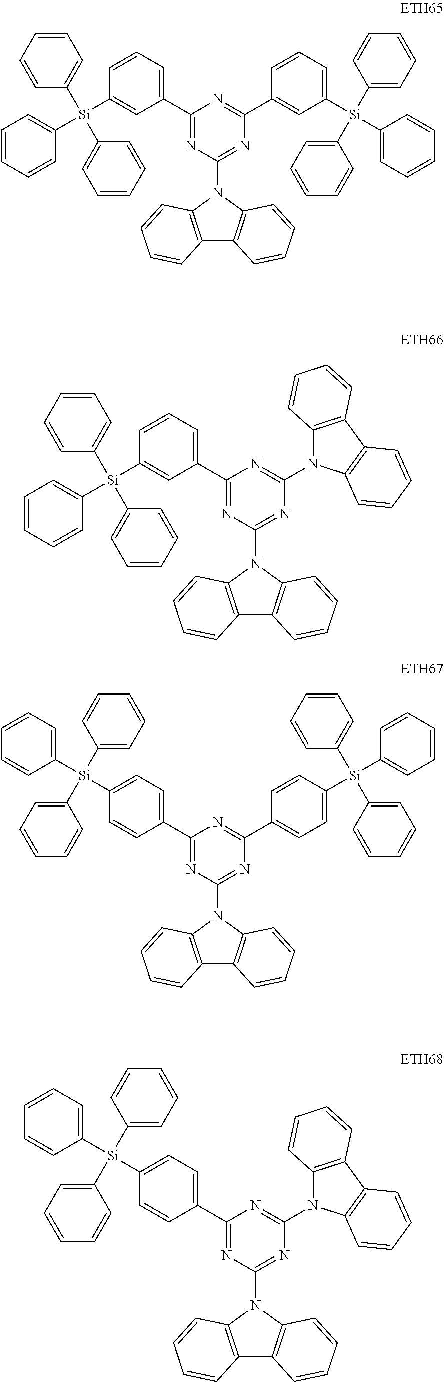 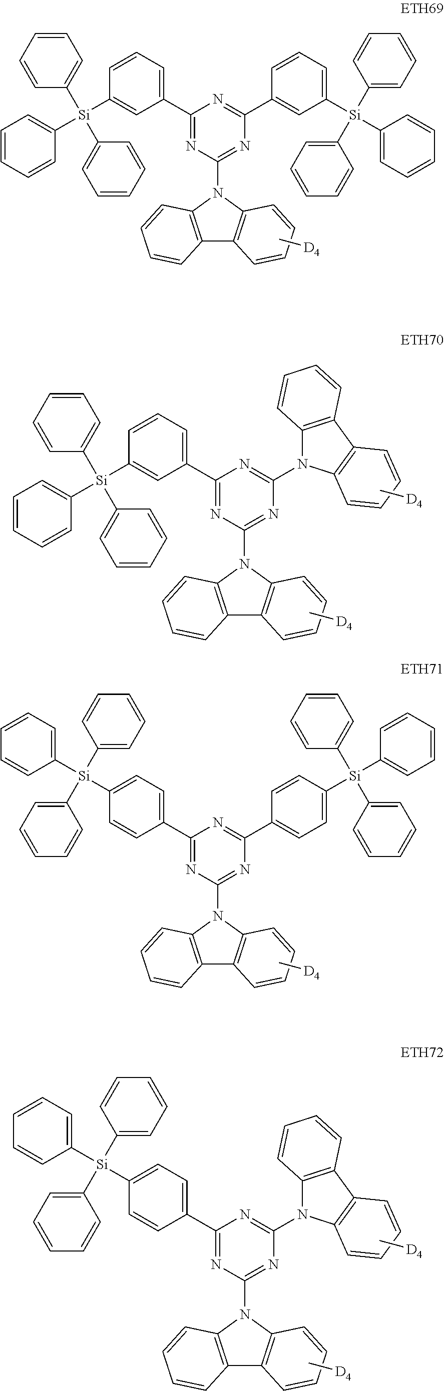 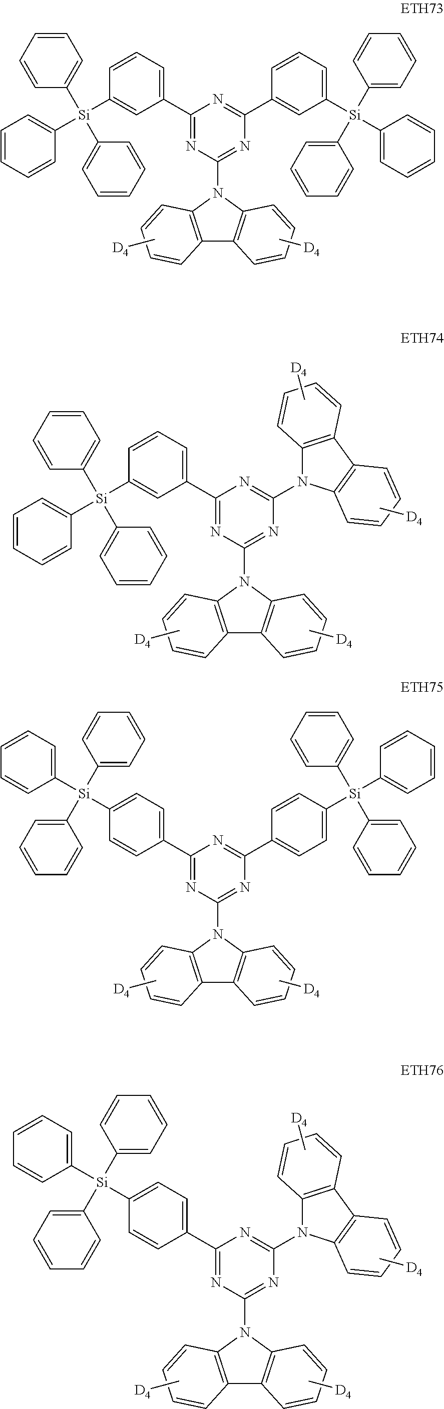 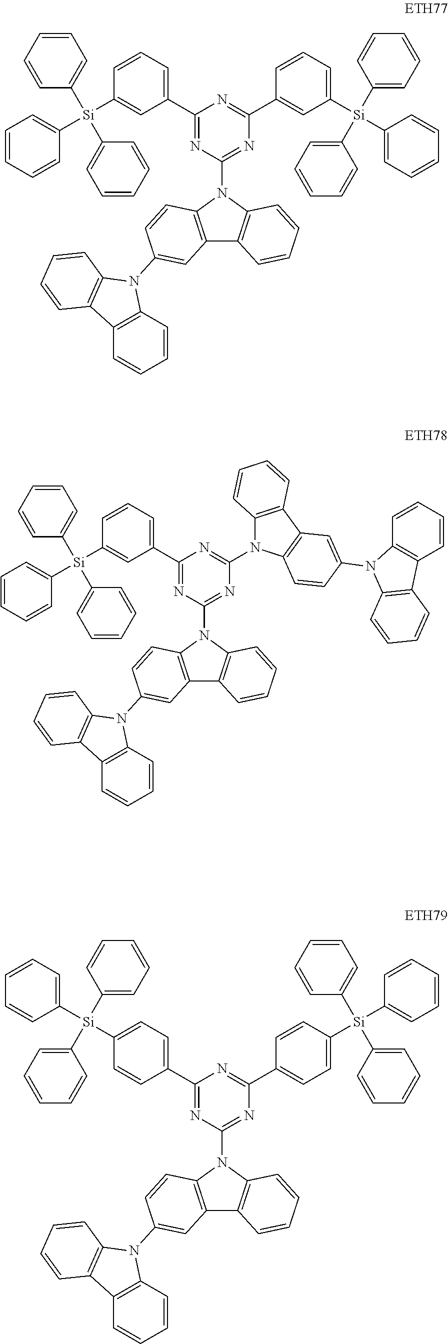 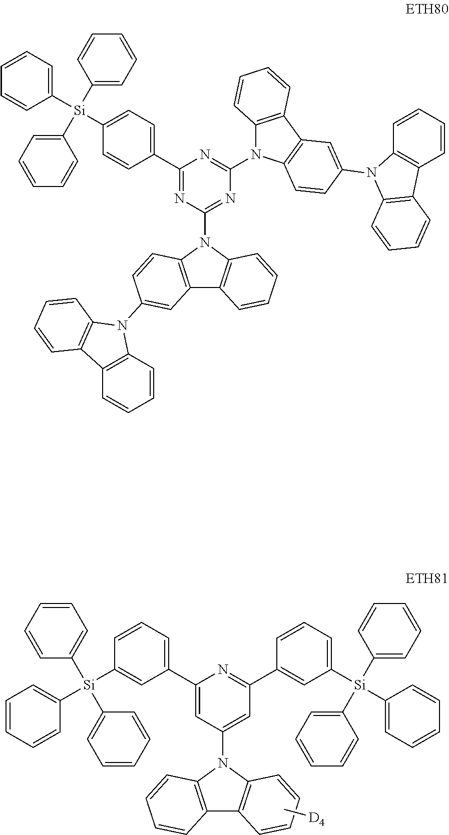 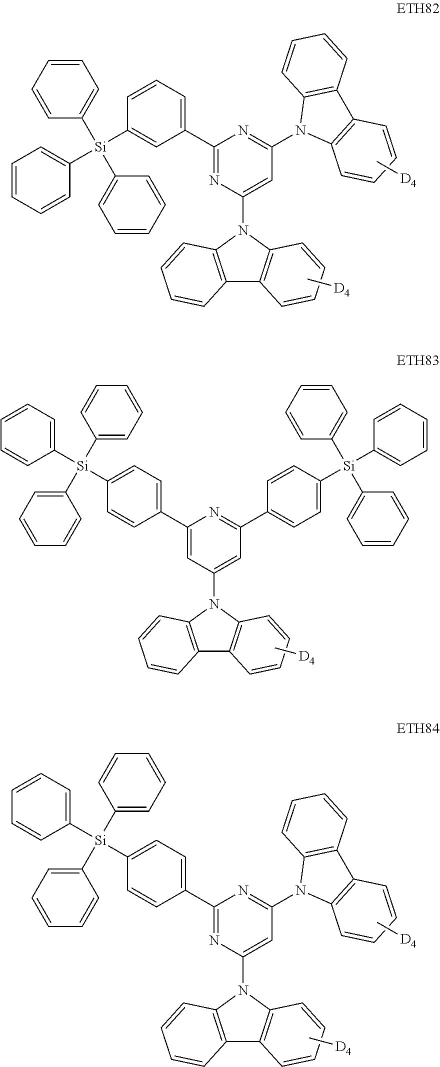 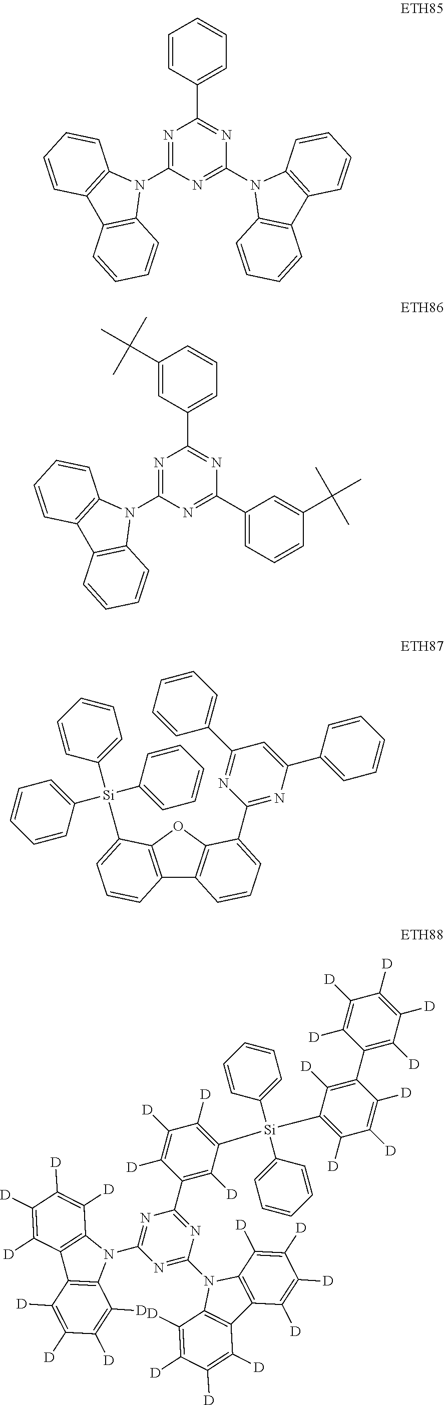 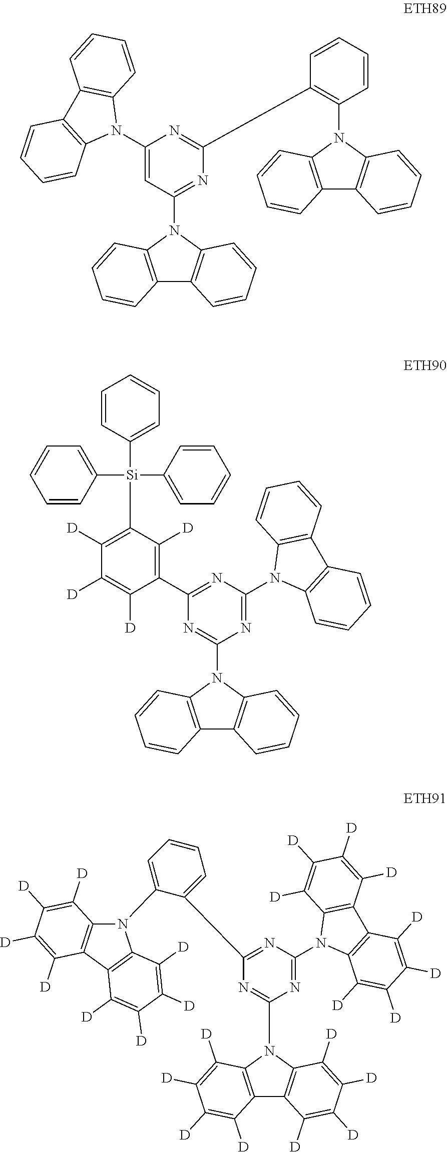 [SMILES: c1ccc(-n2c3ccccc3c3ccccc32)c(-c2nc(-n3c4ccccc4c4ccccc43)cc(-n3c4ccccc4c4ccccc43)n2)c1 ; [2H]c1c([2H])c(-c2nc(-n3c4ccccc4c4ccccc43)nc(-n3c4ccccc4c4ccccc43)n2)c([2H])c([Si](c2ccccc2)(c2ccccc2)c2ccccc2)c1[2H] ; [2H]c1c([2H])c([2H])c2c(c1[2H])c1c([2H])c([2H])c([2H])c([2H])c1n2-c1nc(-c2ccccc2-n2c3c([2H])c([2H])c([2H])c([2H])c3c3c([2H])c([2H])c([2H])c([2H])c32)nc(-n2c3c([2H])c([2H])c([2H])c([2H])c3c3c([2H])c([2H])c([2H])c([2H])c32)n1] 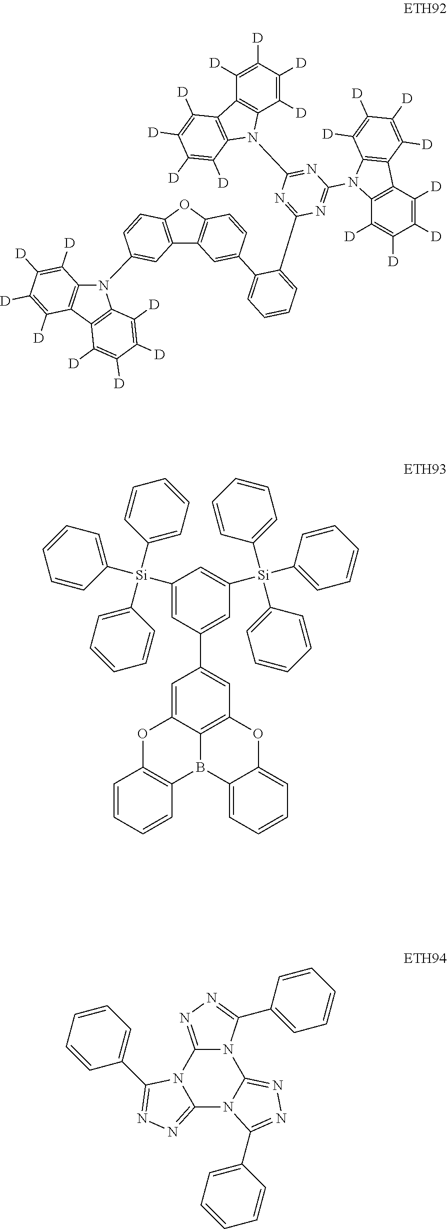 [SMILES: [2H]c1c([2H])c([2H])c2c(c1[2H])c1c([2H])c([2H])c([2H])c([2H])c1n2-c1ccc2oc3ccc(-c4ccccc4-c4nc(-n5c6c([2H])c([2H])c([2H])c([2H])c6c6c([2H])c([2H])c([2H])c([2H])c65)nc(-n5c6c([2H])c([2H])c([2H])c([2H])c6c6c([2H])c([2H])c([2H])c([2H])c65)n4)cc3c2c1 ; c1ccc([Si](c2ccccc2)(c2ccccc2)c2cc(-c3cc4c5c(c3)Oc3ccccc3B5c3ccccc3O4)cc([Si](c3ccccc3)(c3ccccc3)c3ccccc3)c2)cc1 ; c1ccc(-c2nnc3n2c2nnc(-c4ccccc4)n2c2nnc(-c4ccccc4)n32)cc1]
wherein in Compound Groups 1 and 2,
D represents a deuterium atom, and
Ph represents an unsubstituted phenyl group.

8. The light emitting element of claim 1, wherein the phosphorescent sensitizer is an organometallic complex that includes platinum (Pt) as a central metal atom.

9. The light emitting element of claim 1, wherein the light emitting dopant is a thermally activated delayed fluorescence dopant.

10. The light emitting element of claim 1, wherein the phosphorescent sensitizer comprises at least one compound selected from Compound Group 3: 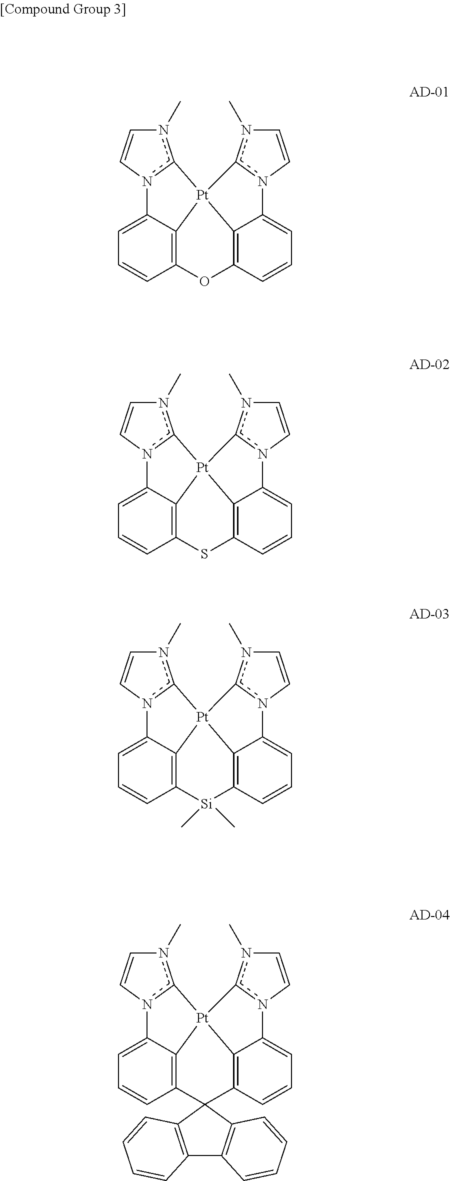 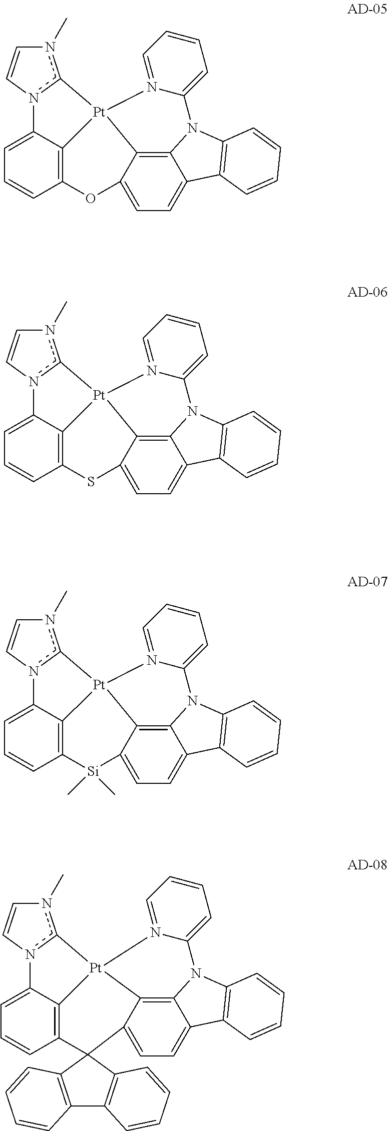 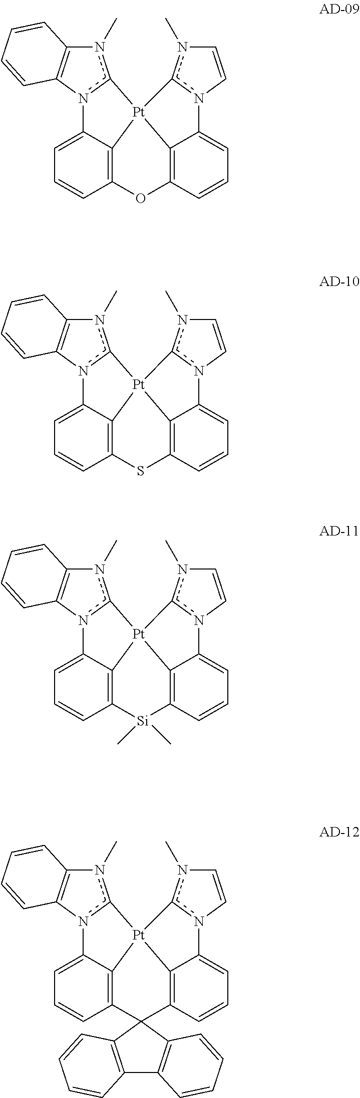 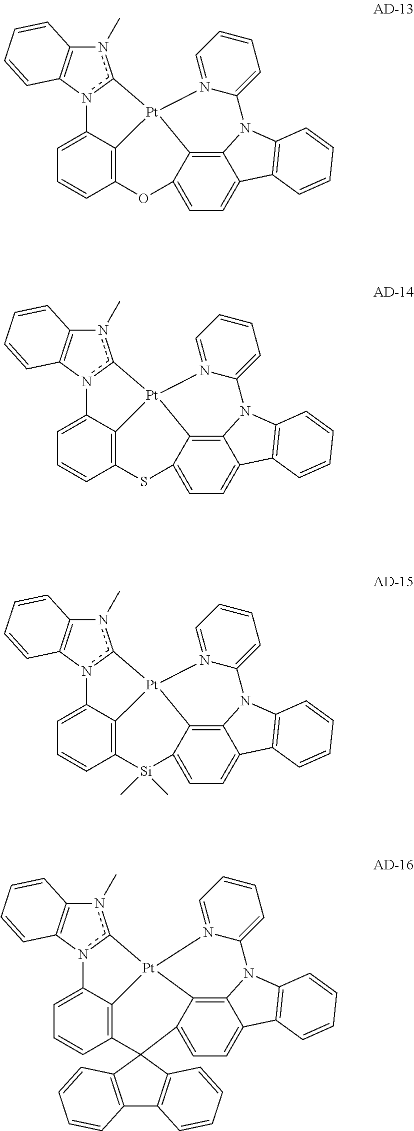 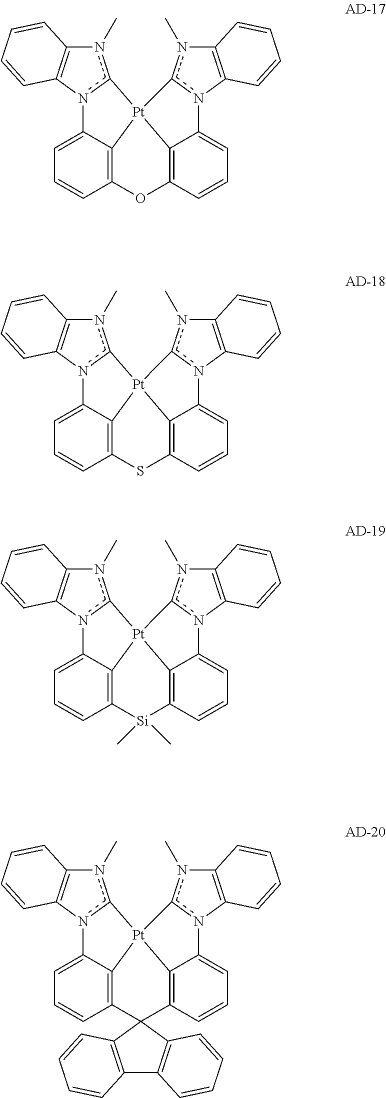 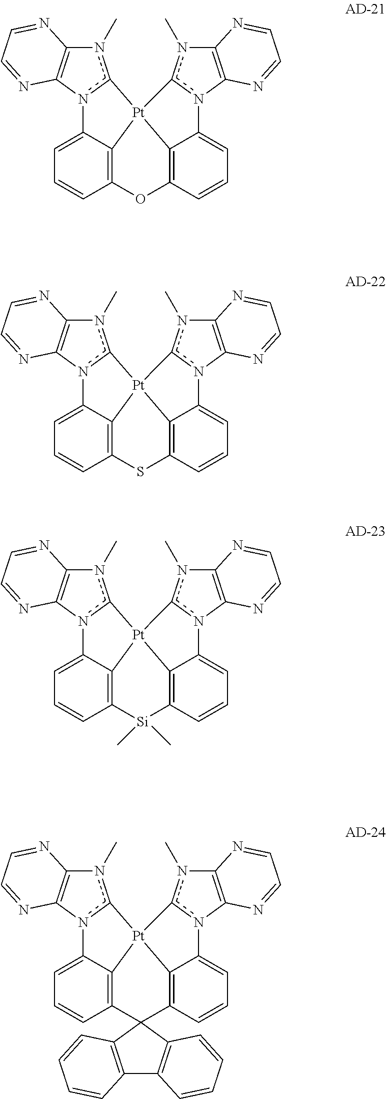 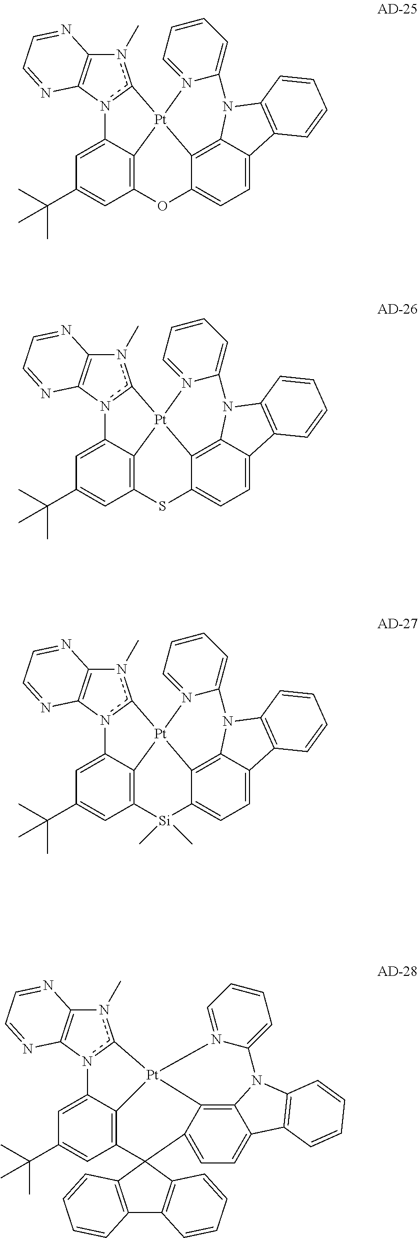 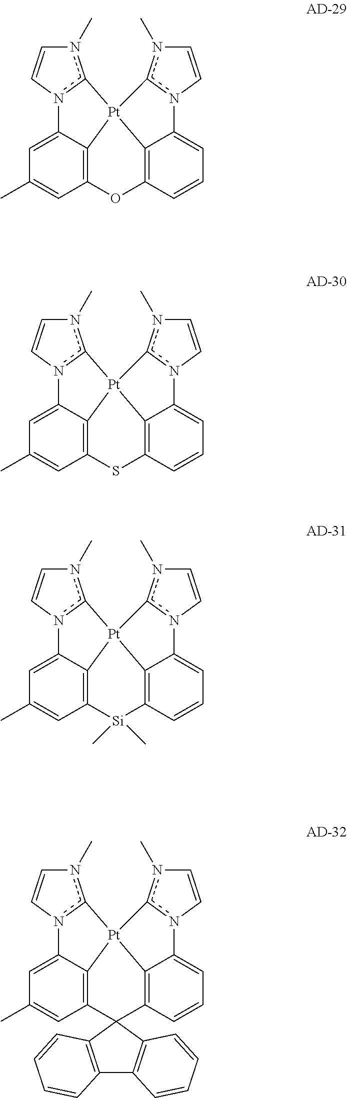 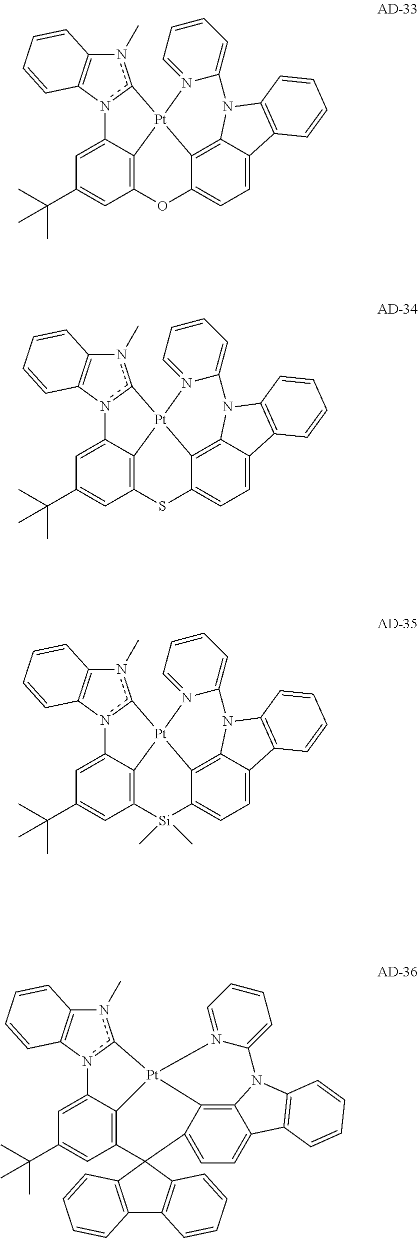 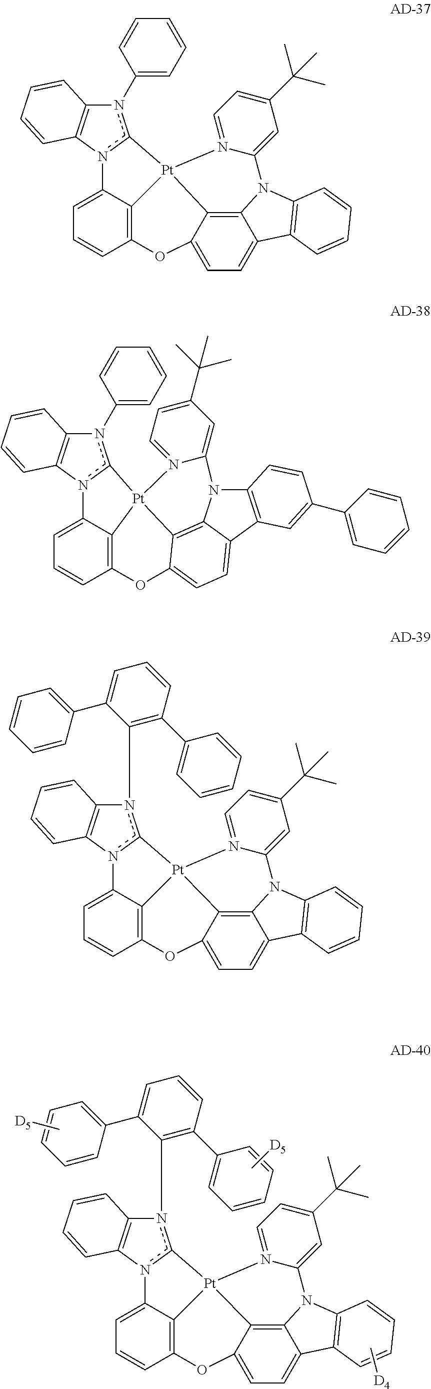 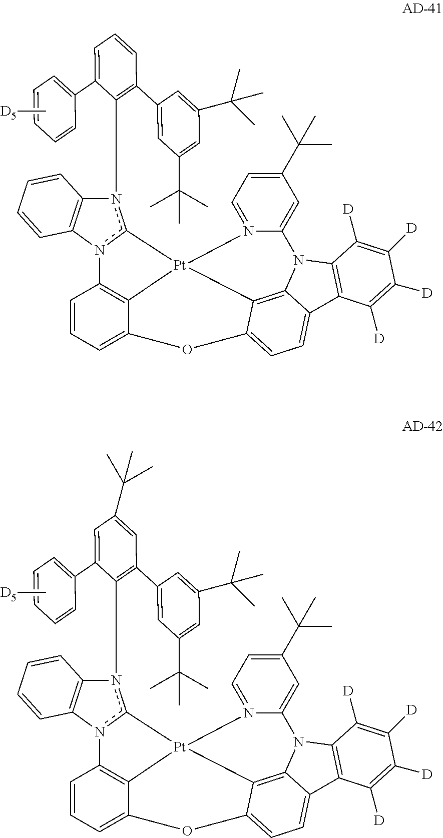 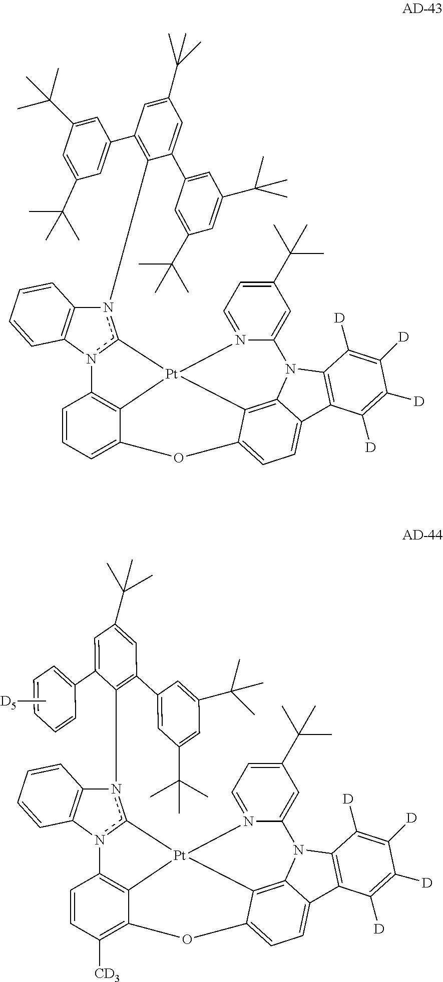 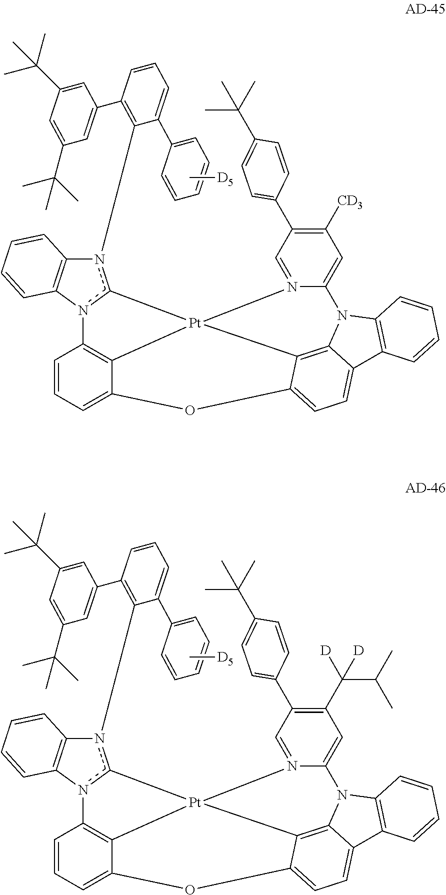 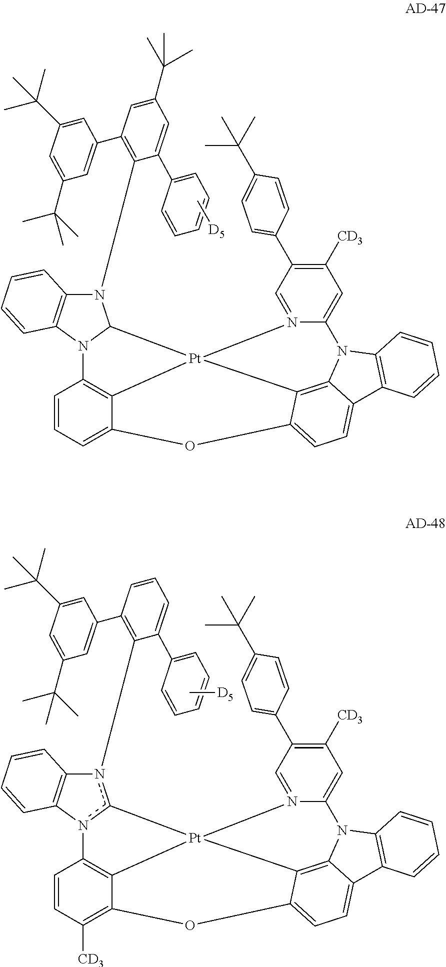 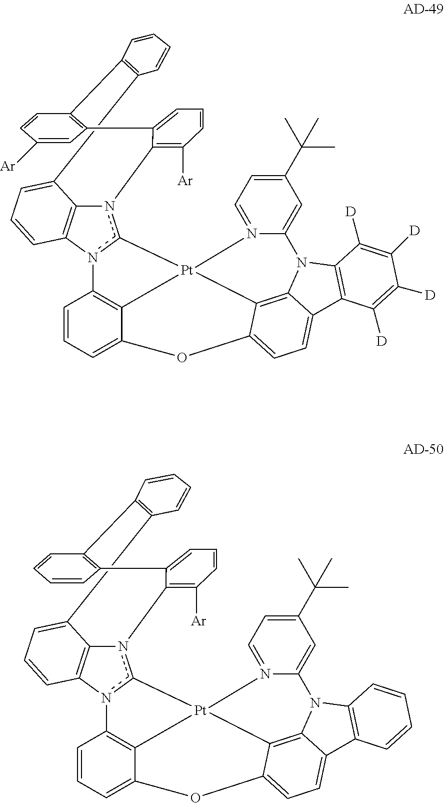 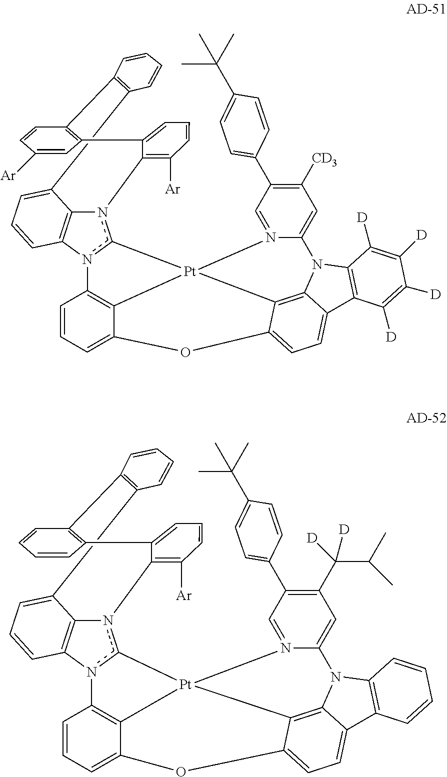 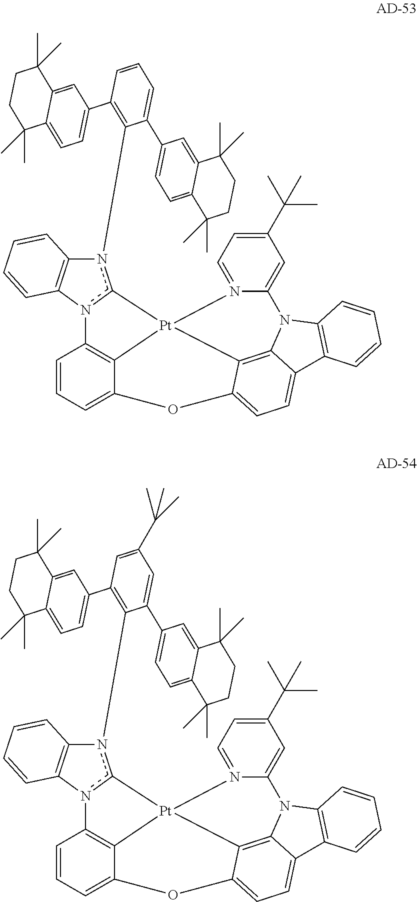 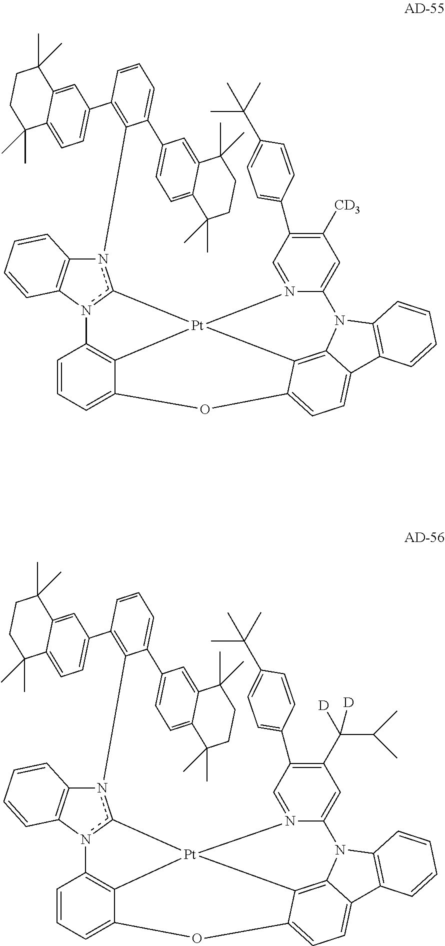
wherein in Compound Group 3,
Ar in Compounds AD-49 and AD-51 is a group represented by Formula Ar-a, and
Ar in Compounds AD-50 and AD-52 is a group represented by Formula Ar-b: 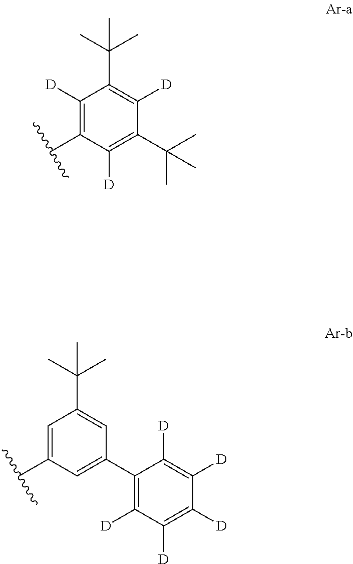 [SMILES: *c1c([2H])c(C(C)(C)C)c([2H])c(C(C)(C)C)c1[2H] ; *c1cc(-c2c([2H])c([2H])c([2H])c([2H])c2[2H])cc(C(C)(C)C)c1]
wherein in Compound Group 3, Formula Ar-a, and Formula Ar-b,
D represents a deuterium atom.

11. The light emitting element of claim 1, wherein the light emitting dopant comprises at least one compound selected from Compound Group 4: 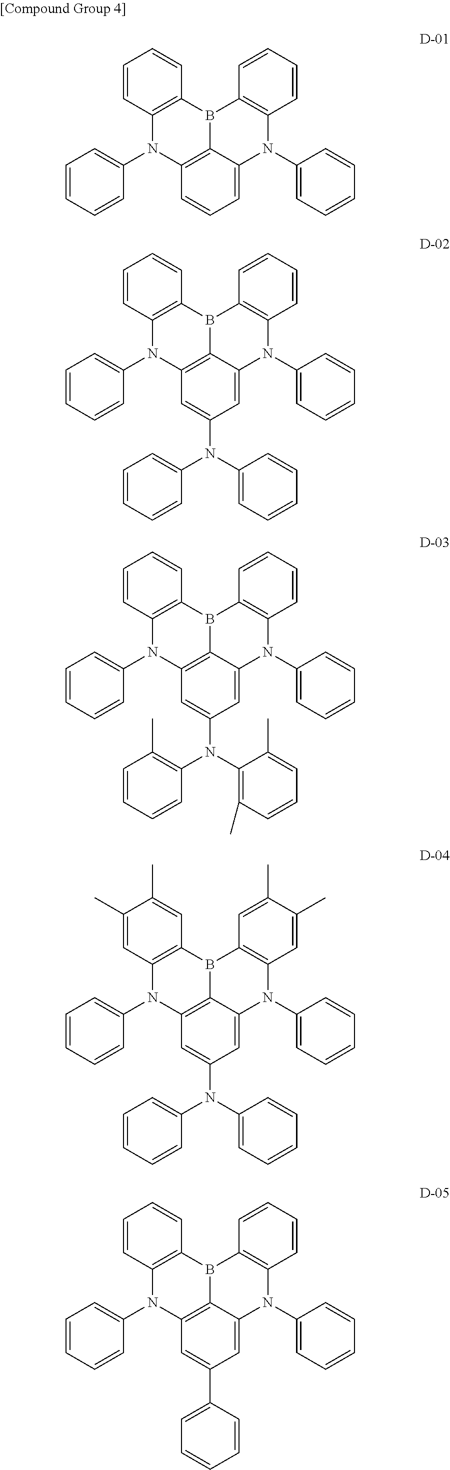 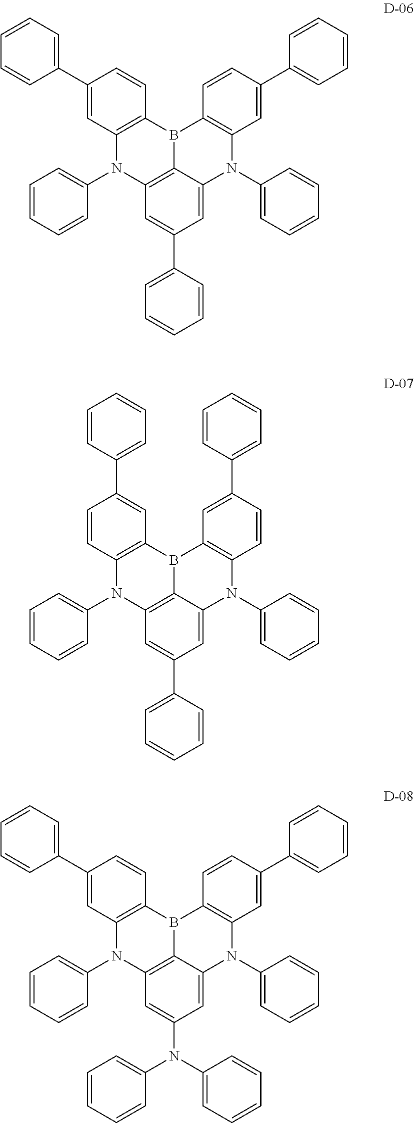 [SMILES: c1ccc(-c2ccc3c(c2)N(c2ccccc2)c2cc(-c4ccccc4)cc4c2B3c2ccc(-c3ccccc3)cc2N4c2ccccc2)cc1 ; c1ccc(-c2ccc3c(c2)B2c4cc(-c5ccccc5)ccc4N(c4ccccc4)c4cc(-c5ccccc5)cc(c42)N3c2ccccc2)cc1 ; c1ccc(-c2ccc3c(c2)N(c2ccccc2)c2cc(N(c4ccccc4)c4ccccc4)cc4c2B3c2ccc(-c3ccccc3)cc2N4c2ccccc2)cc1] 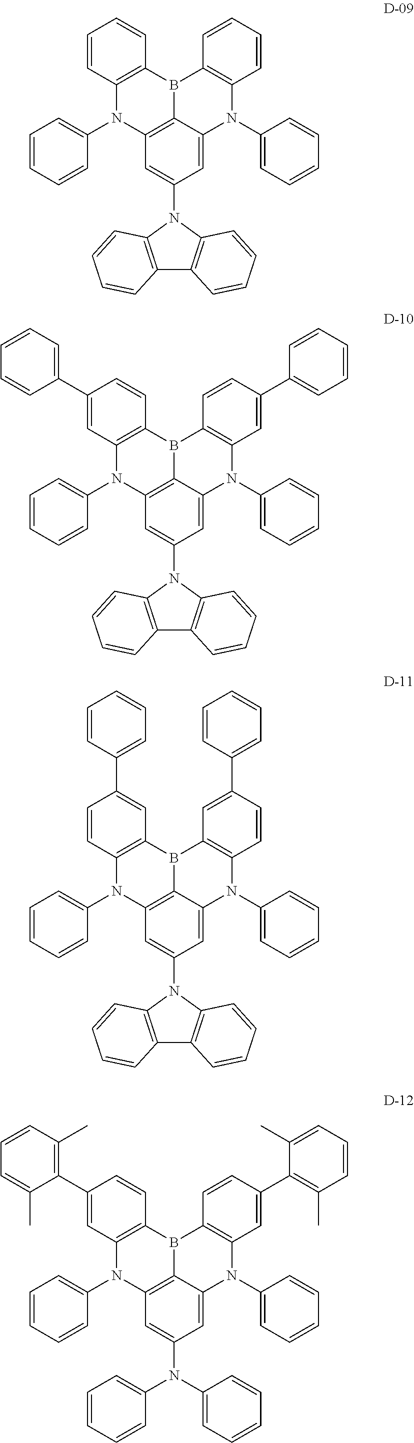 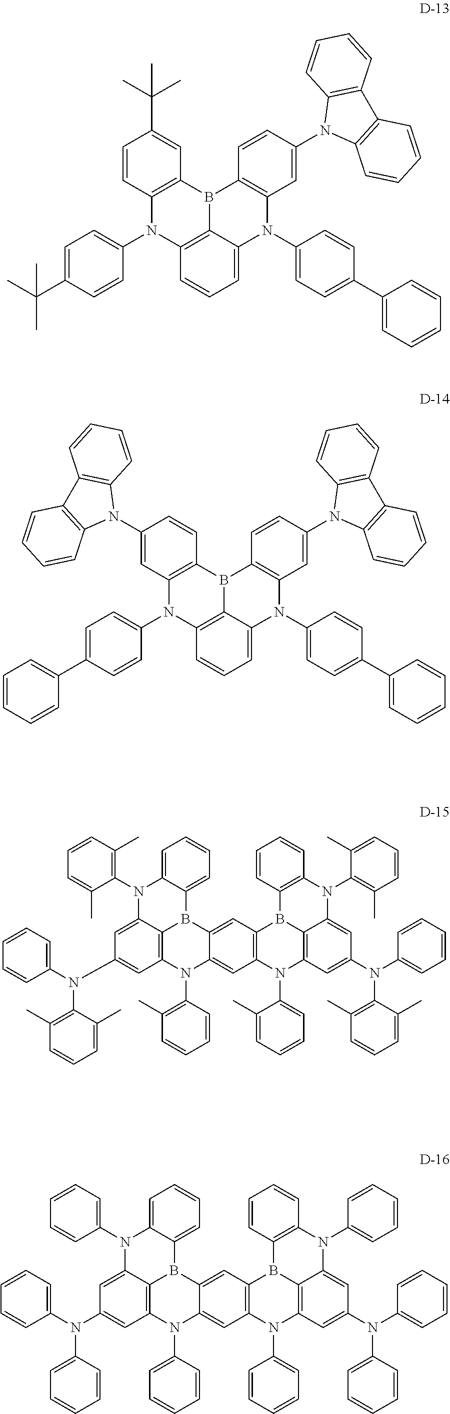 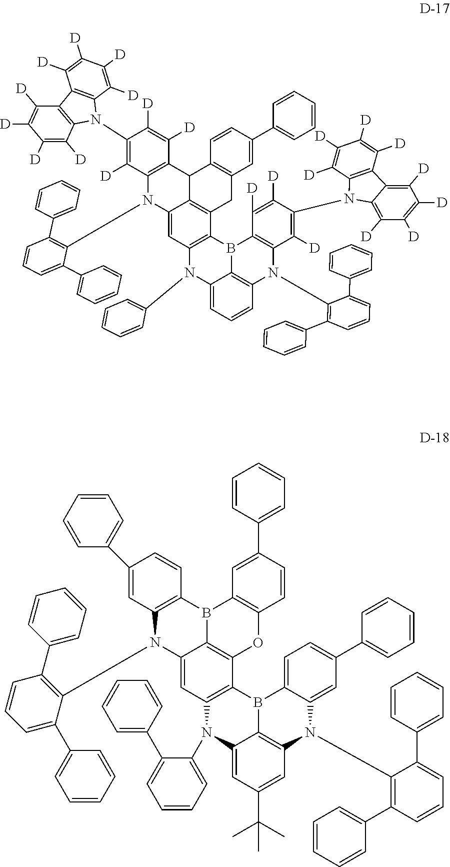
wherein in Compound Group 4,
D represents a deuterium atom.

12. The light emitting element of claim 1, wherein the emission layer emits blue light.

13. A light emitting element comprising:
a first electrode;
a second electrode facing the first electrode; and
at least one light emitting structure disposed between the first electrode and the second electrode, wherein
the at least one light emitting structure includes:
a hole transport region;
a first buffer layer disposed on the hole transport region;
an emission layer disposed on the first buffer layer;
a second buffer layer disposed on the emission layer; and
an electron transport region disposed on the second buffer layer,
the emission layer includes:
a hole transporting host;
an electron transporting host;
a phosphorescent sensitizer; and
a light emitting dopant,
the first buffer layer includes:
the hole transporting host;
the phosphorescent sensitizer; and
the light emitting dopant,
the second buffer layer includes:
the electron transporting host;
the phosphorescent sensitizer; and
the light emitting dopant, and
the first buffer layer and the second buffer layer each independently have a thickness in a range of about 20 Å to about 50 Å.

14. The light emitting element of claim 13, wherein
an amount of the phosphorescent sensitizer in the first buffer layer and the second buffer layer is each independently in a range of about 5 wt % to about 20 wt %, and
an amount of the light emitting dopant in the first buffer layer and the second buffer layer is each independently in a range of about 1 wt % to about 3 wt %.

15. The light emitting element of claim 13, wherein
the light emitting element includes a plurality of light emitting structures, and
the light emitting element further includes a charge generation layer disposed between adjacent structures among the plurality of light emitting structures.

16. An electronic device including a display device that provides images, the display device comprising:
a circuit layer disposed on a base layer; and
a light emitting element disposed on the circuit layer, wherein
the light emitting element includes:
a first electrode;
a second electrode facing the first electrode; and
at least one light emitting structure disposed between the first electrode and the second electrode,
the at least one light emitting structure includes:
a hole transport region;
a first buffer layer disposed on the hole transport region;
an emission layer disposed on the first buffer layer;
a second buffer layer disposed on the emission layer; and
an electron transport region disposed on the second buffer layer,
the emission layer includes:
a hole transporting host;
an electron transporting host;
a phosphorescent sensitizer; and
a light emitting dopant,
the first buffer layer includes:
the hole transporting host;
the phosphorescent sensitizer; and
the light emitting dopant,
the second buffer layer includes:
the electron transporting host;
the phosphorescent sensitizer; and
the light emitting dopant, and
the first buffer layer and the second buffer layer each independently have a thickness in a range of about 20 Å to about 50 Å.

17. The electronic device of claim 16, further comprising:
a light control layer disposed on the light emitting element, wherein
the light emitting element emits a source light, and
the light control layer transmits the source light or converts the wavelength of the source light.

18. The electronic device of claim 17, comprising:
a first pixel region emitting red light;
a second pixel region emitting green light; and
a third pixel region emitting blue light, wherein
the first pixel region, the second pixel region, and the third pixel region do not overlap each other in a plan view,
the light control layer includes:
a first light control part that is disposed to correspond to the first pixel region, and includes a first quantum dot that converts the wavelength of the source light;
a second light control part that is disposed to correspond to the second pixel region, and includes a second quantum dot that converts the wavelength of the source light; and
a third light control part that is disposed to correspond to the third pixel region.

19. The electronic device of claim 16, wherein
an amount of the phosphorescent sensitizer in the first buffer layer and the second buffer layer is each independently in a range of about 5 wt % to about 20 wt %, and
an amount of the light emitting dopant in the first buffer layer and the second buffer layer is each independently in a range of about 1 wt % to about 3 wt %.

20. The electronic device of claim 16, wherein
the phosphorescent sensitizer is an organometallic complex that includes platinum (Pt) as a central metal atom, and
the light emitting dopant is a thermally activated delayed fluorescence dopant.
